(19) United States
(12) Patent Application Publication
(10) Pub. No.: US 2024/0419073 A1
(43) Pub. Date: Dec. 19, 2024

(54) ADDITIVE-CONTAINING SILICON-CONTAINING RESIST UNDERLAYER FILM FORMING COMPOSITION

(71) Applicant: NISSAN CHEMICAL CORPORATION, Tokyo (JP)

(72) Inventors: Shuhei SHIGAKI, Toyama (JP); Taiki SAIJO, Toyama (JP); Wataru SHIBAYAMA, Toyama (JP)

(73) Assignee: NISSAN CHEMICAL CORPORATION, Tokyo (JP)

(21) Appl. No.: 18/704,765

(22) PCT Filed: Oct. 27, 2022
(86) PCT No.: PCT/JP2022/040061

§ 371 Date: Apr. 25, 2024

(30) Foreign Application Priority Data
Oct. 28, 2021 (JP) 2021-176582

(51) Int. Cl. G03F 7/075; G03F 7/027; G03F 7/40; H01L 21/311

(52) U.S. Cl. CPC G03F 7/0755; G03F 7/027; G03F 7/40; H01L 21/31144; H01L 21/31111; H01L 21/31127

(57) ABSTRACT

A silicon-containing resist underlayer film forming composition that includes a hydrolysis condensate of a hydrolyzable silane represented by Formula (1) or a hydrolyzable silane mixture containing a hydrolyzable silane represented by Formula (2) is the silicon-containing resist underlayer film forming composition for forming a silicon-containing resist underlayer film soluble in a basic chemical solution.

### TECHNICAL FIELD

The present invention relates to a resist underlayer film forming composition, and provides a silicon-containing resist underlayer film forming composition, which can form a pattern with low roughness in fine patterning, can be easily peeled off with a peeling solution that does not damage a semiconductor substrate, a coating-type organic underlayer film required in a patterning step, or a CVD film containing carbon as a main component, and can form a silicon-containing film that is particularly soluble in an alkaline chemical solution (basic chemical solution) and can maintain peelability even after dry etching.

### BACKGROUND ART

Conventionally, fine processing by lithography using a photoresist has been performed in manufacturing a semiconductor device. The fine processing is a processing method of forming fine irregularities corresponding to the pattern on a substrate surface by forming a photoresist thin film on a semiconductor substrate such as a silicon wafer, irradiating the photoresist thin film with active rays such as ultraviolet rays through a mask pattern on which a pattern of a semiconductor device is drawn, developing the photoresist thin film, and etching the substrate using the obtained photoresist pattern as a protective film.

In recent years, the degree of integration of semiconductor devices has increased, and the wavelength of the active rays which are used has also decreased from that of a KrF excimer laser (248 nm) to that of an ArF excimer laser (193 nm). With the shortening of the active light beam, the influence of reflection of the active light beam from the semiconductor substrate becomes a major problem, and a method of providing a resist underlayer film called an antireflection film (Bottom Anti-Reflective Coating, BARC) between a photoresist and a substrate to be processed has been widely applied.

As an underlayer film between the semiconductor substrate and the photoresist, a film known as a hard mask containing a metal element such as silicon or titanium is used. In this case, since there is a large difference in the constituent components between the resist and the hard mask, the rate at which the resist and the hard mask are removed by dry etching greatly depends on the type of gas used for dry etching. By appropriately selecting the gas type, the hard mask can be removed by dry etching without a large decrease in the film thickness of the photoresist. As described above, in recent manufacturing of a semiconductor device, a resist underlayer film has been arranged between a semiconductor substrate and a photoresist in order to achieve various effects including an antireflection effect.

A composition for a resist underlayer film has been studied so far, and development of a new material for a resist underlayer film is desired due to the diversity of required characteristics and the like. For example, a composition for forming a coating type boron phosphorus glass (BPSG) film having a structure having a specific silicic acid as a skeleton (Patent Literature 1) for the purpose of forming a wet-etchable film, and a silicon-containing resist underlayer film forming composition having a carbonyl structure (Patent Literature 2) for the purpose of removing a chemical solution of a mask residue after lithography have been disclosed.

### CITATION LIST

### Patent Literature

Patent Literature 1: JP 2016-74774 A
Patent Literature 2: WO 2018/181989 A

### SUMMARY OF INVENTION

### Technical Problem

In the most advanced semiconductor devices, while a multilayer process is frequently used due to miniaturization of an implant layer, transfer to an underlayer is usually performed by the above-described dry etching in the multilayer process, and finally processing of a substrate and removal of a mask residue after the substrate processing, for example, a resist film or an underlayer film including a resist underlayer film are also performed by dry etching or ashing treatment. However, dry etching and the ashing treatment cause considerable damage to the substrate, and amelioration thereof is required.

The present invention has been made in view of the above circumstances, and an object of the present invention is to provide a silicon-containing resist underlayer film forming composition for forming a resist underlayer film which can be peeled off not only by a conventional dry etching method but also by a wet etching method using a chemical solution such as dilute hydrofluoric acid, buffered hydrofluoric acid, or an alkaline chemical solution (basic chemical solution), and particularly exhibits excellent solubility in an alkaline chemical solution (basic chemical solution) in a processing process of a semiconductor substrate or the like, and to provide a silicon-containing resist underlayer film forming composition for forming a resist underlayer film having excellent storage stability and little residue in a dry etching process.

### Solution to Problem

As a result of intensive studies to solve the above problems, the present inventors have found that a film obtained from a composition containing a specific hydrolysis condensate (polysiloxane) obtained from a hydrolyzable silane having a succinic anhydride skeleton or a hydrolyzable silane having a group derived from a phosphonic acid exhibits excellent solubility in an alkaline solution (basic chemical solution), and a film obtained from a composition containing a hydrolysis condensate (polysiloxane) obtained from a hydrolyzable silane containing a specific additive (compound A) having a chemical structure containing a cation AX⁺ and an anion AZ⁻ exhibits excellent solubility in an alkaline solution (basic chemical solution), thereby completing the present invention.

That is, the present invention includes the following aspects.
[1] A silicon-containing resist underlayer film forming composition containing at least one of a hydrolysis condensate of a hydrolyzable silane represented by Formula (1) below and a hydrolyzable silane mixture containing a hydrolyzable silane represented by Formula (2) below is the silicon-containing resist underlayer film forming composition for forming a silicon-containing resist underlayer film soluble in a basic chemical solution.

[Chem. 1]

R¹ₐR²_{b}Si(R³)₄—(a+b) (1)

(In Formula (1),
R¹ is a group bonded to a silicon atom, and represents an organic group containing a succinic anhydride skeleton,
R² is a group bonded to a silicon atom, and independently of one another represents an optionally substituted alkyl group, an optionally substituted halogenated alkyl group or an optionally substituted amide group, an alkoxy group, a sulfonyl group, or a cyano group, or a combination of these,
R³ is a group or atom bonded to a silicon atom, and independently of one another represents an alkoxy group, an aralkyloxy group, an acyloxy group, or a halogen atom, and
a represents 1, b represents an integer of 0 to 2, and 4-(a+b) represents an integer of 1 to 3.)

[Chem. 2]

R⁴ₐR⁵_{b}Si(R⁶)₄—(a+b) (2)

(In Formula (2),
R⁴ is a group bonded to a silicon atom and represents a monovalent group represented by Formula (2-1) below,

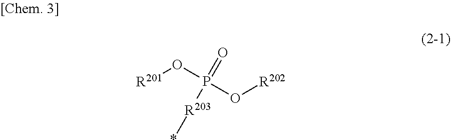

(In Formula (2-1),
R²⁰¹ to R²⁰² each independently represent a hydrogen atom or an organic group containing an optionally substituted alkyl group, R²⁰³ represents an optionally substituted alkylene group, and * represents a bond bonded to a silicon atom.)
R⁵ is a group bonded to a silicon atom, and independently of one another represents an optionally substituted alkyl group, an optionally substituted halogenated alkyl group or an optionally substituted alkoxyalkyl group, or represents an organic group containing an epoxy group, an acryloyl group, a methacryloyl group, a mercapto group, an amino group, an amide group, an alkoxy group, a sulfonyl group, or a cyano group, or a combination of these,
R⁶ is a group or atom bonded to a silicon atom, and independently of one another represents an alkoxy group, an aralkyloxy group, an acyloxy group, or a halogen atom, and
a represents 1, b represents an integer of 0 to 2, and 4-(a+b) represents an integer of 1 to 3.)
[2] The silicon-containing resist underlayer film forming composition according to [1], further including a compound A having a chemical structure containing a cation AX⁺ and an anion AZ⁻, the anion having a molecular weight of 65 or more.
[3] The silicon-containing resist underlayer film forming composition according to [2], in which the anion AZ⁻ is at least one anion selected from the group consisting of anions represented by the following (A) to (E):

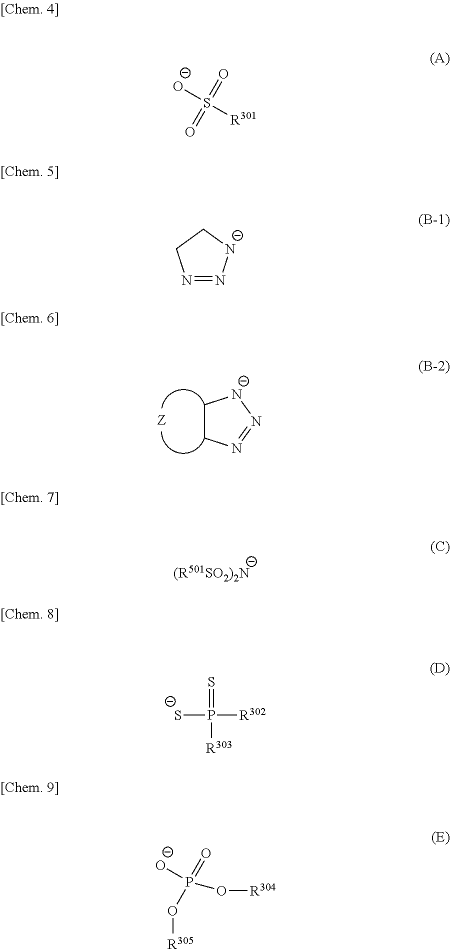

(In Formulae (A) to (E),
R³⁰¹ represents an optionally substituted alkyl group, an optionally substituted aryl group, an optionally substituted halogenated alkyl group, an optionally substituted aralkyl group, or an organic group containing an ester bond (—C(═O)—O— or —O—C(═O)—), or a combination of these,
Z represents an aromatic ring, a cyclic alkane, or a cyclic alkene with a non-aromatic ring,
R⁵⁰¹ represents an alkyl group in which some or all of the alkyl group may be substituted with a fluorine atom,
R³⁰² and R³⁰³ each independently represent an alkyl group, and
R³⁰⁴ and R³⁰⁵ each independently represent an alkyl group.)
[4] The silicon-containing resist underlayer film forming composition according to any one of [1] to [3], in which the hydrolyzable silane mixture further contains a hydrolyzable silane represented by the following formula (3):

[Chem. 10]

R⁷ₐR⁸_{b}Si(R⁹)₄—(a+b) (3)

(In Formula (3),
R⁷ is a group bonded to a silicon atom, and represents an organic group containing an alkenyl group,
R⁸ is a group bonded to a silicon atom, and independently of one another represents an optionally substituted alkyl group, an optionally substituted halogenated alkyl group or an optionally substituted amide group, an alkoxy group, a sulfonyl group, or a cyano group, or a combination of these,
R⁹ is a group or atom bonded to a silicon atom, and independently of one another represents an alkoxy group, an aralkyloxy group, an acyloxy group, or a halogen atom, and
a represents 1, b represents an integer of 0 to 2, and 4-(a+b) represents an integer of 1 to 3.)
[5] The silicon-containing resist underlayer film forming composition according to [4], in which the hydrolyzable silane mixture further contains a hydrolyzable silane represented by Formula (4) below:

[Chem. 11]

Si(R¹⁰)₄ (4)

(In Formula (4),
R¹⁰ is a group or atom bonded to a silicon atom, and independently of one another represents an alkoxy group, an aralkyloxy group, an acyloxy group, or a halogen atom.)
[6] A silicon-containing resist underlayer film forming composition for forming a silicon-containing resist underlayer film soluble in a basic chemical solution, the composition including
   a compound A having a chemical structure containing a cation AX⁺ and an anion AZ⁻, the anion having a molecular weight of 65 or more.
[7] The silicon-containing resist underlayer film forming composition according to [6], in which the anion AZ⁻ is at least one anion selected from the group consisting of anions represented by the following (A) to (E):

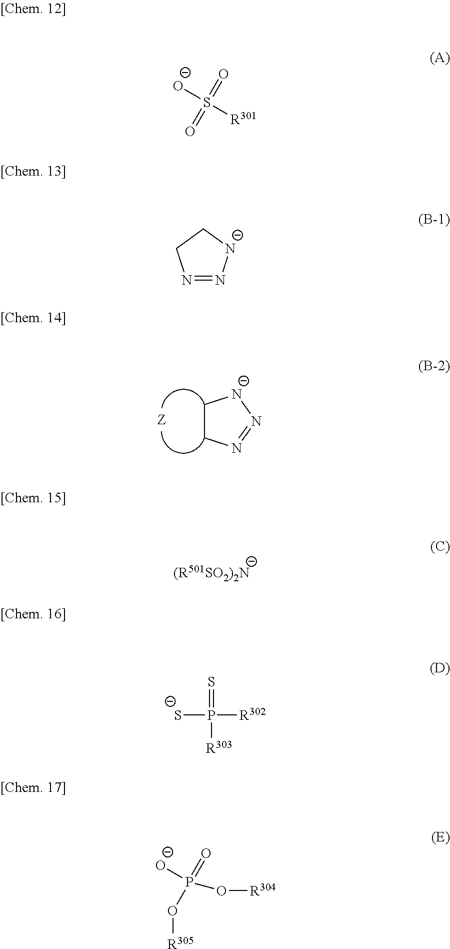

(In Formulae (A) to (E),
R³⁰¹ represents an optionally substituted alkyl group, an optionally substituted aryl group, an optionally substituted halogenated alkyl group, an optionally substituted aralkyl group, or an organic group containing an ester bond (—C(═O)—O— or —O—C(═O)—), or a combination of these,
Z represents an aromatic ring, a cyclic alkane, or a cyclic alkene with a non-aromatic ring,
R⁵⁰¹ represents an alkyl group in which some or all of the alkyl group may be substituted with a fluorine atom,
R³⁰² and R³⁰³ each independently represent an alkyl group, and
R³⁰⁴ and R³⁰⁵ each independently represent an alkyl group.)
[8] A silicon-containing resist underlayer film formed using the resist underlayer film forming composition according to any one of [1] to [7].
[9] A pattern forming method including
   a process of forming an organic underlayer film on a semiconductor substrate,
   a process of forming a silicon-containing resist underlayer film by applying the resist underlayer film forming composition according to any one of [1] to [7] on the organic underlayer film and firing the composition,
   a process of forming a resist film by applying a resist film forming composition on the silicon-containing resist underlayer film,
   a process of obtaining a resist pattern by exposing and developing the resist film;
   a process of etching the silicon-containing resist underlayer film using a resist pattern as a mask, and
   a process of etching the organic underlayer film using the patterned silicon-containing resist underlayer film as a mask.
[10] The pattern forming method according to [9], further including
   a process of removing a silicon-containing resist underlayer film by a wet method using a chemical solution after the process of etching the organic underlayer film.
[11] The pattern forming method according to [10], in which the chemical solution is a basic chemical solution.

### Advantageous Effects of Invention

In the present invention, a hydrolysis condensate obtained using a silane compound having a specific structure containing a succinic anhydride skeleton or a group derived from phosphonic acid as a hydrolyzable silane is used as one component of a resist underlayer film forming composition, whereby even a silicon-based film in a film formed from the composition exhibits excellent solubility with respect to a basic chemical solution, and removability by a wet method can be enhanced.

In addition, in the present invention, by using a specific additive (compound A) having a chemical structure containing a cation AX⁺ and an anion AZ⁻ as one component of a resist underlayer film forming composition containing a hydrolysis condensate obtained using a silane compound, even a silicon-based film in a film formed from the composition exhibits excellent solubility with respect to a basic chemical solution, and removability by a wet method can be enhanced.

Therefore, when pattern formation using a photoresist film or the like or processing of a semiconductor substrate or the like is performed using the resist underlayer film forming composition of the present invention, removal of residues of a mask after processing, for example, removal of an underlayer film including a resist film or a resist underlayer film can be easily performed with a chemical solution, and a semiconductor device with less substrate damage can be manufactured.

In addition, according to the present invention, when a film formed from a composition containing the hydrolysis condensate is dry-etched, the residue removability by etching can be enhanced.

### DESCRIPTION OF EMBODIMENTS

Hereinafter, the present invention will be described in detail. Note that the description of the constituent elements described below is an example for describing the present invention, and the present invention is not limited to these contents.

### [Silicon-containing Resist Underlayer Film Forming Composition]

The present invention is directed to a composition for forming a silicon-containing resist underlayer film that can be peeled off by a wet method, particularly that exhibits excellent solubility in a basic chemical solution.

The resist underlayer film forming composition of the present invention contains a hydrolysis condensate of a hydrolyzable silane mixture.

The resist underlayer film forming composition of the present invention is characterized by containing a product (hydrolysis condensate) obtained by hydrolytically condensing a hydrolyzable silane mixture containing a hydrolyzable silane having a specific structure. Hereinafter, a detailed description will be given in the section of (Silicon-containing Resist Underlayer Film Forming Composition of First Aspect).

In addition, the resist underlayer film forming composition of the present invention is characterized by containing a hydrolysis condensate of a hydrolyzable silane mixture and a specific additive (compound A) having a chemical structure containing a cation AX⁺ and an anion AZ⁻. Hereinafter, a detailed description will be given in the section of (Silicon-containing Resist Underlayer Film Forming Composition of Second Aspect).

In addition to the hydrolysis condensate of the hydrolyzable silane mixture and the specific additive (compound A), the resist underlayer film forming composition of the present invention may further contain a solvent and other components described later.

In the present invention, the hydrolysis condensate includes not only a polyorganosiloxane polymer that is a condensate in which the condensation is completely completed but also a polyorganosiloxane polymer that is a partial hydrolysis condensate in which the condensation is not completely completed. Such a partial hydrolysis condensate is also a polymer obtained by hydrolysis and condensation of a hydrolyzable silane compound, similarly to a condensate in which condensation is completely completed, but the polymer is only partially hydrolyzed and is not condensed, and therefore Si—OH groups remain. In addition, in the resist underlayer film forming composition of the present invention, an uncondensed hydrolysate (complete hydrolysate or partial hydrolysate) or a monomer (hydrolyzable silane compound) may remain in addition to the hydrolysis condensate.

In the present specification, the “hydrolyzable silane” may also be simply referred to as a “silane compound”.

### (Silicon-containing Resist Underlayer Film Forming Composition of First Aspect)

The resist underlayer film forming composition of the present invention contains a hydrolysis condensate of a hydrolyzable silane mixture containing a hydrolyzable silane having a specific structure.

### <Hydrolysis Condensate of Hydrolyzable Silane Mixture>

The hydrolyzable silane mixture contains a hydrolyzable silane represented by Formula (1) below or a hydrolyzable silane represented by Formula (2) below, and may contain, as desired, a hydrolyzable silane represented by Formula (3) below, a hydrolyzable silane of a tetraalkoxysilane represented by Formula (4) below, a hydrolyzable silane represented by Formula (5) below, or other hydrolyzable silane.

<<Silane Compound represented by Formula (1) (Hydrolyzable Silane)>>

The hydrolysis condensate used in the resist underlayer film forming composition of the present invention can be a product of hydrolysis condensation of a hydrolyzable silane mixture containing a silane compound represented by Formula (1) below.

[Chem. 18]

R¹ₐR²_{b}Si(R³)₄—(a+b) (1)
R¹ is a group bonded to a silicon atom, and represents an organic group containing a succinic anhydride skeleton.

The organic group of the R¹ is not particularly limited as long as it is an organic group containing the above skeleton.

Examples of the organic group containing a succinic anhydride skeleton include not only the skeleton itself but also an organic group in which one or more hydrogen atoms in an alkyl group are substituted with a succinic anhydride skeleton.

The alkyl group in which a hydrogen atom is substituted by the succinic anhydride skeleton or the like is not particularly limited, and may be linear, branched, or cyclic, and the number of carbon atoms thereof is usually 40 or less, for example, 30 or less, more preferably 20 or less, or 10 or less.

Specific examples of the linear or branched alkyl group include a methyl group, an ethyl group, a n-propyl group, an i-propyl group, a n-butyl group, an i-butyl group, a s-butyl group, a t-butyl group, a n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a n-hexyl, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, and a 1-ethyl-2-methyl-n-propyl group, but are not limited thereto.

In addition, specific examples of the cyclic alkyl group include a cycloalkyl group such as a cyclopropyl group, a cyclobutyl group, a 1-methyl-cyclopropyl group, a 2-methyl-cyclopropyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl, or a 2-ethyl-3-methyl-cyclopropyl group; and a bicycloalkyl group such as a bicyclobutyl group, a bicyclopentyl group, a bicyclohexyl group, a bicycloheptyl group, a bicyclooctyl group, a bicyclononyl group, or a bicyclodecyl group, but are not limited thereto.

Examples of the organic group of the R¹ include a monovalent group represented by Formula (1-1) below.

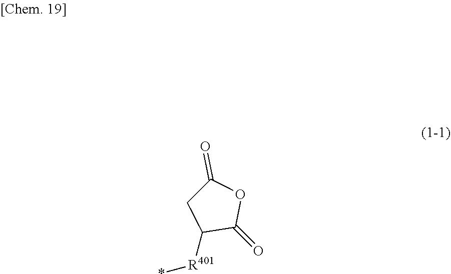

R⁴⁰¹ represents, for example, an alkylene group which is a divalent group derived by removing one hydrogen atom from the above-described linear, branched, or cyclic alkyl group. *represents a bond bonded to a silicon atom.

In Formula (1), R² is a group bonded to a silicon atom, and independently of one another represents an optionally substituted alkyl group, an optionally substituted halogenated alkyl group, or an optionally substituted amide group, an alkoxy group, a sulfonyl group, or a cyano group, or a combination of these.

Examples of the alkyl group in R² of Formula (1) include a linear or branched alkyl group having 1 to 10 carbon atoms, for example, a methyl group, an ethyl group, a n-propyl group, an i-propyl group, a n-butyl group, an i-butyl group, a s-butyl group, a t-butyl group, a n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, and a 1-ethyl-2-methyl-n-propyl group are included.

In addition, the cyclic alkyl group can also be used, and examples of the cyclic alkyl group having 3 to 10 carbon atoms include a cyclopropyl group, a cyclobutyl group, a 1-methyl-cyclopropyl group, a 2-methyl-cyclopropyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, a 2-ethyl-3-methyl-cyclopropyl group, and the like.

The halogenated alkyl group in R² in Formula (1) refers to an alkyl group substituted with a halogen atom.

Examples of the halogen atom include a fluorine atom, a chlorine atom, a bromine atom, and an iodine atom, and specific examples of the alkyl group include the same ones as those described above.

The number of carbon atoms of the halogenated alkyl group is not particularly limited, but is preferably 40 or less, more preferably 30 or less, still more preferably 20 or less, and still more preferably 10 or less.

Specific examples of the halogenated alkyl group include a monofluoromethyl group, a difluoromethyl group, a trifluoromethyl group, a bromodifluoromethyl group, a 2-chloroethyl group, a 2-bromoethyl group, a 1,1-difluoroethyl group, a 2,2,2-trifluoroethyl group, a 1,1,2,2-tetrafluoroethyl group, a 2-chloro-1, a 1,2-trifluoroethyl group, a pentafluoroethyl group, a 3-bromopropyl group, a 2,2,3,3-tetrafluoropropyl group, a 1,1,2,3,3,3-hexafluoropropyl group, a 1,1,1,3,3,3-hexafluoropropane-2-yl group, a 3-bromo-2-methylpropyl group, a 4-bromobutyl group, a perfluoropentyl group, and the like, but are not limited thereto.

The alkoxyalkyl group in R² in Formula (1) refers to an alkyl group substituted with an alkoxy group.

Specific examples of the alkyl group include the same groups as those described above.

Specific examples of the alkoxy group include alkoxy groups having a linear, branched, or cyclic alkyl moiety having 1 to 20 carbon atoms. Examples of the linear or branched alkoxy group include a methoxy group, an ethoxy group, an n-propoxy group, an i-propoxy group, an n-butoxy group, an i-butoxy group, an s-butoxy group, a t-butoxy group, an n-pentyloxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, a n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2-trimethyl-n-propoxy group, a 1-ethyl-1-methyl-n-propoxy group, a 1-ethyl-2-methyl-n-propoxy group, and the like.

Examples of the cyclic alkoxy group include a cyclopropoxy group, a cyclobutoxy group, a 1-methyl-cyclopropoxy group, a 2-methyl-cyclopropoxy group, a cyclopentyloxy group, a 1-methyl-cyclobutoxy group, a 2-methyl-cyclobutoxy group, a 3-methyl-cyclobutoxy group, a 1,2-dimethyl-cyclopropoxy group, a 2,3-dimethyl-cyclopropoxy group, a 1-ethyl-cyclopropoxy group, a 2-ethyl-cyclopropoxy group, a cyclohexyloxy group, a 1-methyl-cyclopentyloxy group, a 2-methyl-cyclopentyloxy group, a 3-methyl-cyclopentyloxy group, a 1-ethyl-cyclobutoxy group, a 2-ethyl-cyclobutoxy group, a 3-ethyl-cyclobutoxy group, a 1,2-dimethyl-cyclobutoxy group, 1,3-dimethyl-cyclobutoxy group, 2,2-dimethyl-cyclobutoxy group, 2,3-dimethyl-cyclobutoxy group, 2,4-dimethyl-cyclobutoxy group, 3,3-dimethyl-cyclobutoxy group, 1-n-propyl-cyclopropoxy group, 2-n-propyl-cyclopropoxy group, 1-i-propyl-cyclopropoxy group, 2-i-propyl-cyclopropoxy group, 1,2,2-trimethyl-cyclopropoxy group, 1,2,3-trimethyl-cyclopropoxy group, 2,2,3-trimethyl-cyclopropoxy group, 1-ethyl-2-methyl-cyclopropoxy group, 2-ethyl-1-methyl-cyclopropoxy group, a 2-ethyl-2-methyl-cyclopropoxy group, a 2-ethyl-3-methyl-cyclopropoxy group, and the like, but are not limited thereto.

The number of carbon atoms of the alkoxyalkyl group is not particularly limited, but is preferably 40 or less, more preferably 30 or less, still more preferably 20 or less, and still more preferably 10 or less.

Specific examples of the alkoxyalkyl group include, lower alkyloxy lower alkyl groups such as a methoxymethyl group, an ethoxymethyl group, a 1-ethoxyethyl group, a 2-ethoxyethyl group, an ethoxymethyl group, and the like, but are not limited thereto.

Examples of the substituent in the alkyl group, halogenated alkyl group, or alkoxyalkyl group include an alkyl group, an aryl group, an aralkyl group, a halogenated alkyl group, a halogenated aryl group, a halogenated aralkyl group, an alkoxyalkyl group, an aryloxy group, an alkoxyaryl group, an alkoxyaralkyl group, an alkenyl group, an alkoxy group, an aralkyloxy group, and the like. Among them, specific examples of the alkyl group, the halogenated alkyl group, the alkoxyalkyl group, and the alkoxy group, and the preferred number of carbon atoms thereof include the same as those described above.

Examples of the aryl group mentioned in the substituent include a phenyl group, an o-methylphenyl group, an m-methylphenyl group, a p-methylphenyl group, an o-chlorophenyl group, an m-chlorophenyl group, a p-chlorophenyl group, an o-fluorophenyl group, a p-mercaptophenyl group, an o-methoxyphenyl group, a p-methoxyphenyl group, a p-aminophenyl group, a p-cyanophenyl group, an α-naphthyl group, a β-naphthyl group, an o-biphenylyl group, an m-biphenylyl group, a p-biphenylyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, and the like, but are not limited thereto.

Examples of the aralkyl group mentioned in the substituent include a phenylmethyl group (benzyl group), a 2-phenylethylene group, a 3-phenyl-n-propyl group, a 4-phenyl-n-butyl group, a 5-phenyl-n-pentyl group, a 6-phenyl-n-hexyl group, a 7-phenyl-n-heptyl group, an 8-phenyl-n-octyl group, a 9-phenyl-n-nonyl group, a 10 phenyl-n-decyl group, and the like, but are not limited thereto.

The halogenated aryl group mentioned in the substituent is an aryl group substituted with a halogen atom, and specific examples of such an aryl group include the same groups as those described above. Examples of the halogen atom include a fluorine atom, a chlorine atom, a bromine atom, and an iodine atom.

The number of carbon atoms of the halogenated aryl group is not particularly limited, but is preferably 40 or less, more preferably 30 or less, and still more preferably 20 or less.

Specific examples of the halogenated aryl group include a 2-fluorophenyl group, a 3-fluorophenyl group, a 4-fluorophenyl group, a 2,3-difluorophenyl group, a 2,4-difluorophenyl group, a 2,5-difluorophenyl group, a 2,6-difluorophenyl group, a 3,4-difluorophenyl group, a 3,5-difluorophenyl group, a 2,3,4-trifluorophenyl group, a 2,3,5-trifluorophenyl group, a 2,3,6-trifluorophenyl group, a 2,4,5-trifluorophenyl group, a 2,4,6-trifluorophenyl group, a 3,4,5-trifluorophenyl group, a 2,3,4,5-tetrafluorophenyl group, a 2,3,4,6-tetrafluorophenyl group, a 2,3,5,6-tetrafluorophenyl group, a pentafluorophenyl group, a 2-fluoro-1-naphthyl group, a 3-fluoro-1-naphthyl group, a 4-fluoro-1-naphthyl group, a 6-fluoro-1-naphthyl group, a 7-fluoro-1-naphthyl group, an 8-fluoro-1-naphthyl group, a 4,5-difluoro-1-naphthyl group, a 5,7-difluoro-1-naphthyl group, a 5,8-difluoro-1-naphthyl group, a 5,6,7,8-tetrafluoro-1-naphthyl group, a heptafluoro-1-naphthyl group, a 1-fluoro-2-naphthyl group, a 5-fluoro-2-naphthyl group, a 6-fluoro-2-naphthyl group, a 7-fluoro-2-naphthyl group, a 5,7-difluoro-2-naphthyl group, a heptafluoro-2-naphthyl group, and the like, but are not limited thereto.

The halogenated aralkyl group mentioned in the substituent is an aralkyl group substituted with a halogen atom, and specific examples of such aralkyl group and halogen atom include the same groups as those described above.

The number of carbon atoms of the halogenated aralkyl group is not particularly limited, but is preferably 40 or less, more preferably 30 or less, and still more preferably 20 or less.

Specific examples of the halogenated aralkyl group include a 2-fluorobenzyl group, a 3-fluorobenzyl group, a 4-fluorobenzyl group, a 2,3-difluorobenzyl group, a 2,4-difluorobenzyl group, a 2,5-difluorobenzyl group, a 2,6-difluorobenzyl group, a 3,4-difluorobenzyl group, a 3,5-difluorobenzyl group, a 2,3,4-trifluorobenzyl group, a 2,3,5-trifluorobenzyl group, a 2,3,6-trifluorobenzyl group, a 2,4,5-trifluorobenzyl group, a 2,4,6-trifluorobenzyl group, a 2,3,4,5-tetrafluorobenzyl group, a 2,3,4,6-tetrafluorobenzyl group, a 2,3,5,6-tetrafluorobenzyl group, a 2,3,4,5,6-pentafluorobenzyl group, and the like, but are not limited thereto.

The aryloxy group mentioned in the substituent is a group in which an aryl group is bonded via an oxygen atom (—O—), and specific examples of such an aryl group include the same groups as those described above. The number of carbon atoms of the aryloxy group is not particularly limited, but is preferably 40 or less, more preferably 30 or less, and still more preferably 20 or less, and specific examples thereof include a phenoxy group, a naphthalene-2-yl-oxy group, and the like but are not limited thereto.

In addition, in a case where there are two or more substituents, the substituents may be bonded to each other to form a ring.

The alkoxyaryl group mentioned in the substituent is an aryl group substituted with an alkoxy group, and specific examples of such an alkoxy group and aryl group include the same groups as those described above.

The number of carbon atoms of the alkoxyaryl group is not particularly limited, but is preferably 40 or less, more preferably 30 or less, and still more preferably 20 or less.

Specific examples of the alkoxyaryl group include a 2-methoxyphenyl group, a 3-methoxyphenyl group, a 4-methoxyphenyl group, a 2-(1-ethoxy) phenyl group, a 3-(1-ethoxy) phenyl group, a 4-(1-ethoxy) phenyl group, a 2-(2-ethoxy) phenyl group, a 3-(2-ethoxy) phenyl group, a 4-(2-ethoxy) phenyl group, a 2-methoxynaphthalene-1-yl group, a 3-methoxynaphthalene-1-yl group, a 4-methoxynaphthalene-1-yl group, a 5-methoxynaphthalene-1-yl group, a 6-methoxynaphthalene-1-yl group, a 7-methoxynaphthalene-1-yl group, and the like, but are not limited thereto

The alkoxyaralkyl group mentioned in the substituent is an aralkyl group substituted with an alkoxy group, and specific examples of such an alkoxy group and aralkyl group include the same groups as those described above.

The number of carbon atoms of the alkoxyaralkyl group is not particularly limited, but is preferably 40 or less, more preferably 30 or less, and still more preferably 20 or less.

Specific examples of the alkoxyaralkyl group include a 3-(methoxyphenyl) benzyl group and a 4-(methoxyphenyl) benzyl group, but are not limited thereto.

Examples of the alkenyl group mentioned in the substituent include an optionally substituted alkenyl group, and examples thereof include an alkenyl group having 2 to 10 carbon atoms. More specific examples thereof include an ethenyl group (vinyl group), a 1-propenyl group, a 2-propenyl group, a 1-methyl-1-ethenyl group, a 1-butenyl group, a 2-butenyl group, a 3-butenyl group, a 2-methyl-1-propenyl group, a 2-methyl-2-propenyl group, a 1-ethylethenyl group, a 1-methyl-1-propenyl group, a 1-methyl-2-propenyl group, a 1-pentenyl group, a 2-pentenyl group, a 3-pentenyl group, a 4-pentenyl group, a 1-n-propylethenyl group, a 1-methyl-1-butenyl group, a 1-methyl-2-butenyl group, a 1-methyl-3-butenyl group, a 2-ethyl-2-propenyl group, a 2-methyl-1-butenyl group, a 2-methyl-2-butenyl group, a 2-methyl-3-butenyl group, a 3-methyl-1-butenyl group, a 3-methyl-2-butenyl group, a 3-methyl-3-butenyl group, a 1,1-dimethyl-2-propenyl group, a 1-i-propylethenyl group, a 1,2-dimethyl-1-propenyl group, a 1,2-dimethyl-2-propenyl group, a 1-cyclopentenyl group, a 2-cyclopentenyl group, a 3-cyclopentenyl group, a 1-hexenyl group, a 2-hexenyl group, a 3-hexenyl group, a 4-hexenyl group, a 5-hexenyl group, a 1-methyl-1-pentenyl group, a 1-methyl-2-pentenyl group, a 1-methyl-3-pentenyl group, a 1-methyl-4-pentenyl group, a 1-n-butylethenyl group, a 2-methyl-1-pentenyl group, a 2-methyl-2-pentenyl group, a 2-methyl-3-pentenyl group, a 2-methyl-4-pentenyl group, a 2-n-propyl-2-propenyl group, a 3-methyl-1-pentenyl group, a 3-methyl-2-pentenyl group, a 3-methyl-3-pentenyl group, a 3-methyl-4-pentenyl group, a 3-ethyl-3-butenyl group, a 4-methyl-1-pentenyl group, a 4-methyl-2-pentenyl group, a 4-methyl-3-pentenyl group, a 4-methyl-4-pentenyl group, a 1,1-dimethyl-2-butenyl group, a 1,1-dimethyl-3-butenyl group, a 1,2-dimethyl-1-butenyl group, a 1,2-dimethyl-2-butenyl group, a 1,2-dimethyl-3-butenyl group, a 1-methyl-2-ethyl-2-propenyl group, a 1-s-butylethenyl group, a 1,3-dimethyl-1-butenyl group, a 1,3-dimethyl-2-butenyl group, a 1,3-dimethyl-3-butenyl group, a 1-i-butylethenyl group, a 2,2-dimethyl-3-butenyl group, a 2,3-dimethyl-1-butenyl group, a 2,3-dimethyl-2-butenyl group, a 2,3-dimethyl-3-butenyl group, a 2-i-propyl-2-propenyl group, a 3,3-dimethyl-1-butenyl group, a 1-ethyl-1-butenyl group, a 1-ethyl-2-butenyl group, a 1-ethyl-3-butenyl group, a 1-n-propyl-1-propenyl group, a 1-n-propyl-2-propenyl group, a 2-ethyl-1-butenyl group, a 2-ethyl-2-butenyl group, a 2-ethyl-3-butenyl group, a 1,1,2-trimethyl-2-propenyl group, a 1-t-butylethenyl group, a 1-methyl-1-ethyl-2-propenyl group, a 1-ethyl-2-methyl-1-propenyl group, a 1-ethyl-2-methyl-2-propenyl group, a 1-i-propyl-1-propenyl group, a 1-i-propyl-2-propenyl group, a 1-methyl-2-cyclopentenyl group, a 1-methyl-3-cyclopentenyl group, a 2-methyl-1-cyclopentenyl group, a 2-methyl-2-cyclopentenyl group, a 2-methyl-3-cyclopentenyl group, a 2-methyl-4-cyclopentenyl group, a 2-methyl-5-cyclopentenyl group, a 2-methylene-cyclopentyl group, a 3-methyl-1-cyclopentenyl group, a 3-methyl-2-cyclopentenyl group, a 3-methyl-3-cyclopentenyl group, a 3-methyl-4-cyclopentenyl group, a 3-methyl-5-cyclopentenyl group, a 3-methylene-cyclopentyl group, a 1-cyclohexenyl group, a 2-cyclohexenyl group, a 3-cyclohexenyl group, and the like, and bridged cyclic alkenyl groups such as a bicycloheptenyl group (norbornyl group) are also included.

The aralkyloxy group mentioned in the substituent is a group derived by removing a hydrogen atom from a hydroxy group of aralkyl alcohol, and specific examples of such an aralkyl group include the same groups as those described above.

The number of carbon atoms of the aralkyloxy group is not particularly limited, but is preferably 40 or less, more preferably 30 or less, and still more preferably 20 or less.

Specific examples of the aralkyloxy group include a phenylmethyloxy group (benzyloxy group), a 2-phenylethyleneoxy group, a 3-phenyl-n-propyloxy group, a 4-phenyl-n-butyloxy group, a 5-phenyl-n-pentyloxy group, a 6-phenyl-n-hexyloxy group, a 7-phenyl-n-heptyloxy group, an 8-phenyl-n-octyloxy group, a 9-phenyl-n-nonyloxy group, a 10 phenyl-n-decyloxy group, and the like, but are not limited thereto.

Examples of the organic group containing an epoxy group in R² of Formula (1) above include a glycidoxymethyl group, a glycidoxyethyl group, a glycidoxypropyl group, a glycidoxybutyl group, an epoxy cyclohexyl group, and the like, but are not limited thereto.

Examples of the organic group containing an acryloyl group in R² of Formula (1) above include an acryloylmethyl group, an acryloylethyl group, an acryloylpropyl group, and the like, but are not limited thereto.

Examples of the organic group containing a methacryloyl group in R² of Formula (1) above include a methacryloyl methyl group, a methacryloyl ethyl group, a methacryloyl propyl group, and the like, but are not limited thereto.

Examples of the organic group containing a mercapto group in R² of Formula (1) above include an ethylmercapto group, a butylmercapto group, a hexylmercapto group, an octylmercapto group, and the like, but are not limited thereto.

Examples of the organic group containing an amino group in R² of Formula (1) above include an amino group, an aminomethyl group, an aminoethyl group, a dimethylaminoethyl group, a dimethylaminopropyl group, and the like, but are not limited thereto.

Examples of the organic group containing an alkoxy group in R² of Formula (1) above include a methoxymethyl group, a methoxyethyl group, and the like, but are not limited thereto. However, a group in which an alkoxy group is directly bonded to a silicon atom is excluded.

Examples of the organic group containing a sulfonyl group in R² of Formula (1) above include a sulfonylalkyl group, a sulfonylaryl group, and the like, but are not limited thereto.

Examples of the organic group containing a cyano group in R² of Formula (1) above include a cyanoethyl group, a cyanopropyl group, and the like, but are not limited thereto.

In Formula (1), R³ is a group or atom bonded to a silicon atom, and independently of one another represents an alkoxy group, an aralkyloxy group, an acyloxy group, or a halogen atom. Examples of the alkoxy group and the halogen atom include the same groups as those described above.

The aralkyloxy group is a group derived by removing a hydrogen atom from a hydroxy group of aralkyl alcohol, and specific examples of such an aralkyl group include the same groups as those described above.

The number of carbon atoms of the aralkyloxy group is not particularly limited, but is preferably 40 or less, more preferably 30 or less, and still more preferably 20 or less.

Specific examples of the aralkyloxy group include a phenylmethyloxy group (benzyloxy group), a 2-phenylethyleneoxy group, a 3-phenyl-n-propyloxy group, a 4-phenyl-n-butyloxy group, a 5-phenyl-n-pentyloxy group, a 6-phenyl-n-hexyloxy group, a 7-phenyl-n-heptyloxy group, an 8-phenyl-n-octyloxy group, a 9-phenyl-n-nonyloxy group, a 10 phenyl-n-decyloxy group, and the like, but are not limited thereto.

The acyloxy group is a group derived by removing a hydrogen atom from a carboxylic acid group of a carboxylic acid compound, and typically includes an alkylcarbonyloxy group, an arylcarbonyloxy group, or an aralkylcarbonyloxy group derived by removing a hydrogen atom from a carboxylic acid group of an alkyl carboxylic acid, an aryl carboxylic acid, or an aralkyl carboxylic acid, but are not limited thereto. Specific examples of the alkyl group, the aryl group, and the aralkyl group in such alkyl carboxylic acid, carboxylic acid, and carboxylic acid include the same groups as those described above.

Specific examples of the acyloxy group include an acyloxy group having 2 to 20 carbon atoms. For example, a methylcarbonyloxy group, an ethylcarbonyloxy group, a n-propylcarbonyloxy group, an i-propylcarbonyloxy group, a n-butylcarbonyloxy group, an i-butylcarbonyloxy group, a s-butylcarbonyloxy group, a t-butylcarbonyloxy group, a n-pentylcarbonyloxy group, a 1-methyl-n-butylcarbonyloxy group, a 2-methyl-n-butylcarbonyloxy group, a 3-methyl-n-butylcarbonyloxy group, a 1,1-dimethyl-n-propylcarbonyloxy group, a 1,2-dimethyl-n-propylcarbonyloxy group, a 2,2-dimethyl-n-propylcarbonyloxy group, a 1-ethyl-n-propylcarbonyloxy group, a n-hexylcarbonyloxy group, a 1-methyl-n-pentylcarbonyloxy group, a 2-methyl-n-pentylcarbonyloxy group, a 3-methyl-n-pentylcarbonyloxy group, a 4-methyl-n-pentylcarbonyloxy group, a 1,1-dimethyl-n-butylcarbonyloxy group, a 1,2-dimethyl-n-butylcarbonyloxy group, a 1,3-dimethyl-n-butylcarbonyloxy group, a 2,2-dimethyl-n-butylcarbonyloxy group, a 2,3-dimethyl-n-butylcarbonyloxy group, a 3,3-dimethyl-n-butylcarbonyloxy group, a 1-ethyl-n-butylcarbonyloxy group, a 2-ethyl-n-butylcarbonyloxy group, a 1,1,2-trimethyl-n-propylcarbonyloxy group, a 1,2,2-trimethyl-n-propylcarbonyloxy group, a 1-ethyl-1-methyl-n-propylcarbonyloxy group, a 1-ethyl-2-methyl-n-propylcarbonyloxy group, a phenylcarbonyloxy group, a tosylcarbonyloxy group, and the like are included, but are not limited thereto.

In Formula (1) above, a represents 1, b represents an integer of 0 to 2, and 4-(a+b) represents an integer of 1 to 3.

b preferably represents 0 or 1, and more preferably 0.

Specific examples of the compound represented by Formula (1) above include silane compounds having a succinic anhydride skeleton such as [(3-trimethoxysilyl) propyl] succinic anhydride, [(3-triethoxysilyl) propyl] succinic anhydride, [(3-trimethoxysilyl) ethyl] succinic anhydride, [(3-trimethoxysilyl) butyl] succinic anhydride, and the like.

<<Silane Compound represented by Formula (2) (Hydrolyzable Silane)>>

The hydrolysis condensate used in the resist underlayer film forming composition of the present invention can be a product of hydrolysis condensation of a hydrolyzable silane mixture containing a silane compound represented by Formula (2) below.

[Chem. 20]

R⁴ₐR⁵_{b}Si(R⁶)₄—(a+b) (2)
R⁴ is a group bonded to a silicon atom and represents a monovalent group represented by Formula (2-1).

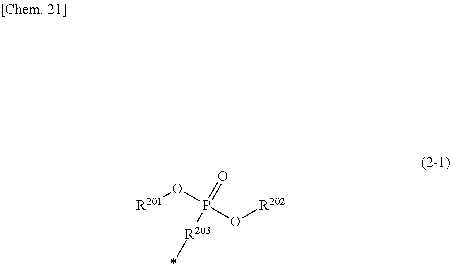

In Formula (2-1), R²⁰¹ to R²⁰² each independently represent a hydrogen atom or an organic group containing an optionally substituted alkyl group, R²⁰³ represents an optionally substituted alkylene group, and * represents a bond bonded to a silicon atom.

The optionally substituted alkyl group in the monovalent group represented by Formula (2-1) of R⁴ in Formula (2) is the same as the optionally substituted alkyl group described for R² in Formula (1) above.

Examples of the organic group containing the optionally substituted alkyl group include an optionally substituted alkyl group.

In Formula (2), the optionally substituted alkylene group in the monovalent group represented by Formula (2-1) of R⁴ refers to a divalent group derived by further removing one hydrogen atom from the optionally substituted alkyl group. It may be linear, branched, or cyclic.

Specific examples of the alkylene group include linear alkylene groups such as a methylene group, an ethylene group, a trimethylene group, a methylethylene group, a tetramethylene group, a pentamethylene group, a hexamethylene group, a heptamethylene group, an octamethylene group, a nonamethylene group, and a decamethylene group; branched alkylene groups such as a 1-methyltrimethylene group, a 2-methyltrimethylene group, a 1,1-dimethylethylene group, a 1-methyltetramethylene group, a 2-methyltetramethylene group, a 1,1-dimethyltrimethylene group, a 1,2-dimethyltrimethylene group, a 2,2-dimethyltrimethylene group, and a 1-ethyltrimethylene group; cyclic alkylene groups such as a 1,2-cyclopropypanediyl group, a 1,2-cyclobutanediyl group, a 1,3-cyclobutanediyl group, a 1,2-cyclohexanediyl group, and a 1,3-cyclohexanediyl group, the alkylene group including alkylene groups including ether groups such as —CH₂OCH₂—, —CH₂CH₂OCH₂—, —CH₂CH₂OCH₂CH₂—, —CH₂CH₂CH₂OCH₂CH₂—, —CH₂CH₂OCH₂CH₂CH₂—, —CH₂CH₂CH₂OCH₂CH₂CH₂—, —CH₂SCH₂—, —CH₂CH₂SCH₂—, —CH₂CH₂SCH₂CH₂—, —CH₂CH₂CH₂SCH₂CH₂—, —CH₂CH₂SCH₂CH₂CH₂—, —CH₂CH₂CH₂SCH₂CH₂CH₂—, and —CH₂OCH₂CH₂SCH₂—, but are not limited thereto.

In Formula (2), R⁵ is the same as R² in Formula (1) above.

In Formula (2), R⁶ is the same as R³ in Formula (1) above.

In Formula (2) above, a represents 1, b represents an integer of 0 to 2, and 4-(a+b) represents an integer of 1 to 3.

b preferably represents 0 or 1, and more preferably 0.

Specific examples of the compound represented by Formula (2) above include silane compounds containing an alkylphosphonic acid such as [3-(triethoxysilyl) ethyl] phosphonic acid diethyl ester.

<<Silane Compound represented by Formula (3) (Hydrolyzable Silane)>>

The hydrolysis condensate used in the resist underlayer film forming composition of the present invention may further contain a hydrolyzable silane represented by Formula (3) below.

[Chem. 22]

R⁷ₐR⁸_{b}Si(R⁹)₄—(a+b) (3)
R⁷ is a group bonded to a silicon atom, and represents an organic group containing an alkenyl group.

The organic group of the R⁷ is not particularly limited as long as it is an organic group containing the above group.

Examples of the organic group containing an alkenyl group include not only the alkenyl group itself but also an organic group in which one or more hydrogen atoms in an alkyl group are substituted with an alkenyl group.

Examples of the alkenyl group for R⁷ include an optionally substituted alkenyl group as described for R² in Formula (1), and examples thereof include an alkenyl group having 2 to 10 carbon atoms. More specific examples thereof include an ethenyl group (vinyl group), a 1-propenyl group, a 2-propenyl group, a 1-methyl-1-ethenyl group, a 1-butenyl group, a 2-butenyl group, a 3-butenyl group, a 2-methyl-1-propenyl group, a 2-methyl-2-propenyl group, a 1-ethylethenyl group, a 1-methyl-1-propenyl group, a 1-methyl-2-propenyl group, a 1-pentenyl group, a 2-pentenyl group, a 3-pentenyl group, a 4-pentenyl group, a 1-n-propylethenyl group, a 1-methyl-1-butenyl group, a 1-methyl-2-butenyl group, a 1-methyl-3-butenyl group, a 2-ethyl-2-propenyl group, a 2-methyl-1-butenyl group, a 2-methyl-2-butenyl group, a 2-methyl-3-butenyl group, a 3-methyl-1-butenyl group, a 3-methyl-2-butenyl group, a 3-methyl-3-butenyl group, a 1,1-dimethyl-2-propenyl group, a 1-i-propylethenyl group, a 1,2-dimethyl-1-propenyl group, a 1,2-dimethyl-2-propenyl group, a 1-cyclopentenyl group, a 2-cyclopentenyl group, a 3-cyclopentenyl group, a 1-hexenyl group, a 2-hexenyl group, a 3-hexenyl group, a 4-hexenyl group, a 5-hexenyl group, a 1-methyl-1-pentenyl group, a 1-methyl-2-pentenyl group, a 1-methyl-3-pentenyl group, a 1-methyl-4-pentenyl group, a 1-n-butylethenyl group, a 2-methyl-1-pentenyl group, a 2-methyl-2-pentenyl group, a 2-methyl-3-pentenyl group, a 2-methyl-4-pentenyl group, a 2-n-propyl-2-propenyl group, a 3-methyl-1-pentenyl group, a 3-methyl-2-pentenyl group, a 3-methyl-3-pentenyl group, a 3-methyl-4-pentenyl group, a 3-ethyl-3-butenyl group, a 4-methyl-1-pentenyl group, a 4-methyl-2-pentenyl group, a 4-methyl-3-pentenyl group, a 4-methyl-4-pentenyl group, a 1,1-dimethyl-2-butenyl group, a 1,1-dimethyl-3-butenyl group, a 1,2-dimethyl-1-butenyl group, a 1,2-dimethyl-2-butenyl group, a 1,2-dimethyl-3-butenyl group, a 1-methyl-2-ethyl-2-propenyl group, a 1-s-butylethenyl group, a 1,3-dimethyl-1-butenyl group, a 1,3-dimethyl-2-butenyl group, a 1,3-dimethyl-3-butenyl group, a 1-i-butylethenyl group, a 2,2-dimethyl-3-butenyl group, a 2,3-dimethyl-1-butenyl group, a 2,3-dimethyl-2-butenyl group, a 2,3-dimethyl-3-butenyl group, a 2-i-propyl-2-propenyl group, a 3,3-dimethyl-1-butenyl group, a 1-ethyl-1-butenyl group, a 1-ethyl-2-butenyl group, a 1-ethyl-3-butenyl group, a 1-n-propyl-1-propenyl group, a 1-n-propyl-2-propenyl group, a 2-ethyl-1-butenyl group, a 2-ethyl-2-butenyl group, a 2-ethyl-3-butenyl group, a 1,1,2-trimethyl-2-propenyl group, a 1-t-butylethenyl group, a 1-methyl-1-ethyl-2-propenyl group, a 1-ethyl-2-methyl-1-propenyl group, a 1-ethyl-2-methyl-2-propenyl group, a 1-i-propyl-1-propenyl group, a 1-i-propyl-2-propenyl group, a 1-methyl-2-cyclopentenyl group, a 1-methyl-3-cyclopentenyl group, a 2-methyl-1-cyclopentenyl group, a 2-methyl-2-cyclopentenyl group, a 2-methyl-3-cyclopentenyl group, a 2-methyl-4-cyclopentenyl group, a 2-methyl-5-cyclopentenyl group, a 2-methylene-cyclopentyl group, a 3-methyl-1-cyclopentenyl group, a 3-methyl-2-cyclopentenyl group, a 3-methyl-3-cyclopentenyl group, a 3-methyl-4-cyclopentenyl group, a 3-methyl-5-cyclopentenyl group, a 3-methylene-cyclopentyl group, a 1-cyclohexenyl group, a 2-cyclohexenyl group, a 3-cyclohexenyl group, and the like, and bridged cyclic alkenyl groups such as a bicycloheptenyl group (norbornyl group) are also included.

Among the above, R⁷ is preferably a group containing a vinyl group.

In Formula (3), R⁸ is the same as R² in Formula (1) above.

In Formula (3), R⁹ is the same as R³ in Formula (1) above.

In Formula (3) above, a represents 1, b represents an integer of 0 to 2, and 4-(a+b) represents an integer of 1 to 3.

b preferably represents 0 or 1, and more preferably 0.

Specific examples of the compound represented by Formula (3) above include silane compounds containing an alkenyl group (vinyl group) such as vinyltrimethoxysilane, vinyltriethoxysilane, vinyltrichlorosilane, vinyltriacetoxysilane, methylvinyldimethoxysilane, methylvinyldiethoxysilane, methylvinyldichlorosilane, methylvinyldiacetoxysilane, dimethylvinylmethoxysilane, dimethylvinylethoxysilane, dimethylvinylchlorosilane, dimethylvinylacetoxysilane, divinyldimethoxysilane, divinyldiethoxysilane, divinyldichlorosilane, divinyldiacetoxysilane, γ-glycidoxypropylvinyldimethoxysilane, γ-glycidoxypropylvinyldiethoxysilane, allyltrimethoxysilane, allyltriethoxysilane, allyltrichlorosilane, allyltriacetoxysilane, allylmethyldimethoxysilane, allylmethyldiethoxysilane, allylmethyldichlorosilane, allylmethyldiacetoxysilane, allyldimethylmethoxysilane, allyldimethylethoxysilane, allyldimethylchlorosilane, allyldimethylacetoxysilane, diallyldimethoxysilane, diallyldiethoxysilane, diallyldichlorosilane, diallyldiacetoxysilane, 3-allylaminopropyltrimethoxysilane, 3-allylaminopropyltriethoxysilane, p-styryltrimethoxysilane.

<<Silane Compound represented by Formula (4) (Hydrolyzable Silane)>>

The hydrolysis condensate used in the resist underlayer film forming composition of the present invention may further contain a hydrolyzable silane represented by Formula (4) below.

[Chem. 23]

Si(R¹⁰)₄ (4)
R¹⁰ is a group or atom bonded to a silicon atom, and independently of one another represents an alkoxy group, an aralkyloxy group, an acyloxy group, or a halogen atom.

Specific examples of the alkoxy group, the aralkyloxy group, and the acyloxy group include the same groups as those described above.

Specific examples of the hydrolyzable silane represented by Formula (4) include tetramethoxysilane, tetrachlorosilane, tetraacetoxysilane, tetraethoxysilane, tetra-n-propoxysilane, tetra-i-propoxysilane, and tetra-n-butoxysilane.

It is preferable to use a tetrafunctional silane such as tetramethoxysilane or tetraethoxysilane represented by Formula (4) from the viewpoint of improving the crosslinking density of the film obtained from the composition of the present invention, suppressing diffusion of components of the resist film into the obtained film, and maintaining and improving the resist characteristics of the resist film.

<<Silane Compound represented by Formula (5) (Hydrolyzable Silane)>>

The hydrolysis condensate used in the resist underlayer film forming composition of the present invention may further contain a hydrolyzable silane represented by Formula (5) below.

[Chem. 24]

R¹¹ₐR¹²_{b}Si(R¹³)₄—(a+b) (5)

R¹¹ is a group bonding to a silicon atom, and represents an organic group containing at least one kind of group selected from the group consisting of an aryl group, an optionally substituted amino group, and a group represented by Formula (5-2) described later.

The organic group of the R¹¹ is not particularly limited as long as it is an organic group containing the above group.

Examples of the organic group including an aryl group and a group represented by Formula (5-2) described later include not only the group itself but also an organic group in which one or more hydrogen atoms in the alkyl group are substituted with at least one selected from the group consisting of an aryl group and a group represented by Formula (5-2) described later.

In addition, preferred examples of the substituent in the optionally substituted amino group defined by R¹¹ include an alkyl group. In particular, an alkyl group having 1 to 4 carbon atoms is preferably substituted.

Examples of the aryl group in R¹¹ include an optionally substituted aryl group, and examples thereof include an aryl group having 6 to 20 carbon atoms. As described for R² of Formula (1) above, more specific examples of the aryl group include a phenyl group, an o-methylphenyl group, a m-methylphenyl group, a p-methylphenyl group, an o-chlorophenyl group, a m-chlorophenyl group, a p-chlorophenyl group, an o-fluorophenyl group, a p-mercaptophenyl group, an o-methoxyphenyl group, a p-methoxyphenyl group, a p-aminophenyl group, a p-cyanophenyl group, an α-naphthyl group, a β-naphthyl group, an o-biphenylyl group, a m-biphenylyl group, a p-biphenylyl group, a 1-anthryl group, a 2-anthryl group, a 9-anthryl group, a 1-phenanthryl group, a 2-phenanthryl group, a 3-phenanthryl group, a 4-phenanthryl group, and a 9-phenanthryl group.

In addition, examples of the group containing the aryl group include an optionally substituted aralkyl group, an optionally substituted halogenated aryl group, an optionally substituted halogenated aralkyl group, an optionally substituted alkoxyaryl group, and an optionally substituted alkoxyaralkyl group.

The aralkyl group is an alkyl group substituted with an aryl group, and specific examples of such an aryl group and an alkyl group include the same groups as those described above.

The number of carbon atoms of the aralkyl group is not particularly limited, but is preferably 40 or less, more preferably 30 or less, and still more preferably 20 or less.

As described for R² of Formula (1) above, specific examples of the aralkyl group include a phenylmethyl group (benzyl group), a 2-phenylethylene group, a 3-phenyl-n-propyl group, a 4-phenyl-n-butyl group, a 5-phenyl-n-pentyl group, a 6-phenyl-n-hexyl group, a 7-phenyl-n-heptyl group, an 8-phenyl-n-octyl group, a 9-phenyl-n-nonyl group, a 10 phenyl-n-decyl group, and the like, but are not limited thereto.

The halogenated aryl group is an aryl group substituted with a halogen atom, and specific examples of such an aryl group include the same groups as those described above.

Examples of the halogen atom in the present invention include a fluorine atom, a chlorine atom, a bromine atom, and an iodine atom.

The number of carbon atoms of the halogenated aryl group is not particularly limited, but is preferably 40 or less, more preferably 30 or less, and still more preferably 20 or less.

As described for R² of Formula (1) above, specific examples of the halogenated aryl group include a 2-fluorophenyl group, a 3-fluorophenyl group, a 4-fluorophenyl group, a 2,3-difluorophenyl group, a 2,4-difluorophenyl group, a 2,5-difluorophenyl group, a 2,6-difluorophenyl group, a 3,4-difluorophenyl group, a 3,5-difluorophenyl group, a 2,3,4-trifluorophenyl group, a 2,3,5-trifluorophenyl group, a 2,3,6-trifluorophenyl group, a 2,4,5-trifluorophenyl group, a 2,4,6-trifluorophenyl group, a 3,4,5-trifluorophenyl group, a 2,3,4,5-tetrafluorophenyl group, a 2,3,4,6-tetrafluorophenyl group, a 2,3,5,6-tetrafluorophenyl group, a pentafluorophenyl group, a 2-fluoro-1-naphthyl group, a 3-fluoro-1-naphthyl group, a 4-fluoro-1-naphthyl group, a 6-fluoro-1-naphthyl group, a 7-fluoro-1-naphthyl group, an 8-fluoro-1-naphthyl group, a 4,5-difluoro-1-naphthyl group, a 5,7-difluoro-1-naphthyl group, a 5,8-difluoro-1-naphthyl group, a 5,6,7,8-tetrafluoro-1-naphthyl group, a heptafluoro-1-naphthyl group, a 1-fluoro-2-naphthyl group, a 5-fluoro-2-naphthyl group, a 6-fluoro-2-naphthyl group, a 7-fluoro-2-naphthyl group, a 5,7-difluoro-2-naphthyl group, a heptafluoro-2-naphthyl group, and the like, but are not limited thereto.

The halogenated aralkyl group is an aralkyl group substituted with a halogen atom, and specific examples of such aralkyl group and halogen atom include the same groups as those described above.

The number of carbon atoms of the halogenated aralkyl group is not particularly limited, but is preferably 40 or less, more preferably 30 or less, and still more preferably 20 or less.

As described for R² of Formula (1) above, specific examples of the halogenated aralkyl group include a 2-fluorobenzyl group, a 3-fluorobenzyl group, a 4-fluorobenzyl group, a 2,3-difluorobenzyl group, a 2,4-difluorobenzyl group, a 2,5-difluorobenzyl group, a 2,6-difluorobenzyl group, a 3,4-difluorobenzyl group, a 3,5-difluorobenzyl group, a 2,3,4-trifluorobenzyl group, a 2,3,5-trifluorobenzyl group, a 2,3,6-trifluorobenzyl group, a 2,4,5-trifluorobenzyl group, a 2,4,6-trifluorobenzyl group, a 2,3,4,5-tetrafluorobenzyl group, a 2,3,4,6-tetrafluorobenzyl group, a 2,3,5,6-tetrafluorobenzyl group, a 2,3,4,5,6-pentafluorobenzyl group, and the like, but are not limited thereto.

The alkoxyaryl group is an aryl group substituted with an alkoxy group, and specific examples of such an alkoxy group and aryl group include the same groups as those described above.

The number of carbon atoms of the alkoxyaryl group is not particularly limited, but is preferably 40 or less, more preferably 30 or less, and still more preferably 20 or less.

As described for R² in Formula (1) above, specific examples of the alkoxyaryl group include a 2-methoxyphenyl group, a 3-methoxyphenyl group, a 4-methoxyphenyl group, a 2-(1-ethoxy) phenyl group, a 3-(1-ethoxy) phenyl group, a 4-(1-ethoxy) phenyl group, a 2-(2-ethoxy) phenyl group, a 3-(2-ethoxy) phenyl group, a 4-(2-ethoxy) phenyl group, a 2-methoxynaphthalene-1-yl group, a 3-methoxynaphthalene-1-yl group, a 4-methoxynaphthalene-1-yl group, a 5-methoxynaphthalene-1-yl group, a 6-methoxynaphthalene-1-yl group, a 7-methoxynaphthalene-1-yl group, and the like, but are not limited thereto.

The alkoxyaralkyl group is an aralkyl group substituted with an alkoxy group, and specific examples of such an alkoxy group and aralkyl group include the same groups as those described above.

The number of carbon atoms of the alkoxyaralkyl group is not particularly limited, but is preferably 40 or less, more preferably 30 or less, and still more preferably 20 or less.

Specific examples of the alkoxyaralkyl group include a 3-(methoxyphenyl) benzyl group and a 4-(methoxyphenyl) benzyl group, but are not limited thereto.

In addition, examples of the optionally substituted amino group in the R¹¹ include an amino group or an alkylamino group substituted with an alkyl group having 1 to 4 carbon atoms. More specific examples include an amino group, an aminomethyl group, an aminoethyl group, a dimethylaminoethyl group, and a dimethylaminopropyl group.

In addition, as the group represented by Formula (5-2) below in the R¹¹,

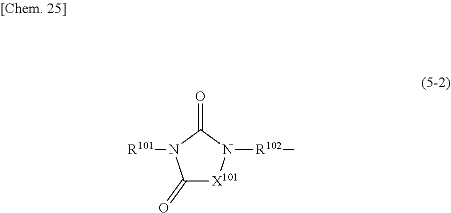

wherein X₁₀₁ independently of one another represents any one of Formulae (5-3) to (5-5) below, and the carbon atom of the ketone group in Formulae (5-4) and (5-5) below is bonded to the nitrogen atom to which R¹⁰² in Formula (5-2) is bonded.

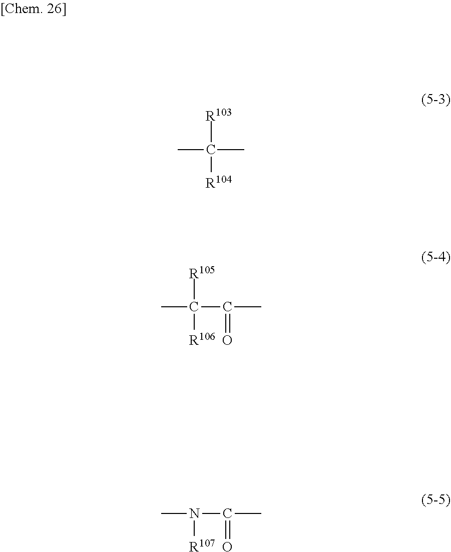

In Formulae (5-3) to (5-5), R¹⁰³ to R¹⁰⁷ each independently represent a hydrogen atom, an optionally substituted alkyl group, an optionally substituted alkenyl group, or an organic group containing an epoxy group or a sulfonyl group, and specific examples of the optionally substituted alkyl group and the optionally substituted alkenyl group, and suitable numbers of carbon atoms and the like are the same as alkyl group mentioned as the alkyl group in which a hydrogen atom is substituted by a succinic anhydride skeleton or the like and those mentioned above as the alkenyl group for R¹.

Examples of the organic group containing an epoxy group include a glycidoxymethyl group, a glycidoxyethyl group, a glycidoxypropyl group, a glycidoxybutyl group, an epoxy cyclohexyl group, and the like, but are not limited thereto.

Examples of the organic group containing a sulfonyl group include a sulfonylalkyl group, a sulfonylaryl group, and the like, but are not limited thereto.

In Formula (5-2) above, R¹⁰¹ independently of one another represents a hydrogen atom, an optionally substituted alkyl group, an optionally substituted alkenyl group, or an organic group containing an epoxy group or a sulfonyl group, and R¹⁰² independently of one another represents an alkylene group, a hydroxyalkylene group, a sulfide bond (—S—), an ether bond (—O—), or an ester bond (—C(═O)—O— or —O—C(═O)—).

Here, specific examples of the organic group including an optionally substituted alkyl group, an optionally substituted alkenyl group, an epoxy group, or an epoxy group, suitable carbon atom numbers, and the like are the same as those described above for R¹⁰³ to R¹⁰⁷. Besides these, the optionally substituted alkyl group is preferably an alkyl group in which a terminal hydrogen atom is substituted with a vinyl group, and specific examples thereof include an allyl group, a 2-vinylethyl group, a 3-vinylpropyl group, and a 4-vinylbutyl group.

The alkylene group is a divalent group derived by further removing one hydrogen atom from the alkyl group, and may be linear, branched, or cyclic, and the number of carbon atoms of the alkylene group is not particularly limited, but is preferably 40 or less, more preferably 30 or less, still more preferably 20 or less, and still more preferably 10 or less.

In addition, the alkylene group of R¹⁰² may have one or two or more selected from a sulfide bond, an ether bond, and an ester bond at the end or in the middle, preferably in the middle.

Specific examples of the alkylene group include linear alkylene groups such as a methylene group, an ethylene group, a trimethylene group, a methylethylene group, a tetramethylene group, a pentamethylene group, a hexamethylene group, a heptamethylene group, an octamethylene group, a nonamethylene group, and a decamethylene group; branched alkylene groups such as a 1-methyltrimethylene group, a 2-methyltrimethylene group, a 1,1-dimethylethylene group, a 1-methyltetramethylene group, a 2-methyltetramethylene group, a 1,1-dimethyltrimethylene group, a 1,2-dimethyltrimethylene group, a 2,2-dimethyltrimethylene group, and a 1-ethyltrimethylene group; cyclic alkylene groups such as a 1,2-cyclopropypanediyl group, a 1,2-cyclobutanediyl group, a 1,3-cyclobutanediyl group, a 1,2-cyclohexanediyl group, and a 1,3-cyclohexanediyl group, the alkylene group including alkylene groups including ether groups such as —CH₂OCH₂—, —CH₂CH₂OCH₂—, —CH₂CH₂OCH₂CH₂—, —CH₂CH₂CH₂OCH₂CH₂—, —CH₂CH₂OCH₂CH₂CH₂—, —CH₂CH₂CH₂OCH₂CH₂CH₂—, —CH₂SCH₂—, —CH₂CH₂SCH₂—, —CH₂CH₂SCH₂CH₂—, —CH₂CH₂CH₂SCH₂CH₂—, —CH₂CH₂SCH₂CH₂CH₂—, —CH₂CH₂CH₂SCH₂CH₂CH₂—, and —CH₂OCH₂CH₂SCH₂—, but are not limited thereto.

The hydroxyalkylene group is one in which at least one of hydrogen atoms of the alkylene group is replaced with a hydroxy group, and specific examples thereof include a hydroxymethylene group, a 1-hydroxyethylene group, a 2-hydroxyethylene group, a 1,2-dihydroxyethylene group, a 1-hydroxytrimethylene group, a 2-hydroxytrimethylene group, a 3-hydroxytrimethylene group, a 1-hydroxytetramethylene group, a 2-hydroxytetramethylene group, a 3-hydroxytetramethylene group, a 4-hydroxytetramethylene group, a 1,2-dihydroxytetramethylene group, a 1,3-dihydroxytetramethylene group, a 1,4-dihydroxytetramethylene group, a 2,3-dihydroxytetramethylene group, a 2,4-dihydroxytetramethylene group, a 4,4-dihydroxytetramethylene group, and the like, but are not limited thereto.

Among the above, R¹¹ is preferably a group containing at least one selected from the group consisting of a phenyl group, a diaminopropyl group, and an isocyanuric acid skeleton (in Formula (5-2), X₁₀₁ represents a group represented by Formula (5-5)).

In Formula (5), R¹² is the same as R² in Formula (1) above.

In Formula (5), R¹³ is the same as R³ in Formula (1) above.

In Formula (5) above, a represents 1, b represents an integer of 0 to 2, and 4-(a+b) represents an integer of 1 to 3.

b preferably represents 0 or 1, and more preferably 0.

Specific examples of the compound represented by Formula (5) above include silane compounds containing phenyl groups such as phenyltrimethoxysilane, phenyltriethoxysilane, phenyltrichlorosilane, phenyltriacetoxysilane, phenylmethyldimethoxysilane, phenylmethyldiethoxysilane, phenylmethyldichlorosilane, phenylmethyldiacetoxysilane, phenyldimethylmethoxysilane, phenyldimethylethoxysilane, phenyldimethylchlorosilane, phenyldimethylacetoxysilane, diphenylmethylmethoxysilane, diphenylmethylethoxysilane, diphenylmethylchlorosilane, diphenylmethylacetoxysilane, diphenyldimethoxysilane, diphenyldiethoxysilane, diphenyldichlorosilane, diphenyldiacetoxysilane, triphenylmethoxy sisilane, triphenylethoxysilane, triphenylacetoxysilane, triphenylchlorosilane, 3-phenylaminopropyltrimethoxysilane, 3-phenylaminopropyltriethoxysilane, dimethoxymethyl-3-(3-phenoxypropylthiopropyl) silane, benzyltrimethoxysilane, benzyltriethoxysilane, benzylmethyldimethoxysilane, benzylmethyldiethoxysilane, benzyldimethylmethoxysilane, benzyldimethylethoxysilane, benzyldimethylchlorosilane, phenethyltrimethoxysilane, phenethyltriethoxysilane, phenethyltrichlorosilane, phenethyl triacetoxysilane, phenethylmethyldimethoxysilane, phenethylmethyldiethoxysilane, phenethylmethyldichlorosilane, or phenethylmethyldiacetoxysilane; silane compounds containing substituted aryl groups such as methoxyphenyltrimethoxysilane, methoxyphenyltriethoxysilane, methoxyphenyltriacetoxysilane, methoxyphenyltrichlorosilane, methoxybenzyltrimethoxysilane, methoxybenzyltriethoxysilane, methoxybenzyltriacetoxysilane, methoxybenzyltrichlorosilane, methoxyphenethyltrimethoxysilane, methoxyphenethyltriethoxysilane, methoxyphenethyltriacetoxysilane, methoxyphenethyltrichlorosilane, ethoxyphenyltrimethoxysilane, ethoxyphenyltriethoxysilane, ethoxyphenyltriacetoxysilane, ethoxyphenyltrichlorosilane, ethoxybenzyltrimethoxysilane, ethoxybenzyltriethoxysilane, ethoxybenzyltriacetoxysilane, ethoxybenzyltrichlorosilane, i-propoxyphenyltrimethoxysilane, i-propoxyphenyltriethoxysilane, i-propoxyphenyltriacetoxysilane, i-propoxyphenyltrichlorosilane, i-propoxybenzyltrimethoxysilane, i-propoxybenzyltriethoxysilane, i-propoxybenzyltriacetoxysilane, i-propoxybenzyltrichlorosilane, t-butoxyphenyltrimethoxysilane, t-butoxyphenyltriethoxysilane, t-butoxyphenyltriacetoxysilane, t-butoxyphenyltrichlorosilane, t-butoxybenzyltrimethoxysilane, t-butoxybenzyltriethoxysilane, t-butoxybenzyltriacetoxysilane, t-butoxyxybenzyltrichlorosilane, methoxynaphthyltrimethoxysilane, methoxynaphthyltriethoxysilane, methoxynaphthyltriacetoxysilane, methoxynaphthyltrichlorosilane, ethoxynaphthyltrimethoxysilane, ethoxynaphthyltriethoxysilane, ethoxynaphthyltriacetoxysilane, or ethoxynaphthyltrichlorosilane; dimethylaminopropyltrimethoxysilane; and the like.

In addition, as a specific example of the silane compound represented by Formula (5) above, a commercially available product may be used as the silane compound in which R¹¹ in the formula is an organic group containing a group represented by Formula (5-2) above, and the silane compound can be synthesized by a known method described in WO 2011/102470 A and the like.

Hereinafter, as specific examples of the silane compound containing an organic group containing the group represented by Formula (5-2), the compounds represented below may be mentioned, but the compounds are not limited thereto.

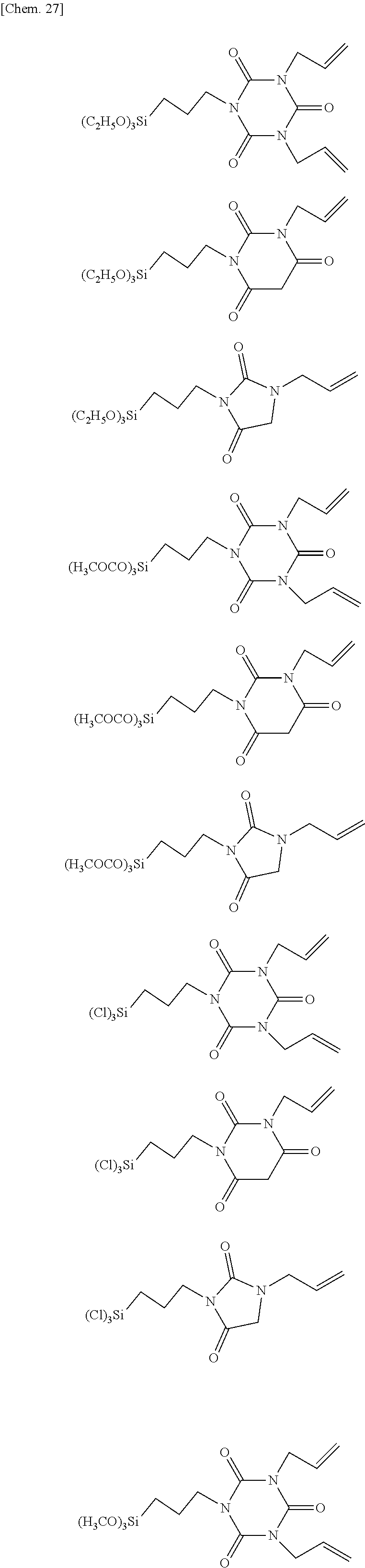

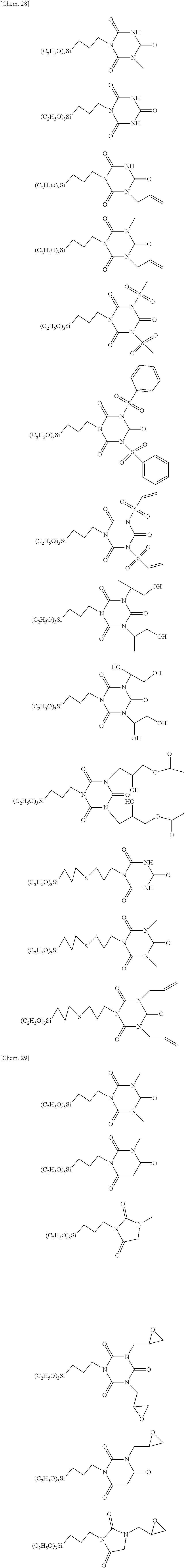

Furthermore, examples of the silane compound represented by Formula (5) include aryl group-containing silane compounds represented by Formulae (A-1) to (A-41).

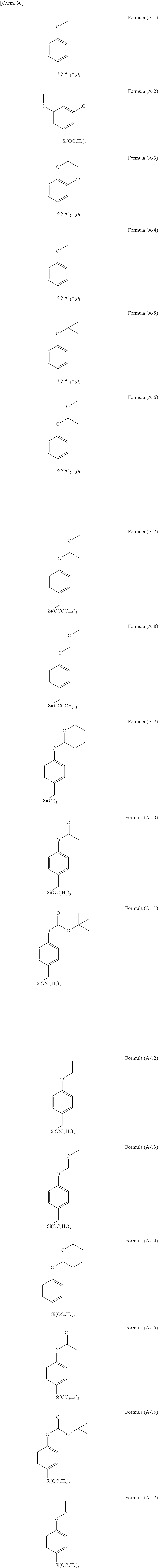

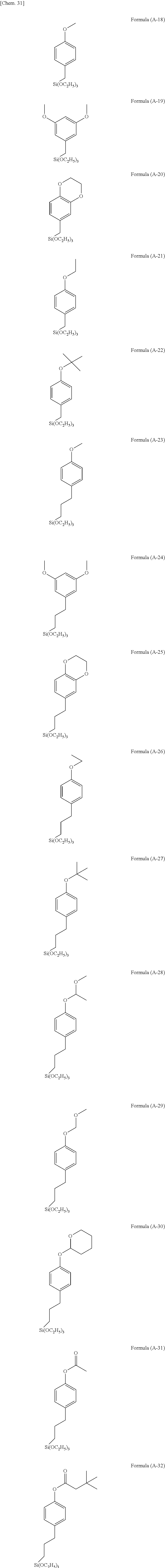

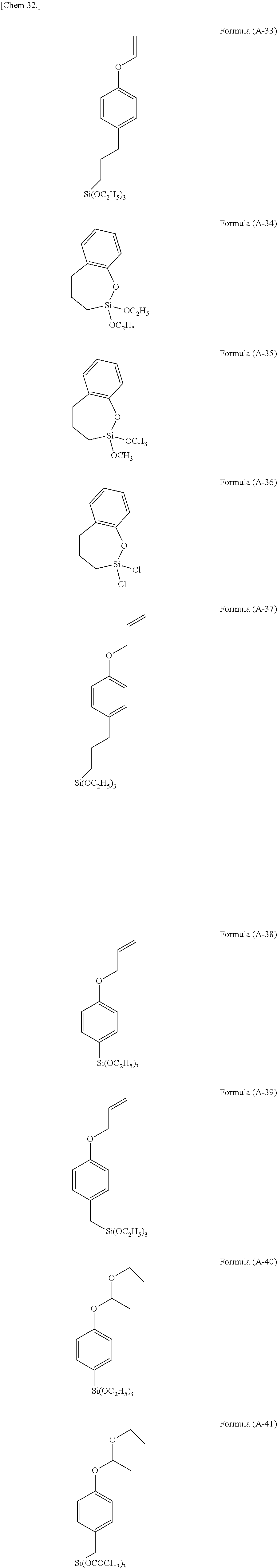

### <<Other Silane Compounds (Hydrolycable Silane)>>

In the present invention, for the purpose of adjusting film physical properties such as film density, other silane compounds represented by Formula (6) below (other hydrolyzable silane) can be used in the hydrolysable silane mixture together with the silane compound represented by Formula (1) or (2) or, if desired, (3), (4), or (5).

[Chem. 33]

R¹⁴_{c}Si(R¹⁵)_{4-c} (6)

In Formula (6), R¹⁴ is a group bonded to a silicon atom, and independently of one another represents an optionally substituted alkyl group, an optionally substituted halogenated alkyl group, or an optionally substituted alkoxyalkyl group, or represents an organic group containing an epoxy group, an acryloyl group, a methacryloyl group, a mercapto group, an amide group, an alkoxy group, a sulfonyl group, or a cyano group, or a combination of these.

In addition, R¹⁵ is a group or atom bonded to a silicon atom, and independently of one another represents an alkoxy group, an aralkyloxy group, an acyloxy group, or a halogen atom.

c represents an integer of 1 to 3.

Specific examples of the groups in the R¹⁴ and the suitable number of carbon atoms thereof include the groups and the number of carbon atoms described above for R².

Specific examples of the groups in the R¹⁵ and the suitable number of carbon atoms thereof can include the groups and atoms and the number of carbon atoms described above for R³.

Specific examples of the hydrolyzable silane represented by Formula (6) include methyltrimethoxysilane, methyltrichlorosilane, methyltriacetoxysilane, methyltriethoxysilane, methyltripropoxysilane, methyltributoxysilane, methyltriamyloxysilane, methyltribenzyloxysilane, methyltriphenethyloxysilane, glycidoxymethyltrimethoxysilane, glycidoxymethyltriethoxysilane, α-glycidoxyethyltrimethoxysilane, α-glycidoxyethyltriethoxysilane, β-glycidoxyethyltrimethoxysilane, β-glycidoxyethyltriethoxysilane, α-glycidoxypropyltrimethoxysilane, α-glycidoxypropyltriethoxysilane, β-glycidoxypropyltrimethoxysilane, β-glycidoxypropyltriethoxysilane, γ-glycidoxypropyltrimethoxysilane, γ-glycidoxypropyltriethoxysilane, γ-glycidoxypropyltripropoxysilane, γ-glycidoxypropyltributoxysilane, α-glycidoxybutyltrimethoxysilane, α-glycidoxybutyltriethoxysilane, β-glycidoxybutyltriethoxysilane, γ-glycidoxybutyltrimethoxysilane, γ-glycidoxybutyltriethoxysilane, δ-glycidoxybutyltrimethoxysilane, δ-glycidoxybutyltriethoxysilane, (3,4-epoxycyclohexyl) methyltrimethoxysilane, (3,4-epoxycyclohexyl) methyltriethoxysilane, β-(3,4-epoxycyclohexyl) ethyltrimethoxysilane, β-(3,4-epoxycyclohexyl) ethyltriethoxysilane, β-(3,4-epoxycyclohexyl) ethyltripropoxysilane, β-(3,4-epoxycyclohexyl) ethyltributoxysilane, γ-(3,4-epoxycyclohexyl) propyltrimethoxysilane, γ-(3,4-epoxycyclohexyl) propyltriethoxysilane, δ-(3,4-epoxycyclohexyl) butyltrimethoxysilane, δ-(3,4-epoxycyclohexyl) butyltriethoxysilane, glycidoxymethylmethyldimethoxysilane, glycidoxymethylmethyldiethoxysilane, α-glycidoxyethylmethyldimethoxysilane, α-glycidoxyethylmethyldiethoxysilane, β-glycidoxyethylmethyldimethoxysilane, β-glycidoxyethylethyldimethoxysilane, α-glycidoxypropylmethyldimethoxysilane, α-glycidoxypropylmethyldiethoxysilane, β-glycidoxypropylmethyldimethoxysilane, β-glycidoxypropylethyldimethoxysilane, γ-glycidoxypropylmethyldimethoxysilane, γ-glycidoxypropylmethyldiethoxysilane, γ-glycidoxypropylmethyldipropoxysilane, γ-glycidoxypropylmethyldibutoxysilane, γ-glycidoxypropylethyldimethoxysilane, γ-glycidoxypropylethyldiethoxysilane, ethyltrimethoxysilane, ethyltriethoxysilane, γ-chloropropyltrimethoxysilane, γ-chloropropyltriethoxysilane, γ-chloropropyltriacetoxysilane, 3,3,3-trifluoropropyltrimethoxysilane, γ-methacryloxypropyltrimethoxysilane, γ-mercaptopropyltrimethoxysilane, γ-mercaptopropyltriethoxysilane, β-cyanoethyltriethoxysilane, chloromethyltrimethoxysilane, chloromethyltriethoxysilane, Bicyclo(2,2,1) heptenyltriethoxysilane, benzenesulfonylpropyltriethoxysilane, benzenesulfonamidopropyltriethoxysilane, dimethyldimethoxysilane, dimethyldiethoxysilane, γ-chloropropylmethyldimethoxysilane, γ-chloropropylmethyldiethoxysilane, dimethyldiacetoxysilane, γ-methacryloxypropylmethyldimethoxysilane, γ-methacryloxypropylmethyldiethoxysilane, γ-mercaptopropylmethyldimethoxysilane, γ-mercaptomethyldiethoxysilane, and the like, but are not limited thereto.

In addition to the above examples, the hydrolyzable silane mixture may contain other silane compounds (hydrolyzable silane) other than the above examples as long as the effects of the present invention are not impaired.

As described above, the resist underlayer film forming composition of the present invention contains a hydrolysis condensate of the hydrolyzable silane mixture.

In a preferred aspect of the present invention, the resist underlayer film forming composition of the present invention contains at least a hydrolysis condensate of the hydrolyzable silane mixture.

In a preferred aspect of the present invention, the hydrolysis condensate contained in the resist underlayer film forming composition of the present invention contains, in addition to the silane represented by Formula (1) or Formula (2), a hydrolysis condensate obtained using, as desired, a hydrolyzable silane represented by Formula (3), a hydrolyzable silane represented by Formula (4), a hydrolyzable silane represented by Formula (5), another hydrolyzable silane represented by Formula (6), or another hydrolyzable silane other than those represented by these formulae.

In a case where the silane compound represented by Formula (1) is used in the hydrolyzable silane mixture, the charged amount of the silane compound represented by Formula (1) can be, for example, 0.1 to 30 mol % with respect to 100 mol % of the charged amount of all silane compounds (hydrolyzable silane) contained in the hydrolyzable silane mixture.

In a case where the silane compound represented by Formula (2) is used in the hydrolyzable silane mixture, the charged amount of the silane compound represented by Formula (2) can be, for example, 0.1 to 30 mol % with respect to 100 mol % of the charged amount of all silane compounds (hydrolyzable silane) contained in the hydrolyzable silane mixture.

In a case where the silane compound represented by Formula (3) is used in the hydrolyzable silane mixture, the charged amount of the silane compound represented by Formula (3) can be, for example, 15 to 50 mol % with respect to 100 mol % of the charged amount of all silane compounds (hydrolyzable silane) contained in the hydrolyzable silane mixture.

In a case where the silane compound represented by Formula (4) is used in the hydrolyzable silane mixture, the charged amount of the silane compound represented by Formula (4) can be, for example, 30 to 70 mol % or 25 to 45 mol % with respect to 100 mol % of the charged amount of all silane compounds (hydrolyzable silane) contained in the hydrolyzable silane mixture.

In a case where the silane compound represented by Formula (5) is used in the hydrolyzable silane mixture (for example, in the case of using a silane compound in which R¹¹ is an aryl group in Formula (5)), the charged amount of the silane compound represented by Formula (5) can be, for example, 0.01 to 5 mol % with respect to 100 mol % of the charged amount of all silane compounds (hydrolyzable silane) contained in the hydrolyzable silane mixture.

The weight average molecular weight of the hydrolysis condensate of the hydrolyzable silane mixture can be, for example, 500 to 1,000,000. From the viewpoint of suppressing precipitation of the hydrolysis condensate in the composition and the like, the weight average molecular weight can be preferably 500,000 or less, more preferably 250,000 or less, and still more preferably 100,000 or less, and from the viewpoint of achieving both storage stability and coatability, the weight average molecular weight can be preferably 700 or more, and more preferably 1,000 or more.

The weight average molecular weight is a molecular weight obtained in terms of polystyrene by GPC analysis. The GPC analysis can be performed using, for example, a GPC apparatus (Trade name: HLC-8220GPC, manufactured by Tosoh Corporation) or a GPC column (Trade name: Shodex (registered trademark) KF803L, KF802, KF801, manufactured by Showa Denko K.K.) at a column temperature of 40° C., using tetrahydrofuran as an eluent (elution solvent), at a flow rate (flow rate) of 1.0 mL/min, and using polystyrene (manufactured by Showa Denko K.K.) as a standard sample.

The hydrolysis condensate of the hydrolyzable silane mixture is obtained by hydrolyzing and condensing the above-described silane compound (hydrolyzable silane).

The silane compound (hydrolyzable silane) includes an alkoxy group directly bonded to a silicon atom, an aralkyloxy group, an acyloxy group, and a halogen atom, that is, an alkoxysilyl group, an aralkyloxysilyl group, an acyloxysilyl group, and a halogenated silyl group which are hydrolyzable groups.

For the hydrolysis of these hydrolyzable groups, usually 0.5 to 100 mol, preferably 1 to 10 mol of water is used per 1 mol of the hydrolyzable groups.

At the time of hydrolysis and condensation, a hydrolysis catalyst may be used for the purpose of accelerating the reaction, or hydrolysis and condensation may be performed without using a hydrolysis catalyst. In a case where the hydrolysis catalyst is used, usually 0.0001 to 10 mol, preferably 0.001 to 1 mol, of the hydrolysis catalyst can be used per 1 mol of the hydrolyzable group.

The reaction temperature at the time of performing hydrolysis and condensation is usually in a range of room temperature or higher and a reflux temperature of an organic solvent that can be used for hydrolysis at normal pressure or lower, and may be, for example, 20 to 110° C. or 20 to 80° C.

The hydrolysis is completely hydrolyzed, that is, all hydrolyzable groups may be changed to silanol groups, or partially hydrolyzed, that is, unreacted hydrolyzable groups may be left.

Examples of the hydrolysis catalyst that can be used in hydrolysis and condensation include metal chelate compounds, organic acids, inorganic acids, organic bases, and inorganic bases.

Examples of the metal chelate compound as the hydrolysis catalyst include titanium chelate compounds such as triethoxy mono(acetylacetonate) titanium, tri-n-propoxy mono(acetylacetonate) titanium, tri-i-propoxy mono(acetylacetonate) titanium, tri-n-butoxy mono(acetylacetonate) titanium, tri-sec-butoxy mono(acetylacetonate) titanium, tri-t-butoxy mono(acetylacetonate) titanium, diethoxy bis(acetylacetonate) titanium, di-n-propoxy bis(acetylacetonate) titanium, di-i-propoxy bis(acetylacetonate) titanium, di-n-butoxy bis(acetylacetonate) titanium, di-sec-butoxy bis(acetylacetonate) titanium, di-t-butoxy bis(acetylacetonate) titanium, monoethoxy tris(acetylacetonate) titanium, mono-n-propoxy tris(acetylacetonate) titanium, mono-i-propoxy tris(acetylacetonate) titanium, mono-n-butoxy tris(acetylacetonate) titanium, mono-sec-butoxy tris(acetylacetonate) titanium, mono-t-butoxy tris(acetylacetonate) titanium, tetrakis(acetylacetonate) titanium, triethoxy mono(ethyl acetoacetate) titanium, tri-n-propoxy mono(ethyl acetoacetate) titanium, tri-i-propoxy mono(ethyl acetoacetate) titanium, tri-n-butoxy mono(ethyl acetoacetate) titanium, tri-sec-butoxy mono(ethylacetoacetate) titanium, tri-t-butoxy mono(ethyl acetoacetate) titanium, diethoxy bis(ethyl acetoacetate) titanium, di-n-propoxy bis(ethyl acetoacetate) titanium, di-i-propoxy bis(ethyl acetoacetate) titanium, di-n-butoxy bis(ethyl acetoacetate) titanium, di-sec-butoxy bis(ethyl acetoacetate) titanium, di-t-butoxy bis(ethyl acetoacetate) titanium, monoethoxy tris(ethyl acetoacetate) titanium, mono-n-propoxy tris(ethyl acetoacetate) titanium, mono-i-propoxy tris(ethyl acetoacetate) titanium, mono-n-butoxy tris(ethyl acetoacetate) titanium, mono-sec-butoxy tris(ethyl acetoacetate) titanium, mono-t-butoxy tris(ethyl acetoacetate) titanium, tetrakis(ethyl acetoacetate) titanium, mono(acetylacetonate) tris(ethylacetoacetate) titanium, bis(acetylacetonate) bis(ethylacetoacetate) titanium, or tris(acetylacetonate) mono(ethylacetoacetate) titanium; zirconium chelate compounds such as triethoxy mono(acetylacetonate) zirconium, tri-n-propoxy mono(acetylacetonate) zirconium, tri-i-propoxy mono(acetylacetonate) zirconium, tri-n-butoxy mono(acetylacetonate) zirconium, tri-sec-butoxy mono(acetylacetonate) zirconium, tri-t-butoxy mono(acetylacetonate) zirconium, diethoxy bis(acetylacetonate) zirconium, di-n-propoxy bis(acetylacetonate) zirconium, di-i-propoxy bis(acetylacetonate) zirconium, di-n-butoxy bis(acetylacetonate) zirconium, di-sec-butoxy bis(acetylacetonate) zirconium, di-t-butoxy bis(acetylacetonate) zirconium, monoethoxy tris(acetylacetonate) zirconium, mono-n-propoxy tris(acetylacetonate) zirconium, mono-i-propoxy tris(acetylacetonate) zirconium, mono-n-butoxy tris(acetylacetonate) zirconium, mono-sec-butoxy tris(acetylacetonate) zirconium, mono-t-butoxy tris(acetylacetonate) zirconium, tetrakis(acetylacetonate) zirconium, triethoxy mono(ethyl acetoacetate) zirconium, tri-n-propoxy mono(ethyl acetoacetate) zirconium, tri-i-propoxy mono(ethyl acetoacetate) zirconium, tri-n-butoxy mono(ethyl acetoacetate) zirconium, tri-sec-butoxy mono(ethyl acetoacetate) zirconium, tri-t-butoxy mono(ethyl acetoacetate) zirconium, diethoxy bis(ethyl acetoacetate) zirconium, di-n-propoxy bis(ethyl acetoacetate) zirconium, di-i-propoxy bis(ethyl acetoacetate) zirconium, di-n-butoxy bis(ethyl acetoacetate) zirconium, di-sec-butoxy bis(ethyl acetoacetate) zirconium, di-t-butoxy bis(ethyl acetoacetate) zirconium, monoethoxy tris(ethyl acetoacetate) zirconium, mono-n-propoxy tris(ethyl acetoacetate) zirconium, mono-i-propoxy tris(ethyl acetoacetate) zirconium, mono-n-butoxy tris(ethyl acetoacetate) zirconium, mono-sec-butoxy tris(ethyl acetoacetate) zirconium, mono-t-butoxy tris(ethyl acetoacetate) zirconium, tetrakis(ethyl acetoacetate) zirconium, mono(acetylacetonate) tris(ethylacetoacetate) zirconium, bis(acetylacetonate) bis(ethylacetoacetate) zirconium, or tris(acetylacetonate) mono(ethylacetoacetate) zirconium; aluminum chelate compounds such as tris(acetylacetonate) aluminum or tris(ethylacetoacetate) aluminum, and the like, but are not limited thereto.

Examples of the organic acid as the hydrolysis catalyst include acetic acid, propionic acid, butanoic acid, pentanoic acid, hexanoic acid, heptanoic acid, octanoic acid, nonanoic acid, decanoic acid, oxalic acid, maleic acid, methylmalonic acid, adipic acid, sebacic acid, gallic acid, butyric acid, mellitic acid, arachidonic acid, 2-ethylhexanoic acid, oleic acid, stearic acid, linoleic acid, linoleic acid, salicylic acid, benzoic acid, p-aminobenzoic acid, p-toluenesulfonic acid, benzenesulfonic acid, monochloroacetic acid, dichloroacetic acid, trichloroacetic acid, trifluoroacetic acid, formic acid, malonic acid, sulfonic acid, phthalic acid, fumaric acid, citric acid, tartaric acid, and the like, but are not limited thereto.

Examples of the inorganic acid as the hydrolysis catalyst include hydrochloric acid, nitric acid, sulfuric acid, hydrofluoric acid, phosphoric acid, and the like, but are not limited thereto.

Examples of the organic base as the hydrolysis catalyst include pyridine, pyrrole, piperazine, pyrrolidine, piperidine, picoline, trimethylamine, triethylamine, monoethanolamine, diethanolamine, dimethylmonoethanolamine, monomethyldiethanolamine, triethanolamine, diazabicyclooctane, diazabicyclononane, diazabicycloundecene, tetramethylammonium hydroxide, tetraethylammonium hydroxide, tetrapropylammonium hydroxide, tetrabutylammonium hydroxide, trimethylphenylammonium hydroxide, benzyltrimethylammonium hydroxide, benzyltriethylammonium hydroxide, and the like, but are not limited thereto.

Examples of the inorganic base as the hydrolysis catalyst include ammonia, sodium hydroxide, potassium hydroxide, barium hydroxide, calcium hydroxide, and the like, but are not limited thereto.

Among these catalysts, metal chelate compounds, organic acids, and inorganic acids are preferable, and these may be used alone or in combination of two or more.

Among them, in the present invention, nitric acid can be suitably used as the hydrolysis catalyst. Using nitric acid, the storage stability of the reaction solution after hydrolysis and condensation can be improved, and in particular, a change in the molecular weight of the hydrolysis condensate can be suppressed. The stability of the hydrolysis condensate in liquid has been found to depend on the pH of the solution. As a result of intensive studies, it has been found that the pH of the solution becomes a stable region using an appropriate amount of nitric acid.

When the hydrolysis and the condensation are performed, an organic solvent may be used as a solvent, and specific examples thereof include aliphatic hydrocarbon solvents such as n-pentane, i-pentane, n-hexane, i-hexane, n-heptane, i-heptane, 2,2,4-trimethylpentane, n-octane, i-octane, cyclohexane, or methylcyclohexane; aromatic hydrocarbon solvents such as benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, or n-amylnaphthalene; monoalcoholic solvents such as methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, n-heptanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethyl nonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethyl carbinol, diacetone alcohol, or cresol; polyhydric alcohol solvents such as ethylene glycol, propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, or glycerin; ketone solvents such as acetone, methyl ethyl ketone, methyl-n-propyl ketone, methyl-n-butyl ketone, diethyl ketone, methyl-1-butylketone, methyl-n-pentylketone, ethyl-n-butylketone, methyl-n-hexylketone, di-i-butyl ketone, trimethylnonanone, cyclohexanone, methylcyclohexanone, 2,4-pentanedione, acetonylacetone, diacetone alcohol, acetophenone, or Fenchone; ether solvents such as ethyl ether, i-propyl ether, n-butyl ether, n-hexyl ether, 2-ethylhexyl ether, ethylene oxide, 1,2-propylene oxide, dioxolane, 4-methyldioxolane, dioxane, dimethyl dioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethyl butyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxy triglycol, tetraethylene glycol di-n-butyl ether, propylene glycol monomethyl ether (1-methoxy-2-propanol), propylene glycol monoethyl ether (1-ethoxy-2-propanol), propylene glycol monopropyl ether, propylene glycol monobutyl ether, propylene glycol monomethyl ether acetate (1-methoxy-2-propanol monoacetate), dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, or 2-methyltetrahydrofuran; ester solvents such as diethyl carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, acetate ethylene glycol monomethyl ether, acetate ethylene glycol monoethyl ether, acetic acid diethylene glycol monomethyl ether, acetic acid diethylene glycol monoethyl ether, acetic acid diethylene glycol mono-n-butyl ether, acetate propylene glycol monomethyl ether, acetate propylene glycol monoethyl ether, acetate propylene glycol monopropyl ether, acetate propylene glycol monobutyl ether, acetate dipropylene glycol monomethyl ether, dipropylene glycol monoethyl ether acetate, glycol diacetate, methoxytriglycol acetate, ethyl propionate, n-butyl propionate, i-amyl propionate, diethyl oxalate, di-n-butyl oxalate, methyl lactate, ethyl lactate, n-butyl lactate, n-amyl lactate, diethyl malonate, dimethyl phthalate, or diethyl phthalate; nitrogen-containing solvents such as N-methylformamide, N, N-dimethylformamide, N, N-diethylformamide, acetamide, N-methylacetamide, N, N-dimethylacetamide, N-methylpropionamide, or N-methyl-2-pyrrolidone; sulfur-containing solvents such as dimethyl sulfide, diethyl sulfide, thiophene, tetrahydrothiophene, dimethyl sulfoxide, sulfolane, or 1,3-propane sultone; and the like, but are not limited thereto. These solvents can be used singly or in combination of two or more kinds thereof.

After completion of the hydrolysis and condensation reaction, the reaction solution is diluted or concentrated as it is, neutralized, and treated using an ion exchange resin, whereby a hydrolysis catalyst such as an acid or a base used for hydrolysis and condensation can be removed. In addition, before or after such treatment, alcohol and water as by-products, the hydrolysis catalyst used, and the like can be removed from the reaction solution by distillation under reduced pressure or the like.

The hydrolysis condensate (hereinafter, also referred to as polysiloxane) thus obtained is obtained in the form of a polysiloxane varnish dissolved in an organic solvent, and this can be used as it is as a resist underlayer film forming composition to be described later. The obtained polysiloxane varnish may be subjected to solvent substitution or may be appropriately diluted with a solvent. The obtained polysiloxane varnish can have a solid content concentration of 100% by distilling off the organic solvent if the storage stability is not poor.

The organic solvent used for solvent substitution, dilution, or the like of the polysiloxane varnish may be the same as or different from the organic solvent used for the hydrolysis and condensation reaction of the hydrolyzable silane mixture. The diluting solvent is not particularly limited, and one kind or two or more kinds can be arbitrarily selected and used.

The resist underlayer film forming composition of the present invention may contain a solvent, a specific additive (compound A) having a chemical structure containing a cation AX⁺ and an anion AZ⁻, and other components in addition to the hydrolysis condensate (polysiloxane) of the hydrolyzable silane mixture.

### <Solvent>

The solvent used in the resist underlayer film forming composition of the present invention can be used without particular limitation as long as it is a solvent capable of dissolving the solid content in the resist underlayer film forming composition.

Such a solvent is not limited as long as it dissolves the hydrolysis condensate of the hydrolyzable silane mixture, a specific additive (compound A), and other components.

Specific examples thereof include methyl cellosolve acetate, ethyl cellosolve acetate, propylene glycol, propylene glycol monomethyl ether (1-methoxy-2-propanol), propylene glycol monoethyl ether (1-ethoxy-2-propanol), methylisobutylcarbinol, propylene glycol monobutyl ether, propylene glycol monomethyl ether acetate (1-methoxy-2-propanol monoacetate), propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol monoethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropionate, methyl 2-hydroxy-3-methylbutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutylpropionate, 3-methyl-3-methoxybutyl butyrate, methyl acetoacetate, toluene, xylene, methyl ethyl ketone, methylpropylketone, methyl butyl ketone, 2-heptanone, 3-heptanone, 4-heptanone, cyclohexanone, N, N-dimethylformamide, N-methylacetamide, N, N-dimethylacetamide, N-methyl-2-pyrrolidone, 4-methyl-2-pentanol, γ-Butyrolactone, and the like and one solvent can be used alone or two or more solvents can be used in combination.

The resist underlayer film forming composition of the present invention may contain water as a solvent. In a case where water is contained as the solvent, the content thereof can be, for example, 30 mass % or less, preferably 20 mass % or less, and still more preferably 15 mass % or less with respect to the total mass of the solvent contained in the composition.

### <Specific Additive (Compound A)>

By further adding a specific additive (compound A) having a chemical structure containing a cation AX⁺ and an anion AZ⁻ to the resist underlayer film forming composition containing the hydrolysis condensate (polysiloxane) of the hydrolyzable silane mixture, a resist underlayer film exhibiting more excellent solubility in an alkaline solution (basic chemical solution) can be formed.

The specific additive (compound A) is a compound having a chemical structure containing a cation AX⁺ and an anion AZ⁻, and having an anion molecular weight of 65 or more.

In the specific additive (compound A), “cation” means an atom having a positive charge or an atomic group having a positive charge, and “anion” means an atom having a negative charge or an atomic group having a negative charge.

It is presumed that the reason why the solubility of the specific additive (compound A) in the alkaline solution (basic chemical solution) in the resist underlayer film is increased by including the specific additive (compound A) in the resist underlayer film forming composition is that the presence of anionic species in the specific additive (compound A) between the hydrolysis condensates (polymers) inhibits the bonding at which the hydrolysis condensates are crosslinked, or the anionic species themselves are bonded and capped, so that three-dimensional crosslinking does not proceed.

The molecular weight of the anion AZ⁻ is more preferably 65 or more from the viewpoint of suppressing condensation. In addition, from the viewpoint of maintaining dry etching resistance, it is more preferably 500 or less.

### <<Anion AZ^{->>}

In the compound A, the anion AZ⁻ may be present outside or inside the molecule of the cation AX⁺.

The phrase “the anion AZ⁻ is present outside the molecule of the cation AX⁺” refers to a state in which the anion AZ⁻ is not bonded to the cation AX⁺ via a covalent bond and is present as a structural unit independent of the cation AX⁺. Examples of the form of the compound A as described above include salts. Hereinafter, an anion present outside the molecule of the cation is also referred to as a counter anion.

In addition, in the compound A, the anion AZ⁻ may be bonded to the cation AX⁺ via the covalent bond. That is, the form of the compound A may be an intramolecular salt (it is also referred to as a zwitterion.).

The type of the anion AZ⁻ is not particularly limited as long as the condition that the molecular weight of the anion is 65 or more is satisfied, and examples thereof include anions having chemical structures represented by the following (A) to (E).

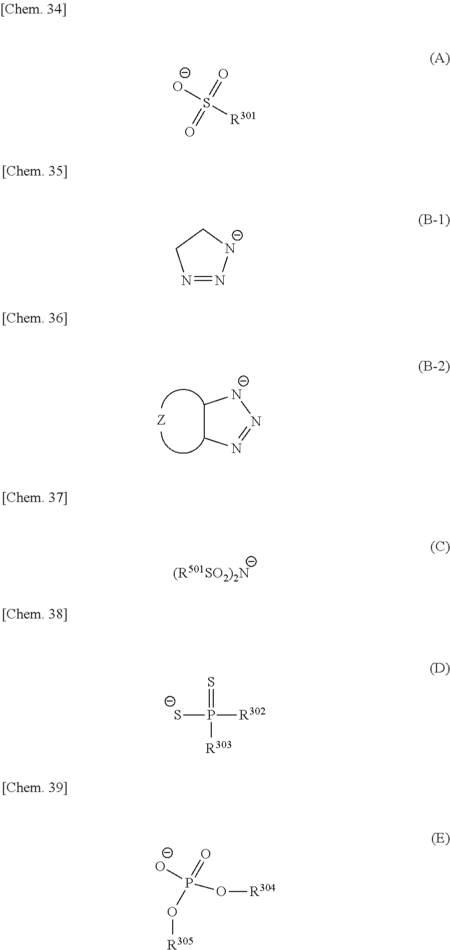

In Formulae (A) to (E), R³⁰¹ represents an optionally substituted alkyl group, an optionally substituted aryl group, an optionally substituted halogenated alkyl group, an optionally substituted aralkyl group, or an organic group containing an ester bond (—C(═O)—O— or —O—C(═O)—), or a combination of these,
Z represents an aromatic ring, a cyclic alkane, or a cyclic alkene with a non-aromatic ring,
R⁵⁰¹ represents an alkyl group in which some or all of the alkyl group may be substituted with a fluorine atom,
R³⁰² and R³⁰³ each independently represent an alkyl group, and
R³⁰⁴ and R³⁰⁵ each independently represent an alkyl group.

Specific examples of the alkyl group, the aryl group, the halogenated alkyl group, and the aralkyl group include the same groups as those described above. Specific examples of the substituent that may be substituted with the alkyl group and the like include the same as those described above.

Examples of the specific additive (compound A) include a compound having a sulfonate anion represented by Formula (A) above.

The compound having a sulfonate anion represented by Formula (A) may be not only a compound having an anion represented by Formula (A) outside the molecule, but also a compound having an anion represented by Formula (A) inside the molecule, such as a sulfobetaine such as lauryl sulfobetaine or myristyl sulfobetaine (see compounds in (Add-6) and (Add-7) below).

Examples of the specific additive (compound A) include a compound having an anion containing a triazole skeleton represented by Formula (B-1) above or Formula (B-2) above.

In Formula (B-2), Z represents an aromatic ring, a cyclic alkane, or a non-aromatic ring cyclic alkene having 1 to 6 carbon atoms.

As the specific additive (compound A), a compound having an anion represented by Formula (B-2) is preferable, and in particular, Z is preferably an aromatic ring in Formula (B-2). That is, a preferred embodiment of the specific additive (compound A) includes, for example, a compound having an anion including a benzotriazole skeleton represented by the following (b-1).

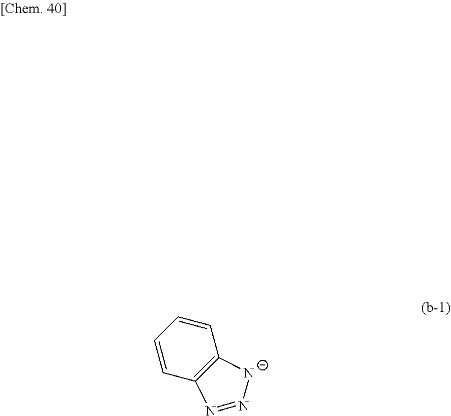

Examples of the specific additive (compound A) include a compound represented by Formula (C) above.

In Formula (C), R⁵⁰¹ represents an alkyl group having 1 to 4 carbon atoms, a fluoroalkyl group in which a part or all of the alkyl group is substituted with a fluorine atom, or a perfluoroalkyl group.

Among them, R⁵⁰¹ is preferably a CF₃ group or a C₄F₉ group. In particular, the specific additive (compound A) is more preferably, for example, a compound having an anion of bis(trifluoromethanesulfonyl) imide represented by the following (c-1).

[Chem. 41]

(CF₃SO₂)₂N^{θ} (c-1)

Examples of the specific additive (compound A) include a compound having a thiophosphate anion represented by Formula (D) above.

Examples of the specific additive (compound A) include a compound having a phosphate anion represented by Formula (E) above or the like.

Specific examples of the specific additive (compound A) include compounds represented by Formulae (Add-1) to (Add-11) below, but are not limited thereto.

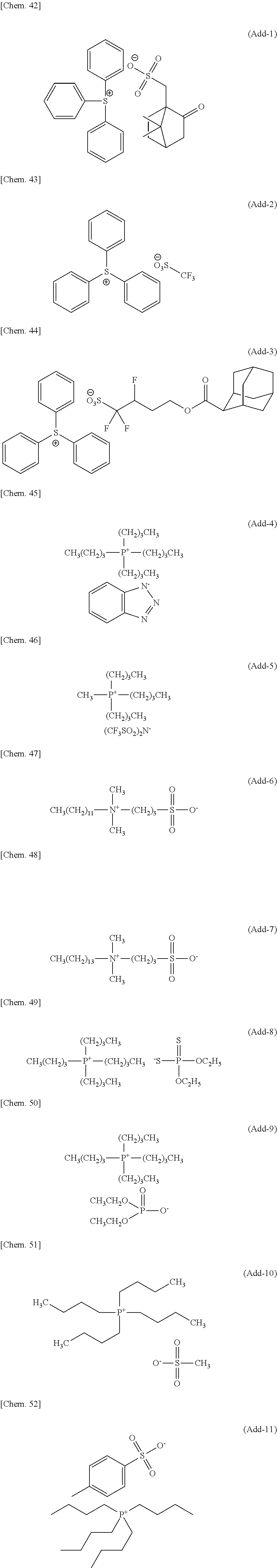

In a case where the resist underlayer film forming composition of the present invention contains a specific additive, the content thereof can be 1 to 30 parts by mass with respect to 100 parts by mass of the resist underlayer film forming composition.

### <Other Components (Other Additives)>

In the resist underlayer film forming composition of the present invention, additives (also referred to as other additives) which are other components other than the specific additives can be variously blended depending on the use of the composition.

Examples of other components (other additives) that can be blended in the resist underlayer film forming composition include known additives that are blended in materials (compositions) for forming various films that can be used for manufacturing a semiconductor device, such as a resist underlayer film, an antireflection film, and a pattern inversion film, such as a curing catalyst (ammonium salt, phosphine, phosphonium salt, sulfonium salt, nitrogen-containing silane compound, or the like), a crosslinking agent, a crosslinking catalyst, a stabilizer (organic acid, water, alcohol, or the like), an organic polymer compound, an acid generator, a surfactant (nonionic surfactant, anionic surfactant, cationic surfactant, silicon-based surfactant, fluorine-based surfactant, UV-curable surfactant, or the like), a pH adjuster, a rheology modifier, or an adhesion aid.

Hereinafter, various additives will be exemplified, but the additives are not limited thereto.

### <<Curing Catalyst>>

As the curing catalyst, ammonium salts, phosphines, phosphonium salts, sulfonium salts and the like can be used. The following salts described as the curing catalyst may be added in the form of a salt, or may be any of those that form a salt in the composition (one that is added as a separate compound at the time of addition and forms a salt in the system).

Examples of the ammonium salt include
a quaternary ammonium salt having a structure represented by Formula (D-1):

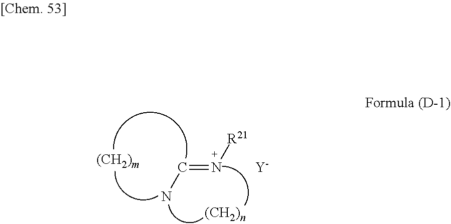

(wherein m represents an integer of 2 to 11, n represents an integer of 2 and 3, R²¹ represents an alkyl group or an aryl group, and Y-represents an anion.), a quaternary ammonium salt having a structure represented by Formula (D-2):

[Chem. 54]

R²²R²³R²⁴R²⁵N⁺Y⁻ Formula (D-2)
(wherein R²², R²³, R²⁴, and R²⁵ represent an alkyl group or an aryl group, N represents a nitrogen atom, Y⁻ represents an anion, and R²², R²³, R²⁴, and R²⁵ are each bonded to a nitrogen atom by a C—N bond),
a quaternary ammonium salt having a structure represented by Formula (D-3):

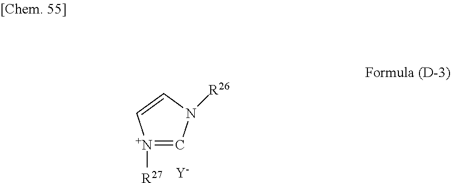

(wherein R²⁶ and R²⁷ represent an alkyl group or an aryl group, N represents a nitrogen atom, and Y⁻ represents an anion),
a quaternary ammonium salt having a structure represented by Formula (D-4):

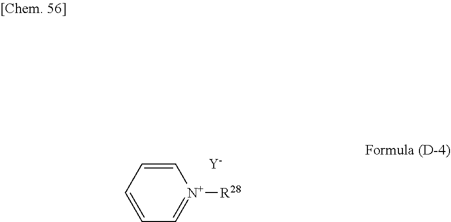

(wherein R²⁸ represents an alkyl group or an aryl group, N represents a nitrogen atom, and Y⁻ represents an anion),
a quaternary ammonium salt having a structure represented by Formula (D-5):

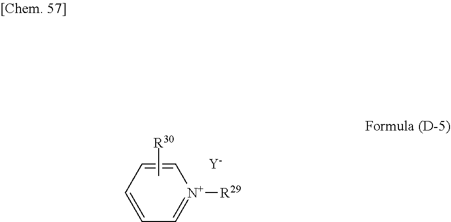

(wherein R²⁹ and R³⁰ represent an alkyl group or an aryl group, N represents a nitrogen atom, and Y-represents an anion), and
a tertiary ammonium salt having a structure represented by Formula (D-6):

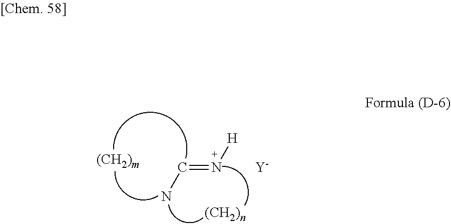

(wherein m represents an integer of 2 to 11, n represents an integer of 2 and 3, H represents a hydrogen atom, N represents a nitrogen atom, and Y⁻ represents an anion).

In addition, examples of the phosphonium salt include a quaternary phosphonium salt represented by Formula (D-7):

[Chem. 59]

R³¹R³²R³³R³⁴P⁺Y⁻ Formula (D-7)
(wherein R³¹, R³², R³³, and R³⁴ represent an alkyl group or an aryl group, P represents a phosphorus atom, Y⁻ represents an anion, and R³¹, R³², R³³, and R³⁴ are each bonded to a phosphorus atom by a C—P bond).

In addition, examples of the sulfonium salt include
a tertiary sulfonium salt represented by Formula (D-8):

[Chem. 60]

R³⁵R³⁶R³⁷S⁺Y⁻ Formula(D-8)
(wherein R³⁵, R³⁶, and R³⁷ represent an alkyl group or an aryl group, S represents a sulfur atom, Y-represents an anion, and R³⁵, R³⁶, and R³⁷ are each bonded to a sulfur atom by a C—S bond).

The compound of Formula (D-1) above is a quaternary ammonium salt derived from an amine, wherein m represents an integer of 2 of 11, and n represents an integer of 2 and 3. R²¹ of the quaternary ammonium salt represents an alkyl group having 1 to 18 carbon atoms, preferably 2 to 10 carbon atoms, or an aryl group having 6 to 18 carbon atoms, and examples thereof include a linear alkyl group such as an ethyl group, a propyl group, or a butyl group, a benzyl group, a cyclohexyl group, a cyclohexylmethyl group, and a dicyclopentadienyl group. In addition, examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻).

The compound of Formula (D-2) above is a quaternary ammonium salt represented by R²²R²³R²⁴R²⁵N⁺Y⁻. R²², R²³, R²⁴, and R²⁵ of the quaternary ammonium salt are each an alkyl group having 1 to 18 carbon atoms or an aryl group having 6 to 18 carbon atoms. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). This quaternary ammonium salt can be obtained as a commercially available product, and examples thereof include tetramethylammonium acetate, tetrabutylammonium acetate, triethylbenzylammonium chloride, triethylbenzylammonium bromide, trioctylmethylammonium chloride, tributylbenzylammonium chloride, and trimethylbenzylammonium chloride.

The compound of Formula (D-3) above is a quaternary ammonium salt derived from a 1-substituted imidazole, the number of carbon atoms of R²⁶ and R²⁷ is preferably 1 to 18, and the total number of carbon atoms of R²⁶ and R²⁷ is preferably 7 or more. For example, R²⁶ may be a methyl group, an ethyl group, a propyl group, a phenyl group, or a benzyl group, and R²⁷ may be a benzyl group, an octyl group, or an octadecyl group. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). This compound can also be obtained as a commercially available product, and can be manufactured, for example, by reacting an imidazole-based compound such as 1-methylimidazole or 1-benzylimidazole with an alkyl halide or aryl halide such as benzyl bromide or methyl bromide.

The compound of Formula (D-4) above is a quaternary ammonium salt derived from pyridine, R²⁸ is an alkyl group having 1 to 18 carbon atoms, preferably 4 to 18 carbon atoms, or an aryl group having 6 to 18 carbon atoms, and examples of the quaternary ammonium salt include a butyl group, an octyl group, a benzyl group, and a lauryl group. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). This compound can also be obtained as a commercially available product, but can be manufactured, for example, by reacting pyridine with an alkyl halide such as lauryl chloride, benzyl chloride, benzyl bromide, methyl bromide, or octyl bromide, or an aryl halide. Examples of the compound include N-laurylpyridinium chloride and N-benzylpyridinium bromide.

The compound of Formula (D-5) above is a quaternary ammonium salt derived from substituted pyridine represented by picoline or the like, and R²⁹ is an alkyl group having 1 to 18 carbon atoms, preferably 4 to 18 carbon atoms, or an aryl group having 6 to 18 carbon atoms, and examples thereof include a methyl group, an octyl group, a lauryl group, and a benzyl group. R³⁰ is an alkyl group having 1 to 18 carbon atoms or an aryl group having 6 to 18 carbon atoms, and for example, in the case of quaternary ammonium derived from picoline, R³⁰ is a methyl group. Examples of the anion (Y⁻) include halide ions such as a chlorine ion (Cl⁻), a bromine ion (Br⁻), and an iodine ion (I), and acid groups such as carboxylate (—COO⁻), sulfonate (—SO₃⁻), and alcoholate (—O⁻). This compound can also be obtained as a commercially available product, but can be manufactured, for example, by reacting a substituted pyridine such as picoline with an alkyl halide such as methyl bromide, octyl bromide, lauryl chloride, benzyl chloride, or benzyl bromide, or an aryl halide. Examples of the compound include N-benzylpicolinium chloride, N-benzylpicolinium bromide, and N-laurylpicolinium chloride.

The compound of Formula (D-6) above is a tertiary ammonium salt derived from an amine, wherein m represents an integer of 2 of 11, and n represents an integer of 2 and 3. In addition, examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). The present compound can be manufactured by a reaction of an amine with a weak acid such as a carboxylic acid or phenol. Examples of the carboxylic acid include formic acid and acetic acid, and in a case where the formic acid is used, the anion (Y⁻) is (HCOO⁻), and in a case where the acetic acid is used, the anion (Y⁻) is (CH₃COO⁻). In addition, in a case where the phenol is used, the anion (Y⁻) is (C₆H₅O⁻).

The compound of Formula (D-7) above is a quaternary phosphonium salt having the structure of R³¹R³²R³³R³⁴P⁺Y⁻. R³¹, R³², R³³, and R³⁴ are each an alkyl group having 1 to 18 carbon atoms or an aryl group having 6 to 18 carbon atoms, and preferably three of the four substituents R³¹ to R³⁴ are phenyl groups or substituted phenyl groups, and for example, a phenyl group or a tolyl group can be exemplified, and the remaining one is an alkyl group having 1 to 18 carbon atoms or an aryl group having 6 to 18 carbon atoms. In addition, examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). This compound can be obtained as a commercial product, and examples thereof include halogenated tetraalkylphosphonium such as halogenated tetra n-butylphosphonium, halogenated tetra n-propylphosphonium, halogenated trialkylbenzylphosphonium such as halogenated triethylbenzylphosphonium, halogenated triphenylmonoalkylphosphonium such as halogenated triphenylmethylphosphonium, halogenated triphenylethylphosphonium, triphenylbenzylphosphonium halide, tetraphenylphosphonium halide, tritolyl monoarylphosphonium halide, or tritolyl monoalkylphosphonium halide (in the above, the halogen atom is a chlorine atom or a bromine atom). In particular, halogenated triphenylmonoalkylphosphonium such as halogenated triphenylmethylphosphonium, halogenated triphenylethylphosphonium, etc. are preferable, halogenated triphenyl monoarylphosphonium such as halogenated triphenylbenzylphosphonium, halogenated tritolyl monoarylphosphonium such as halogenated tritolyl monophenylphosphonium, or halogenated tritolyl monoalkylphosphonium such as halogenated tritolyl monomethylphosphonium (halogen atom is chlorine atom or bromine atom) are preferable.

In addition, examples of the phosphines include first phosphines such as methylphosphine, ethylphosphine, propylphosphine, isopropylphosphine, isobutylphosphine, or phenylphosphine; second phosphines such as dimethylphosphine, diethylphosphine, diisopropylphosphine, diisoamylphosphine, or diphenylphosphine; and third phosphines such as trimethylphosphine, triethylphosphine, triphenylphosphine, methyldiphenylphosphine, or dimethylphenylphosphine.

The compound of Formula (D-8) above is a tertiary sulfonium salt having the structure of R³⁵R³⁶R³⁷S⁺Y⁻. R³⁵, R³⁶, and R³⁷ are an alkyl group having 1 to 18 carbon atoms or an aryl group having 6 to 18 carbon atoms, and preferably, two of the three substituents of R³⁵ to R³⁷ are a phenyl group or a substituted phenyl group, and for example, a phenyl group or a tolyl group can be exemplified, and the remaining one is an alkyl group having 1 to 18 carbon atoms or an aryl group having 6 to 18 carbon atoms. In addition, examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻), maleate anion, and nitrate anion. The compound can be obtained as a commercially available product, and examples thereof include halogenated trialkylsulfonium such as halogenated tri-n-butylsulfonium, or halogenated tri-n-propylsulfonium, halogenated dialkylbenzylsulfonium such as diethylbenzylsulfonium halide, halogenated diphenylmonoalkylsulfonium such as halogenated diphenylmethylsulfonium, or halogenated diphenylethylsulfonium, trialkylsulfonium carboxylates such as triphenylsulfonium halides (wherein the halogen atom is a chlorine atom or a bromine atom), tri-n-butylsulfonium carboxylate, or tri-n-propylsulfonium carboxylate, dialkylbenzylsulfonium carboxylates such as diethylbenzylsulfonium carboxylate, diphenylmonoalkylsulfonium carboxylates such as diphenylmethylsulfonium carboxylate or diphenylethylsulfonium carboxylate, and triphenylsulfonium carboxylate. In addition, the triphenylsulfonium halide and the triphenylsulfonium carboxylate can be preferably used.

In addition, in the present invention, a nitrogen-containing silane compound can be added as a curing catalyst. Examples of the nitrogen-containing silane compound include imidazole ring-containing silane compounds such as N-(3-triethoxysilypropyl)-4,5-dihydroimidazole.

In a case where the curing catalyst is used, the content is 0.01 parts by mass to 10 parts by mass, 0.01 parts by mass to 5 parts by mass, or 0.01 parts by mass to 3 parts by mass with respect to 100 parts by mass of the polysiloxane.

### <<Stabilizer>>

The stabilizer can be added for the purpose of stabilizing the hydrolysis condensate of the hydrolyzable silane mixture, and as a specific example thereof, an organic acid, water, alcohol, or a combination thereof can be added.

Examples of the organic acid include oxalic acid, malonic acid, methylmalonic acid, succinic acid, maleic acid, malic acid, tartaric acid, phthalic acid, citric acid, glutaric acid, lactic acid, and salicylic acid. Among them, oxalic acid and maleic acid are preferable. In a case where the organic acid is added, the addition amount thereof is 0.1 to 5.0 mass % with respect to the mass of the hydrolysis condensate of the hydrolyzable silane mixture. These organic acids can also serve as pH adjusters.

As the water, pure water, ultrapure water, ion-exchanged water, or the like can be used, and when used, the addition amount thereof can be 1 part by mass to 20 parts by mass with respect to 100 parts by mass of the resist underlayer film forming composition.

The alcohol is preferably one that is easily scattered (volatilized) by heating after application, and examples thereof include methanol, ethanol, propanol, i-propanol, and butanol. In a case where an alcohol is added, the addition amount thereof can be 1 part by mass to 20 parts by mass with respect to 100 parts by mass of the resist underlayer film forming composition.

### <<Organic Polymer>>

By adding the organic polymer compound to the resist underlayer film forming composition, the dry etching rate (amount of decrease in film thickness per unit time), the attenuation coefficient, the refractive index, and the like of the film (resist underlayer film) formed from the composition can be adjusted. The organic polymer compound is not particularly limited, and is appropriately selected from various organic polymers (polycondensation polymer and addition polymerization polymer) according to the purpose of addition.

Specific examples thereof include addition polymerization polymers and polycondensation polymers such as polyester, polystyrene, polyimide, acrylic polymers, methacrylic polymers, polyvinyl ether, phenol novolac, naphthol novolac, polyether, polyamide, and polycarbonate.

In the present invention, an organic polymer containing an aromatic ring or a heteroaromatic ring such as a benzene ring, a naphthalene ring, an anthracene ring, a triazine ring, a quinoline ring, or a quinoxaline ring, which functions as an absorption site, can also be suitably used when such a function is required. Specific examples of such an organic polymer compound include addition polymerization polymers containing an addition polymerizable monomer such as benzyl acrylate, benzyl methacrylate, phenyl acrylate, naphthyl acrylate, anthryl methacrylate, anthryl methyl methacrylate, styrene, hydroxystyrene, benzyl vinyl ether and N-phenyl maleimide as a structural unit thereof, and polycondensation polymers such as phenol novolac and naphthol novolac, but are not limited thereto.

In a case where the addition polymerization polymer is used as the organic polymer compound, the polymer compound may be either a homopolymer or a copolymer.

An addition polymerizable monomer is used to manufacture the addition polymerization polymer, and specific examples of such an addition polymerizable monomer include acrylic acid, methacrylic acid, an acrylic acid ester compound, a methacrylic acid ester compound, an acrylamide compound, a methacrylamide compound, a vinyl compound, a styrene compound, a maleimide compound, maleic anhydride, and acrylonitrile, and the like, but are not limited thereto.

Specific examples of the acrylic acid ester compound include methyl acrylate, ethyl acrylate, normal hexyl acrylate, i-propyl acrylate, cyclohexyl acrylate, benzyl acrylate, phenyl acrylate, anthryl methyl acrylate, 2-hydroxyethyl acrylate, 3-chloro-2-hydroxypropyl acrylate, 2-hydroxypropyl acrylate, 2,2,2-trifluoroethyl acrylate, 2,2,2-trichloroethyl acrylate, 2-bromoethyl acrylate, 4-hydroxybutyl acrylate, 2-methoxyethyl acrylate, tetrahydrofurfuryl acrylate, 2-methyl-2-adamantyl acrylate, 5-acryloyloxy-6-hydroxynorbornene-2-carboxylic-6-lactone, 3-acryloxypropyl triethoxysilane, glycidyl acrylate, and the like, but are not limited thereto.

Specific examples of the methacrylic acid ester compound include methyl methacrylate, ethyl methacrylate, normal hexyl methacrylate, i-propyl methacrylate, cyclohexyl methacrylate, benzyl methacrylate, phenyl methacrylate, anthryl methyl methacrylate, 2-hydroxyethyl methacrylate, 2-hydroxypropyl methacrylate, 2,2,2-trifluoroethyl methacrylate, 2,2,2-trichloroethyl methacrylate, 2-bromoethyl methacrylate, 4-hydroxybutyl methacrylate, 2-methoxyethyl methacrylate, tetrahydrofurfuryl methacrylate, 2-methyl-2-adamantyl methacrylate, 5-methacryloyloxy-6-hydroxynorbornene-2-carboxylate-6-lactone, 3-methacryloxypropyl triethoxysilane, glycidyl methacrylate, 2-phenylethyl methacrylate, hydroxyphenyl methacrylate, bromophenyl methacrylate, and the like, but are not limited thereto.

Specific examples of the acrylamide compound include acrylamide, N-methylacrylamide, N-ethylacrylamide, N-benzylacrylamide, N-phenylacrylamide, N, N-dimethylacrylamide, N-anthrylacrylamide, and the like, but are not limited thereto.

Specific examples of the methacrylamide compound include methacrylamide, N-methylmethacrylamide, N-ethylmethacrylamide, N-benzylmethacrylamide, N-phenylmethacrylamide, N, N-dimethylmethacrylamide, N-anthrylmethacrylamide, and the like, but are not limited thereto.

Specific examples of the vinyl compound include vinyl alcohol, 2-hydroxyethyl vinyl ether, methyl vinyl ether, ethyl vinyl ether, benzyl vinyl ether, vinyl acetic acid, vinyl trimethoxysilane, 2-chloroethyl vinyl ether, 2-methoxyethyl vinyl ether, vinyl naphthalene, vinyl anthracene, and the like, but are not limited thereto.

Specific examples of the styrene compound include styrene, hydroxystyrene, chlorostyrene, bromostyrene, methoxystyrene, cyanostyrene, acetylstyrene, and the like, but are not limited thereto.

Examples of the maleimide compound include maleimide, N-methylmaleimide, N-phenylmaleimide, N-cyclohexylmaleimide, N-benzylmaleimide, N-hydroxyethylmaleimide, and the like, but are not limited thereto.

In a case where a polycondensation polymer is used as the polymer, examples of such a polymer include a polycondensation polymer of a glycol compound and a dicarboxylic acid compound. Examples of the glycol compound include diethylene glycol, hexamethylene glycol, butylene glycol, and the like. Examples of the dicarboxylic acid compound include succinic acid, adipic acid, terephthalic acid, maleic anhydride, and the like. In addition, examples thereof include polypyrromellitimide, poly(p-phenylene terephthalamide), polybutylene terephthalate, polyesters such as polyethylene terephthalate, polyamide, and polyimide, but are not limited thereto.

In a case where the organic polymer compound contains a hydroxy group, the hydroxy group can undergo a crosslinking reaction with a hydrolysis condensate or the like.

The weight average molecular weight of the organic polymer compound can be usually 1,000 to 1,000,000. In a case where the organic polymer compound is blended, the weight average molecular weight thereof can be, for example, 3,000 to 300,000, 5,000 to 300,000, or 10,000 to 200,000 from the viewpoint of sufficiently obtaining the effect of the function as a polymer and suppressing precipitation in the composition.

Such organic polymer compounds may be used singly or in combination of two or more kinds thereof.

In a case where the resist underlayer film forming composition of the present invention contains an organic polymer compound, the content thereof is appropriately determined in consideration of the function and the like of the organic polymer compound, and thus cannot be generally defined. However, usually, the content can be in the range of 1 to 200 mass % with respect to the mass of the hydrolysis condensate of the hydrolyzable silane mixture, and from the viewpoint of suppressing precipitation in the composition and the like, the content can be, for example, 100 mass % or less, preferably 50 mass % or less, and more preferably 30 mass % or less. From the viewpoint of sufficiently obtaining the effect and the like, the content can be, for example, 5 mass % or more, preferably 10 mass or more, and more preferably 30 mass % or more.

### <<Acid Generator>>

Examples of the acid generator include a thermal acid generator and a photoacid generator, and a photoacid generator can be preferably used.

Examples of the photoacid generator include an onium salt compound, a sulfonimide compound, a disulfonyl diazomethane compound, and the like, but are not limited thereto.

In addition, examples of the thermal acid generator include tetramethylammonium nitrate and the like, but are not limited thereto.

Specific examples of the onium salt compound include iodonium salt compounds such as diphenyliodonium hexafluorophosphate, diphenyliodonium trifluoromethanesulfonate, diphenyliodonium nonafluoronormal butanesulfonate, diphenyliodonium perfluoronormal octanesulfonate, diphenyliodonium camphor sulfonate, bis(4-t-butylphenyl) iodonium camphor sulfonate, and bis(4-t-butylphenyl) iodonium trifluoromethanesulfonate, sulfonium salt compounds such as triphenylsulfonium hexafluoroantimonate, triphenyllufonium nonafluoronormal butanesulfonate, triphenylsulfonium camphor sulfonate, triphenylsulfonium trifluoromethanesulfonate, triphenylsulfonium nitrate (nitrate), triphenylsulfonium trifluoroacetate, and triphenylsulfonium maleate, triphenylsulfonium chloride, and the like, but are not limited thereto.

Specific examples of the sulfonimide compound include N-(trifluoromethanesulfonyloxy) succinimide, N-(nonafluoronormalbutanesulfonyloxy) succinimide, N-(camphorsulfonyloxy) succinimide, N-(trifluoromethanesulfonyloxy) naphthalimide, and the like, but are not limited thereto.

Specific examples of the disulfonyl diazomethane compound include bis(trifluoromethylsulfonyl) diazomethane, bis(cyclohexylsulfonyl) diazomethane, bis(phenylsulfonyl) diazomethane, bis(p-toluenesulfonyl) diazomethane, bis(2,4-dimethylbenzenesulfonyl)diazomethane, methylsulfonyl-p-toluenesulfonyl diazomethane, and the like, but are not limited thereto.

In a case where the resist underlayer film forming composition of the present invention contains an acid generator, the content thereof is appropriately determined in consideration of the type of the acid generator and the like, and thus cannot be generally defined, but is usually in the range of 0.01 to 5 mass % with respect to the mass of the hydrolysis condensate of the hydrolyzable silane mixture, and is preferably 3 mass % or less, more preferably 1 mass % or less from the viewpoint of suppressing precipitation of the acid generator in the composition and the like, and is preferably 0.1 mass % or more, more preferably 0.5 mass % or more from the viewpoint of sufficiently obtaining the effect and the like.

The acid generator can be used singly or in combination of two or more kinds thereof, and a photoacid generator and a thermal acid generator may be used in combination.

### <<Surfactant>>

The surfactant is effective for suppressing generation of pinholes, frustration, and the like when the resist underlayer film forming composition is applied to a substrate. Examples of the surfactant include a nonionic surfactant, an anionic surfactant, a cationic surfactant, a silicon-based surfactant, a fluorine-based surfactant, and a UV-curable surfactant. More specifically, for example, nonionic surfactant such as polyoxyethylene alkyl ethers such as polyoxyethylene lauryl ether, polyoxyethylene stearyl ether, polyoxyethylene cetyl ether, or polyoxyethylene oleyl ether, polyoxyethylene alkylaryl ethers such as polyoxyethylene octylphenol ether or polyoxyethylene nonylphenol ether, polyoxyethylene/polyoxypropylene block copolymers, sorbitan fatty acid esters such as sorbitan monolaurate, sorbitan monopalmitate, sorbitan monostearate, sorbitan monooleate, sorbitan trioleate, or sorbitan tristearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, or polyoxyethylene sorbitan tristearate, fluorine surfactants such as Trade names EFTOP (registered trademark) EF301, EF303, and EF352 (manufactured by Mitsubishi Materials Electronic Chemicals Co., Ltd. (formerly Tochem Products K.K., Japan)), Trade names MEGAFACE (registered trademark) F171, F173, R-08, R-30, R-30N, and R-40 LM (manufactured by DIC CORPORATION), Fluorads FC430 and FC431 (manufactured by 3M Japan Limited), Trade name AsahiGuard (registered trademark) AG710 (manufactured by AGC Inc.), and Surflons (registered trademark) S-382, SC101, SC102, SC103, SC104, SC105, and SC106 (manufactured by AGC SEIMI CHEMICAL CO., LTD.), Organosiloxane polymer-KP341 (manufactured by Shin-Etsu Chemical Co., Ltd.), and the like are included, but are not limited thereto.

The surfactant may be used singly or in combination of two or more kinds thereof.

In a case where the resist underlayer film forming composition of the present invention contains a surfactant, the content thereof is usually 0.0001 to 5 mass %, preferably 0.001 to 4 mass %, and more preferably 0.01 to 3 mass % with respect to the mass of the hydrolysis condensate of the hydrolyzable silane mixture.

### <<Rheology Modifier>>

The rheology modifier is added mainly for the purpose of improving the fluidity of the resist underlayer film forming composition, and particularly for the purpose of improving the film thickness uniformity of the film to be formed and improving the filling property of the composition into the hole in the baking process. Specific examples thereof include phthalic acid derivatives such as dimethyl phthalate, diethyl phthalate, di-i-butyl phthalate, dihexyl phthalate, and butyl i-decyl phthalate, adipic acid derivatives such as di-n-butyl adipate, di-i-butyl adipate, di-i-octyl adipate, and octyl decyl adipate, maleic acid derivatives such as di-n-butyl malate, diethyl malate, and dinonyl malate, oleic acid derivatives such as methyl olate, butyl olate, and tetrahydrofurfuryl olate, and stearic acid derivatives such as n-butyl stearate and glyceryl stearate.

In a case where these rheology modifiers are used, the addition amount thereof is usually less than 30% by mass, based on the total solid content of the resist underlayer film forming composition.

### <<Adhesion Aid>>

The adhesion aid is added mainly for the purpose of improving adhesion between the substrate or the resist and a film (resist underlayer film) formed from the resist underlayer film forming composition, and particularly for the purpose of suppressing or preventing peeling of the resist in development. Specific examples thereof include chlorosilane such as trimethylchlorosilane, dimethylvinylchlorosilane, methyldiphenylchlorosilane, or chloromethyldimethylchlorosilane, alkoxysilane such as trimethylmethoxysilane, dimethyldiethoxysilane, methyldimethoxysilane, or dimethylvinylethoxysilane, silazanes such as hexamethyldisilazane, N, N′-bis(trimethylsilyl) urea, dimethyltrimethylsilylamine, or trimethylsilyl imidazole, other silane such as γ-chloropropyltrimethoxysilane, γ-aminopropyltriethoxysilane, and γ-glycidoxypropyltrimethoxysilane, heterocyclic compounds such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, or mercaptopyrimidine, or urea such as 1,1-dimethylurea and 1,3-dimethylurea or thiourea compounds.

In a case where these adhesion aids are used, the addition amount thereof is usually less than 5% by mass, and preferably less than 2% by mass, based on the total solid content of the resist underlayer film forming composition.

### <<pH Adjuster>>

In addition, as the pH adjuster, bisphenol S or a bisphenol S derivative can be added in addition to the acid having one or two or more carboxylic acid groups such as the organic acid mentioned above as <Stabilizer>. The amount of the bisphenol S or the bisphenol S derivative is 0.01 to 20 parts by mass, 0.01 to 10 parts by mass, or 0.01 to 5 parts by mass with respect to 100 parts by mass of the hydrolysis condensate of the hydrolyzable silane mixture.

Hereinafter, specific examples of bisphenol S and bisphenol S derivatives will be given, but the present invention is not limited thereto.

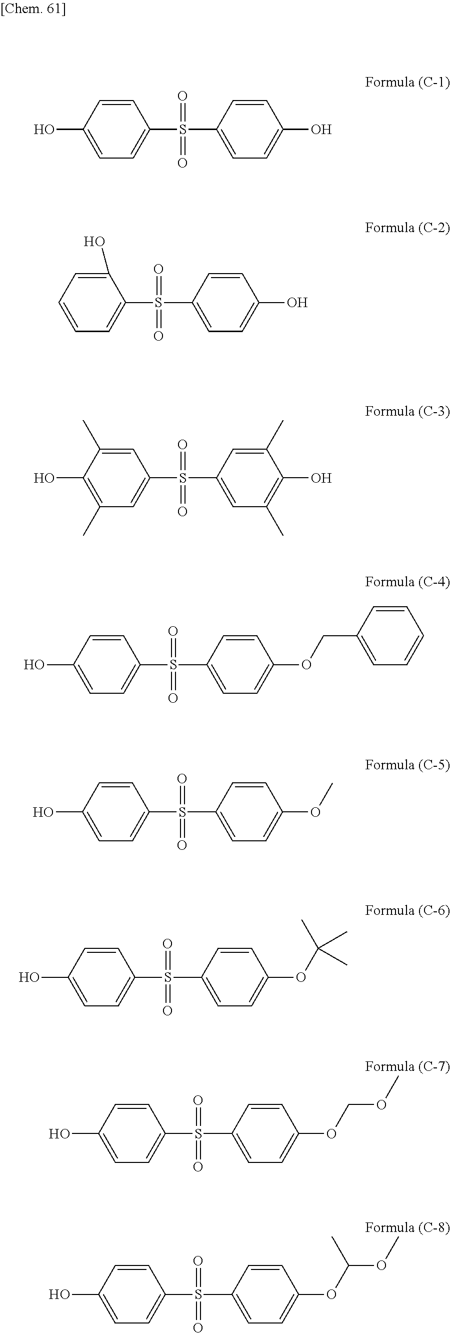

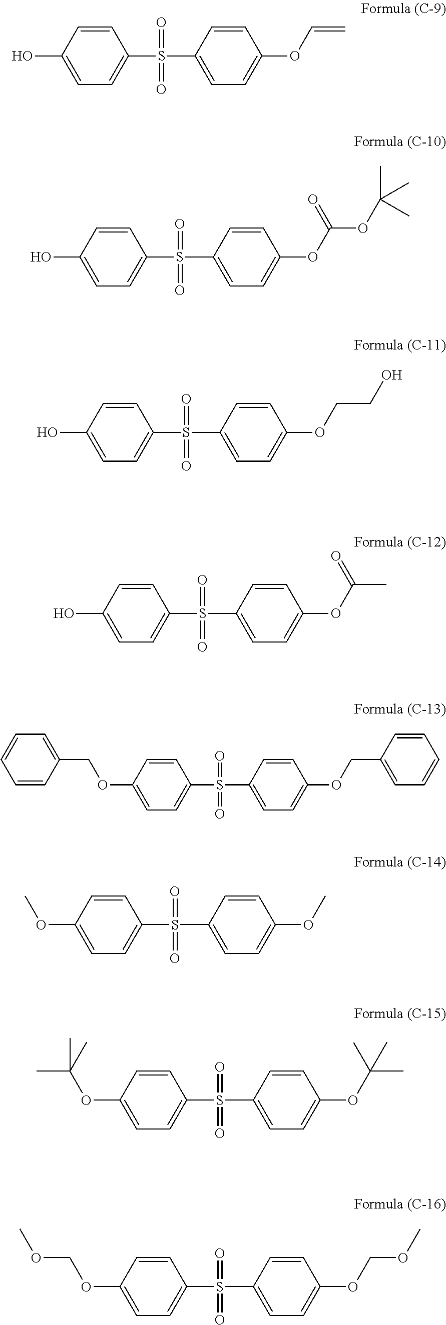

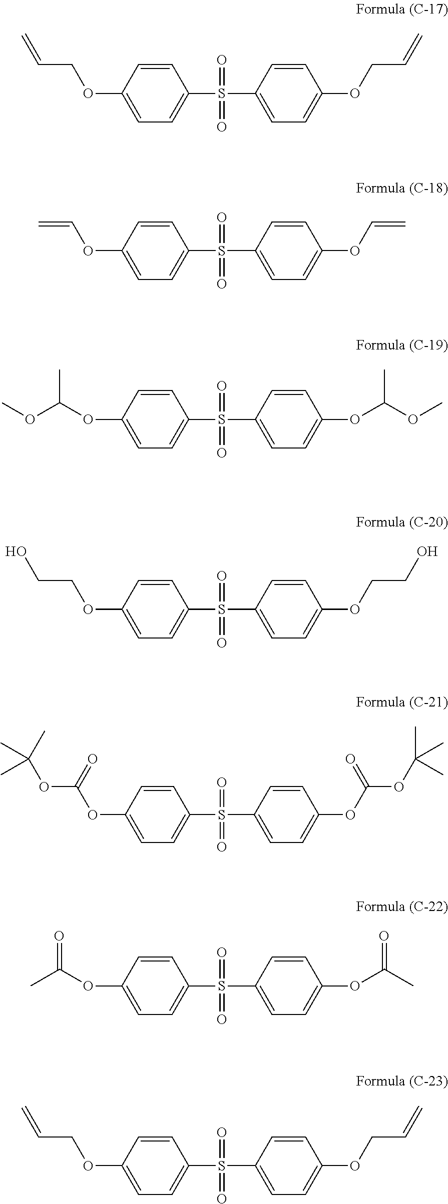

The concentration of the solid content in the resist underlayer film forming composition can be, for example, 0.1 to 50 mass, 0.1 to 30 mass, 0.1 to 25 mass, or 0.5 to 20.0 mass % with respect to the total mass of the composition. The solid content refers to a component obtained by removing a solvent component from all components of the composition.

The content of the hydrolysis condensate of the hydrolyzable silane mixture in the solid content is usually 20 mass % to 100 mass %, but from the viewpoint of obtaining the effect of the present invention with high reproducibility, the lower limit thereof is preferably 50 mass %, more preferably 60 mass %, still more preferably 70 mass %, and still more preferably 80 mass %, the upper limit thereof is preferably 99 mass %, and the rest thereof can be used as a specific additive (compound A) described later or another component.

In addition, the content of the hydrolysis condensate of the hydrolyzable silane mixture in the composition can be, for example, 0.5 to 20.0 mass %.

In addition, the resist underlayer film forming composition preferably has a pH of 2 to 5, and more preferably has a pH of 3 to 4.

The resist underlayer film forming composition can be manufactured by mixing a hydrolysis condensate of the hydrolyzable silane mixture, a solvent, and, if desired, a specific additive (compound A) and other components, the specific additive (compound A) and other components. At this time, a solution containing a hydrolysis condensate or the like may be prepared in advance, and this solution may be mixed with a solvent, a specific additive (compound A), or other components.

The mixing order is not particularly limited. For example, a solvent may be added to and mixed with a solution containing a hydrolysis condensate or the like, and a specific additive (compound A) or other components may be added to the mixture, or a solution containing a hydrolysis condensate or the like, a solvent, a specific additive (compound A), and other components may be simultaneously mixed.

If necessary, a solvent may be further added at the end, or some components relatively easily soluble in the solvent may not be included in the mixture, and the components may be added at the end. However, from the viewpoint of suppressing aggregation and separation of the constituent components and reproducibly preparing a composition excellent in uniformity, it is preferable to prepare a solution in which a hydrolysis condensate or the like is dissolved well in advance, and prepare a composition using the solution. Note that the hydrolysis condensate and the like may aggregate or precipitate when they are mixed depending on the type and amount of the solvent mixed together, the amount and properties of other components, and the like. In addition, in the case of preparing a composition using a solution in which a hydrolysis condensate or the like is dissolved, it is also noted that it is necessary to determine the concentration of the solution of the hydrolysis condensate or the like and the use amount thereof so that the hydrolysis condensate or the like in the finally obtained composition becomes a desired amount.

In preparation of the composition, heating may be appropriately performed as long as the components are not decomposed or altered.

In the present invention, filtration may be performed using a submicrometer-order filter or the like in the middle of manufacturing the resist underlayer film forming composition or after mixing all the components.

The resist underlayer film forming composition of the present invention can be suitably used as a resist underlayer film forming composition used in a lithography process.

### (Silicon-containing Resist Underlayer Film Forming Composition of Second Aspect)

The resist underlayer film forming composition of the present invention contains a hydrolysis condensate of a hydrolyzable silane mixture and a specific additive (compound A) having a chemical structure containing a cation AX⁺ and an anion AZ⁻.

By adding a specific additive (compound A) having a chemical structure containing a cation AX⁺ and an anion AZ⁻ to the resist underlayer film forming composition containing the hydrolysis condensate (polysiloxane) of the hydrolyzable silane mixture, a resist underlayer film exhibiting excellent solubility in an alkaline solution (basic chemical solution) can be formed.

### <Hydrolysis Condensate of Hydrolyzable Silane Mixture>

The hydrolyzable silane that forms the hydrolysis condensate of the hydrolyzable silane mixture contained in the silicon-containing resist underlayer film forming composition of the second aspect is not particularly limited, and all silane compounds (hydrolyzable silane) described in the section of <Hydrolysis Condensate of Hydrolyzable Silane Mixture> in the above (silicon-containing resist underlayer film forming composition of first aspect) can be used. That is, any of the hydrolyzable silane represented by Formula (1), the hydrolyzable silane represented by Formula (2), the hydrolyzable silane represented by Formula (3), the hydrolyzable silane represented by Formula (4), and the hydrolyzable silane represented by Formula (5) may be contained, or a hydrolyzable silane other than the hydrolyzable silane represented by these formulae may be contained.

The difference between the hydrolysis condensate of the second aspect and the hydrolysis condensate of the first aspect is that the type of the hydrolyzable silane contained in the hydrolyzable silane mixture is defined to contain a specific hydrolyzable silane in the first aspect, but is not particularly limited in the second aspect. Since the solubility of the resist underlayer film in an alkaline solution (basic chemical solution) can be improved by including a specific additive (compound A) in the resist underlayer film forming composition, in the second aspect, the type of the hydrolyzable silane contained in the hydrolyzable silane mixture is not particularly limited. In the second aspect, any hydrolyzable silane can be used.

As “Hydrolysis Condensate of Hydrolyzable Silane Mixture” in the second aspect, various hydrolyzable silane described in the section of <Hydrolysis Condensate of Hydrolyzable Silane Mixture> in the above (silicon-containing resist underlayer film forming composition of the first aspect) can be used.

### <Specific Additive (Compound A)>

The “Specific Additive (Compound A)” in the second aspect is as described in the section of the <Specific Additive (Compound A)> in the above (silicon-containing resist underlayer film forming composition of the first aspect).

The resist underlayer film forming composition of the second aspect can also contain a solvent and other components in addition to the hydrolysis condensate (polysiloxane) of the hydrolyzable silane mixture and the specific additive (compound A).

### <Solvent>

The “solvent” in the second aspect is as described in the section of <Solvent> in the above (silicon-containing resist underlayer film forming composition of the first aspect).

### <Other Components (Other Additives)>

The “Other Components” in the second aspect are as described in the section of the <Other components (Other additives)> in the above (silicon-containing resist underlayer film forming composition of the first aspect).

The description of the solid content concentration and the preferred pH value of the resist underlayer film forming composition and the manufacturing method of the resist underlayer film forming composition in the second aspect is as described in the section of the above (silicon-containing resist underlayer film forming composition of the first aspect).

### [Pattern Forming Method and Manufacturing Method of Semiconductor Device]

Hereinafter, as one aspect of the present invention, a pattern forming method using the resist underlayer film forming composition of the present invention and a manufacturing method of a semiconductor device will be described.

First, the resist underlayer film forming composition of the present invention is applied onto a substrate used for manufacturing precision integrated circuit elements (for example, a semiconductor substrate such as a silicon wafer coated with a silicon oxide film, a silicon nitride film, or a silicon oxynitride film, a silicon nitride substrate, a quartz substrate, a glass substrate (including alkali-free glass, low-alkali glass, and crystallized glass), a glass substrate with ITO (indium tin oxide) films and IZO (indium zinc oxide) films, a plastic (polyimide, PET, or the like) substrate, a low dielectric constant material (low-k material) coated substrate, a flexible circuit board, or the like] using an appropriate application method such as a spinner or coater, and then the composition is cured by baking using a heating means such as a hot plate to form a resist underlayer film. In the present specification, the resist underlayer film refers to a film formed from the resist underlayer film forming composition of the present invention.

The firing conditions are appropriately selected from a firing temperature of 40° C. to 400° C., or 80° C. to 250° C., and a firing time of 0.3 minutes to 60 minutes. Preferably, the firing temperature is 150° C. to 250° C., and the firing time is 0.5 minutes to 2 minutes.

The film thickness of the resist underlayer film formed here is, for example, 10 nm to 1,000 nm, or 20 nm to 500 nm, or 50 nm to 300 nm, or 100 nm to 200 nm, or 10 to 150 nm.

In the present invention, an aspect is adopted in which an organic underlayer film is formed on the substrate and then the resist underlayer film is formed on the organic underlayer film, but an aspect may be adopted in which the organic underlayer film is not provided in some cases.

The organic underlayer film used here is not particularly limited, and can be arbitrarily selected and used from those conventionally used in the lithography process.

By adopting an aspect in which an organic underlayer film, a resist underlayer film on the organic underlayer film, and a resist film to be described later are provided on the substrate, the pattern width of the photoresist film is narrowed, and even when the photoresist film is thinly covered in order to prevent pattern collapse, the substrate can be processed by selecting an appropriate etching gas to be described later. For example, the resist underlayer film of the present invention can be processed using a fluorine-based gas having a sufficiently high etching rate with respect to the photoresist film as an etching gas, the organic underlayer film can be processed using an oxygen-based gas having a sufficiently high etching rate with respect to the resist underlayer film of the present invention as an etching gas, and the substrate can be processed using a fluorine-based gas having a sufficiently high etching rate with respect to the organic underlayer film as an etching gas.

Note that the substrate and the application method that can be used at this time are the same as those described above.

Next, for example, a layer (resist film) of a photoresist material is formed on the resist underlayer film. The resist film can be formed by a known method, that is, by applying and firing a coating type resist material (for example, a photoresist film forming composition) on the resist underlayer film.

The thickness of the resist film is, for example, 10 nm to 10,000 nm, or 100 nm to 2,000 nm, or 200 nm to 1,000 nm, or 30 nm to 200 nm.

The photoresist material used for the resist film formed on the resist underlayer film is not particularly limited as long as it is sensitive to light (for example, KrF excimer laser, ArF excimer laser, or the like) used for exposure, and both a negative photoresist material and a positive photoresist material can be used. Examples thereof include a positive photoresist material composed of a novolak resin and 1,2-naphthoquinone diazide sulfonic acid ester, a chemically amplified photoresist material composed of a binder having a group which is decomposed by an acid to increase the alkali dissolution rate, a chemically amplified photoresist material composed of a low molecular compound which is decomposed by an acid to increase the alkali dissolution rate of the photoresist, an alkali-soluble binder, and a photoacid generator, a chemically amplified photoresist material composed of a binder that has a group that decomposes with acid to increase the alkali dissolution rate, a low molecular compound that decomposes with acid to increase the alkali dissolution rate of the photoresist, and a photoacid generator, a chemically amplified photoresist material composed of a photoacid generator, and the like.

Specific examples of commercially available products include APEX-E (trade name) manufactured by Shipley Japan, PAR710 (trade name) manufactured by Sumitomo Chemical Co., Ltd., and JSR Corporation; Examples thereof include trade name AR2772 JN and trade name SEPR430 manufactured by Shin-Etsu Chemical Co., Ltd., but are not limited thereto. Further, examples thereof include a fluorine-containing atomic polymer-based photoresist material as described in Proc. SPIE, Vol. 3999, 330-334 (2000), Proc. SPIE, Vol. 3999, 357-364 (2000), or Proc. SPIE, Vol. 3999, 365-374 (2000).

In addition, for the resist film formed on the resist underlayer film, a resist film for electron beam lithography (also referred to as an electron beam resist film) or a resist film for EUV lithography (also referred to as an EUV resist film) can be used instead of the photoresist film, that is, the silicon-containing resist underlayer film forming composition of the present invention can be used for forming a resist underlayer film for electron beam lithography or for forming a resist underlayer film for EUV lithography. In particular, it is suitable as a resist underlayer film forming composition for EUV lithography.

As the electron beam resist material, either a negative type material or a positive type material can be used. Specific examples thereof include a chemically amplified resist material composed of an acid generator and a binder having a group which is decomposed by an acid to change the alkali dissolution rate, a chemically amplified resist material composed of an alkali-soluble binder, an acid generator and a low-molecular compound which is decomposed by an acid to change the alkali dissolution rate of the resist material, a chemically amplified resist material composed of a binder having a group which is decomposed by an acid generator and an acid to change the alkali dissolution rate and a low-molecular compound which is decomposed by an acid to change the alkali dissolution rate of the resist material, a non-chemically amplified resist material composed of a binder having a group which is decomposed by an electron beam to change the alkali dissolution rate, and a non-chemically amplified resist material composed of a binder having a site which is cut by an electron beam to change the alkali dissolution rate. Even in the case of using these electron beam resist materials, a pattern of a resist film can be formed similarly to the case of using a photoresist material as an electron beam as an irradiation source.

In addition, as the EUV resist material, a methacrylate resin-based resist material can be used.

Next, the resist film formed on the upper layer of the resist underlayer film is exposed through a predetermined mask (reticle). For the exposure, a KrF excimer laser (wavelength: 248 nm), an ArF excimer laser (wavelength: 193 nm), an F2 excimer laser (wavelength: 157 nm), the EUV (wavelength: 13.5 nm), an electron beam, or the like can be used.

After the exposure, post exposure bake may be performed as necessary. The post exposure bake is performed under conditions appropriately selected from a heating temperature of 70° C. to 150° C. and a heating time of 0.3 minutes to 10 minutes.

Next, development is performed with a developer (for example, an alkaline developer). As a result, for example, in a case where a positive photoresist film is used, the photoresist film of the exposed portion is removed, and a pattern of the photoresist film is formed.

Examples of the developer (alkaline developer) include aqueous solutions of alkali metal hydroxides such as potassium hydroxide and sodium hydroxide, aqueous solutions of quaternary ammonium hydroxides such as tetramethylammonium hydroxide, tetraethylammonium hydroxide, and choline, and alkaline aqueous solutions (alkaline developers) such as aqueous amine solutions of ethanolamine, propylamine, and ethylenediamine. Furthermore, a surfactant or the like can be added to these developers. The conditions for development are appropriately selected from a temperature of 5 to 50° C. and a time of 10 seconds to 600 seconds.

In addition, in the present invention, an organic solvent can be used as the developer, and development is performed with the developer (solvent) after exposure. As a result, for example, in a case where a negative photoresist film is used, the photoresist film in an unexposed portion is removed, and a pattern of the photoresist film is formed.

Examples of the developer (organic solvent) include methyl acetate, butyl acetate, ethyl acetate, isopropyl acetate, amyl acetate, isoamyl acetate, ethyl methoxyacetate, ethyl ethoxyacetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, propyl-3-methoxypropionate, and the like. Furthermore, a surfactant or the like can be added to these developers. The conditions for development are appropriately selected from a temperature of 5 to 50° C. and a time of 10 seconds to 600 seconds.

The pattern of the photoresist film (upper layer) thus formed is used as a protective film to remove the resist underlayer film (intermediate layer), and then a film including the patterned photoresist film and the patterned resist underlayer film (intermediate layer) is used as a protective film to remove the organic underlayer film (underlayer). Finally, the patterned photoresist film (upper layer), the patterned resist underlayer film (intermediate layer), and the patterned organic underlayer film (underlayer) are used as protective films to process the substrate.

Removal of the resist underlayer film (intermediate layer) performed using the pattern of the resist film (upper layer) as the protective film is performed by dry etching, and gases such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane, and dichloroborane can be used.

A halogen-based gas is preferably used for dry etching of the resist underlayer film. In the dry etching using the halogen-based gas, a resist film (photoresist film) basically made of an organic substance is hardly removed. On the other hand, the silicon-containing resist underlayer film containing many silicon atoms is quickly removed by the halogen-based gas. Therefore, a decrease in the film thickness of the photoresist film due to dry etching of the resist underlayer film can be suppressed. As a result, the photoresist film can be used as a thin film. Therefore, the dry etching of the resist underlayer film is preferably performed with a fluorine-based gas, and examples of the fluorine-based gas include tetrafluoromethane (CF₄), perfluorocyclobutane (C₄F₈), perfluoropropane (C₃F₈), trifluoromethane, difluoromethane (CH₂F₂), and the like, but are not limited thereto.

In a case where the organic underlayer film is provided between the substrate and the resist underlayer film, the organic underlayer film (underlayer) is preferably removed by dry etching using an oxygen-based gas (oxygen gas, oxygen/carbonyl sulfide (COS) mixed gas, and the like), in which the organic underlayer film (underlayer) is subsequently removed using a film including (in a case where any remains, patterned resist film (upper layer)) the patterned resist underlayer film (intermediate layer) as a protective film. This is because the resist underlayer film of the present invention containing a large amount of silicon atoms is hardly removed by dry etching using an oxygen-based gas.

Finally, the processing of the (semiconductor) substrate performed using the patterned resist underlayer film (intermediate layer) and the patterned organic underlayer film (underlayer) as protective films is preferably performed by dry etching using a fluorine-based gas.

Examples of the fluorine-based gas include tetrafluoromethane (CF₄), perfluorocyclobutane (C₄F₈), perfluoropropane (C₃F₈), trifluoromethane, and difluoromethane (CH₂F₂).

In the present invention, after the process of etching (removing) the organic underlayer film, the resist underlayer film can be removed by a chemical solution. The removal of the resist underlayer film by the chemical solution can also be performed after process of the substrate by the patterned organic underlayer film. In the present invention, using the resist underlayer film forming composition containing the hydrolysis condensate (polysiloxane), the solubility can be enhanced under alkaline conditions in the film formed from the condensate. For example, it exhibits excellent solubility in an alkaline solution (basic chemical solution) such as an aqueous solution containing ammonia and hydrogen peroxide. Therefore, the film exhibits favorable peelability in a case where the film is processed with an alkaline solution, and a semiconductor device with less substrate damage can be manufactured by the resist underlayer film that can be easily removed by a chemical solution even if the mask residue is a silicon-based mask residue such as a silicon-containing resist underlayer film.

Examples of the chemical solution include alkaline solutions such as an aqueous solution containing dilute hydrofluoric acid, buffered hydrofluoric acid, hydrochloric acid and hydrogen peroxide (SC-2 chemical solution), an aqueous solution containing sulfuric acid and hydrogen peroxide (SPM chemical solution), an aqueous solution containing hydrofluoric acid and hydrogen peroxide (FPM chemical solution), and an aqueous solution containing ammonia and hydrogen peroxide (SC-1 chemical solution), and the use of an alkaline chemical solution (basic chemical solution) is suitable from the viewpoint of reducing the influence on the substrate.

Examples of the alkaline solution include an aqueous solution containing 1 to 99 mass % of ammonia, tetramethylammonium hydroxide, tetraethylammonium hydroxide, tetrapropylammonium hydroxide, tetrabutylammonium hydroxide, choline hydroxide, benzyltrimethylammonium hydroxide, benzyltriethylammonium hydroxide, DBU (diazabicycloundecene), DBN (diazabicyclononene), hydroxylamine, 1-butyl-1-methylpyrrolidinium hydroxide, 1-propyl-1-methylpyrrolidinium hydroxide, 1-butyl-1-methylpiperidinium hydroxide, 1-propyl-1-methylpiperidinium hydroxide, mepixide, trimethylsulfonium hydroxide, hydrazines, ethylenediamines, or guanidine, in addition to the above-mentioned ammonia peroxide solution (SC-1 chemical solution), which is a mixture of ammonia, hydrogen peroxide solution, and water.

In addition, an organic antireflection film can be formed on the upper layer of the resist underlayer film before the resist film is formed. An antireflection film composition to be used is not particularly limited, and for example, an antireflection film can be arbitrarily selected and used from those conventionally used in a lithography process, and an antireflection film can be formed by a commonly used method, for example, coating and firing by a spinner and a coater.

In addition, the substrate to which the resist underlayer film forming composition of the present invention is applied may have an organic or inorganic antireflection film formed by a CVD method or the like on the surface thereof, and a resist underlayer film may be formed thereon. In a case where the organic underlayer film is formed on the substrate and then the resist underlayer film of the present invention is formed on the organic underlayer film, the substrate to be used may have an organic or inorganic antireflection film formed by the CVD method or the like on the surface thereof.

The resist underlayer film formed from the resist underlayer film forming composition of the present invention may also have absorption with respect to light used in a lithography process depending on the wavelength of the light. In such a case, it is possible to function as an antireflection film having an effect of preventing reflected light from the substrate.

Furthermore, the resist underlayer film can also be used as a layer for preventing interaction between a substrate and a resist film (a photoresist film or the like), a layer having a function of preventing a material used for the resist film or a substance generated at the time of exposure to the resist film from adversely acting on the substrate, a layer having a function of preventing diffusion of a substance generated from the substrate at the time of heating and firing to the upper resist film, a barrier layer for reducing a poising effect of the resist film by the semiconductor substrate dielectric layer, and the like.

The resist underlayer film can be applied to a substrate on which via holes used in a dual damascene process are formed, and can be used as a hole-filling material (embedding material) that can fill the hole without any gaps. In addition, it can also be used as a planarizing material for planarizing the surface of a semiconductor substrate having irregularities.

In addition, the resist underlayer film can be used as an underlayer antireflection film of an EUV resist film capable of preventing reflection of exposure light that is not preferable in EUV exposure (wavelength 13.5 nm), for example, UV (ultraviolet) light or DUV (deep ultraviolet) light (: ArF light, KrF light) from a substrate or an interface without intermixing with the EUV resist film, for example, as an underlayer film of the EUV resist film in addition to the function as a hard mask. That is, reflection can be efficiently prevented as an underlayer of the EUV resist film. In a case where it is used as the EUV resist underlayer film, the process can be performed in the same manner as the photoresist underlayer film.

Using the semiconductor processing substrate including the resist underlayer film and the semiconductor substrate of the present invention described above, the semiconductor substrate can be suitably processed.

In addition, according to the manufacturing method of a semiconductor element including a process of forming an organic underlayer film, a process of forming a silicon-containing resist underlayer film using the silicon-containing resist underlayer film forming composition of the present invention on the organic underlayer film, and a process of forming a resist film on the silicon-containing resist underlayer film as described above, processing of a semiconductor substrate with high accuracy can be realized with high reproducibility, and therefore stable manufacturing of a semiconductor element can be expected.

### EXAMPLES

Hereinafter, the contents and effects of the present invention will be described in more detail by way of examples, but the present invention is not limited thereto.

The hydrolysis condensate (polyorganosiloxane) of a hydrolyzable silane can give a condensate having a weight average molecular weight of 1,000 to 1,000,000 or 1,000 to 100,000. These molecular weights are molecular weights obtained in terms of polystyrene by GPC analysis.

The measurement condition of GPC can be performed using, for example, a GPC device (Trade name: HLC-8220GPC, manufactured by Tosoh Corporation), a GPC column (Trade name: Shodex (registered trademark) KF803L, KF802, KF801, manufactured by Showa Denko K.K.), a column temperature of 40° C., an eluent (elution solvent) of tetrahydrofuran, a flow rate (flow rate) of 1.0 mL/min, and polystyrene (manufactured by Showa Denko K.K.) as a standard sample.

### [1] Synthesis Examples 1 to 11 and Comparative Synthesis Examples 1 and 2: Synthesis of Hydrolysis Condensate (Polysiloxane)

Compounds 1 to 8 used in each synthesis is shown below.

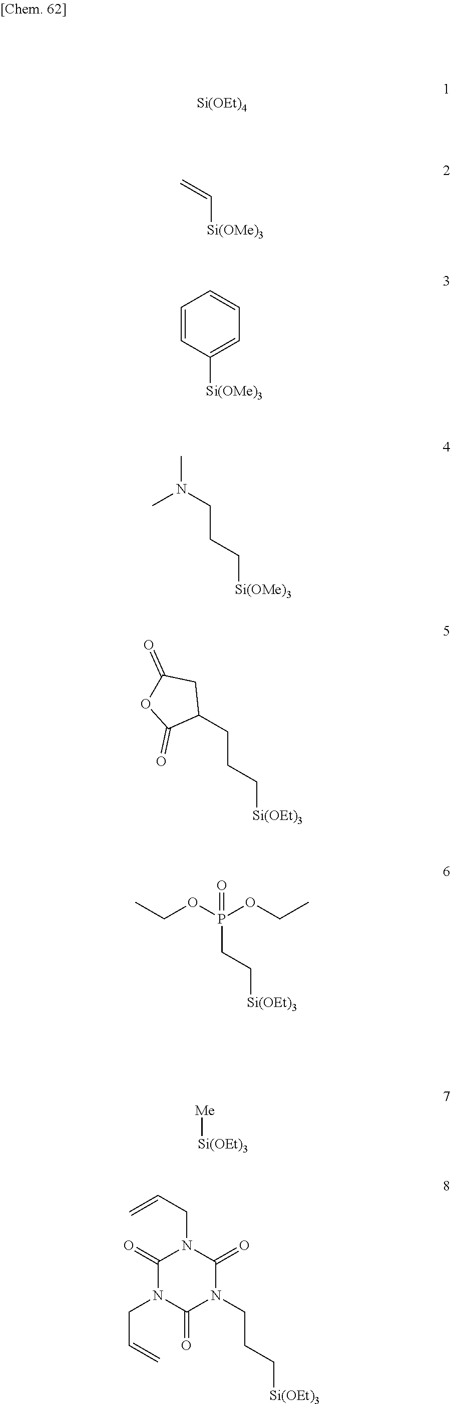

In the above formula, Me represents a methyl group, and Et represents an ethyl group.

### Synthesis Example 1

In a 200 mL flask, 20.8 g of Compound 1, 21.9 g of Compound 2, 8.8 g of Compound 3, 0.1 g of Compound 4, 0.9 g of Compound 5 and 83 g of 1-ethoxy-2-propanol were charged and stirred, and a 0.2 mol/L aqueous nitric acid solution (37 g) was added dropwise thereto while stirring the obtained solution with a magnetic stirrer.

After the dropwise addition, the flask was transferred to an oil bath adjusted to 65° C. and reacted for 20 hours. Thereafter, the reaction solution was cooled to room temperature, 56 g of 1-ethoxy-2-propanol was added to the reaction solution, and water and nitric acid, and methanol and ethanol as reaction by-products were distilled off under reduced pressure to obtain a concentrated solution of a hydrolysis condensate (polymer) using 1-ethoxy-2-propanol as a solvent. The solid content concentration of the obtained concentrated solution was more than 20 mass % in terms of solid residue when heated at 150° C.

The obtained hydrolysis condensate (polysiloxane) corresponded to the following formula, and the weight average molecular weight (Mw) by GPC was 2,000 in terms of polystyrene.

In the chemical formulae described in the following synthesis examples and comparative synthesis examples, the number attached to the side of the siloxane unit represents a molar ratio (total 100).

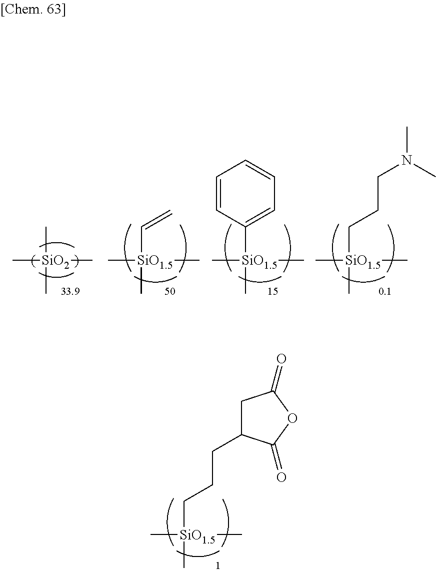

The processes of <Synthesis Example 2> to <Synthesis Example 11> were carried out using compounds (monomers) shown in Table 1 under the same conditions as in Synthesis Example 1, and hydrolysis condensates (polysiloxane compounds) 2 to 11 as target compounds were obtained.

TABLE 1

| | Compound | Compound | Compound | Compound | Compound | Compound | Weight average |
|---|---|---|---|---|---|---|---|
| No. | 1 | 2 | 3 | 4 | 5 | 6 | molecular weight |
| Synthesis | 20.8 g | 21.9 g | 8.8 g | 0.1 g | 0.9 g | — | 2000 |
| Example 1 | | | | | | | |
| (Mol %) | 33.9 | 50 | 15 | 0.1 | 1 | | |
| Synthesis | 20.8 g | 21.9 g | 8.8 g | 0.1 g | — | 1.0 g | 2000 |
| Example 2 | | | | | | | |
| (Mol %) | 33.9 | 50 | 15 | 0.1 | | 1 | |
| Synthesis | 20.8 g | 21.2 g | 8.8 g | 0.1 g | — | 2.4 g | 1800 |
| Example 3 | | | | | | | |
| (Mol %) | 33.9 | 48.5 | 15 | 0.1 | | 2.5 | |
| Synthesis | 20.8 g | 20.1 g | 8.8 g | 0.1 g | — | 4.89 | 1800 |
| Example 4 | | | | | | | |
| (Mol %) | 33.9 | 46 | 15 | 0.1 | | 5 | |
| Synthesis | 20.8 g | 17.9 g | 8.8 g | 0.1 g | — | 9.7 g | 1700 |
| Example 5 | | | | | | | |
| (Mol %) | 33.9 | 41 | 15 | 0.1 | — | 10 | |
| Synthesis | 20.8 g | 20.1 g | 8.8 g | 0.1 g | 2.2 g | 2.4 g | 1800 |
| Example 6 | | | | | | | |
| (Mol %) | 33.9 | 46 | 15 | 0.1 | 2.5 | 2.5 | |
| Synthesis | 20.8 g | 19.0 g | 8.8 g | 0.1 g | 2.2 g | 4.8 g | 1700 |
| Example 7 | | | | | | | |
| (Mol %) | 33.9 | 43.5 | 15 | 0.1 | 2.5 | 5 | |
| Synthesis | 20.8 g | 17.9 g | 8.89 | 0.1 g | 2.2 g | 7.3 g | 1600 |
| Example 8 | | | | | | | |
| (Mol %) | 33.9 | 41 | 15 | 0.1 | 2.5 | 7.5 | |
| Synthesis | 20.8 g | 19.7 g | 8.8 g | 0.1 g | 4.5 g | 1.0 g | 1700 |
| Example 9 | | | | | | | |
| (Mol %) | 33.9 | 45 | 15 | 0.1 | 5 | 1 | |
| Synthesis | 20.8 g | 19.2 g | 8.8 g | 0.1 g | 4.5 g | 1.9 g | 1700 |
| Example 10 | | | | | | | |
| (Mol %) | 33.9 | 44 | 15 | 0.1 | 5 | 2 | |
| Synthesis | 20.8 g | 17.9 g | 8.8 g | 0.19 | 4.5 g | 4.8 g | 1600 |
| Example 11 | | | | | | | |
| (Mol %) | 33.9 | 41 | 15 | 0.1 | 5 | 5 | |

### Comparative Synthesis Example 1

In a 100 mL flask, 20.8 g (70 mol) of Compound 1, 7.6 g (30 mol) of Compound 7, and 42 g of 1-ethoxy-2-propanol were charged and stirred, and 19 g of a 0.2 mol/L nitric acid aqueous solution was added dropwise thereto while stirring the obtained solution with a magnetic stirrer.

After the dropwise addition, the flask was transferred to an oil bath adjusted to 65° C. and reacted for 16 hours. Thereafter, the reaction solution was cooled to room temperature, 100 g of 1-ethoxy-2-propanol was added to the reaction solution, and under reduced pressure, water and nitric acid, and ethanol as a reaction by-product were distilled off from the reaction solution under reduced pressure to obtain a concentrated solution of a hydrolysis condensate (polymer) using 1-ethoxy-2-propanol as a solvent. The solid content concentration of the obtained concentrated solution was more than 20 mass % in terms of solid residue when heated at 150° C.

The obtained hydrolysis condensate (polysiloxane) corresponded to the following formula, and the weight average molecular weight (Mw) by GPC was 2,700 in terms of polystyrene.

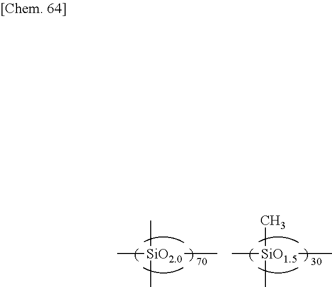

### Comparative Synthesis Example 2

In a 100 mL flask, 12.5 g (40 mol %) of Compound 1, 12.0 g (45 mol %) of Compound 7, 3.6 g (12 mol %) of Compound 3, 1.9 g (3 mol %) of Compound 8, and 45 g of 1-ethoxy-2-propanol were charged and stirred, and while the obtained solution was stirred by a magnetic stirrer, 18 g of a 0.2 mol/L nitric acid aqueous solution was added dropwise thereto while stirring the solution by a magnetic stirrer.

After the dropwise addition, the flask was transferred to an oil bath adjusted to 65° C. and reacted for 16 hours. Thereafter, the reaction solution was cooled to room temperature, 100 g of 1-ethoxy-2-propanol was added to the reaction solution, and under reduced pressure, water and nitric acid, and methanol and ethanol as a reaction by-product were distilled off from the reaction solution under reduced pressure to obtain a concentrated solution of a hydrolysis condensate (polymer) using 1-ethoxy-2-propanol as a solvent. The solid content concentration of the obtained concentrated solution was more than 20 mass % in terms of solid residue when heated at 150° C.

The obtained hydrolysis condensate polysiloxane corresponded to the following formula, and the weight average molecular weight (Mw) by GPC was 1,900 in terms of polystyrene.

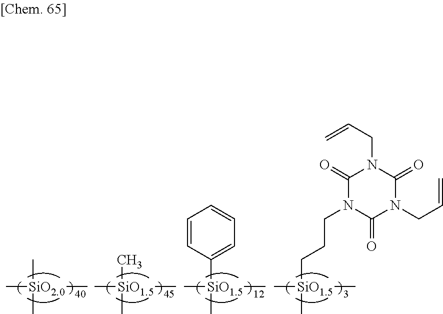

### [2] Preparation Examples 1 to 34 and Comparative Preparation Examples 1 and 2: Preparation of Silicon-Containing Resist Underlayer Film Forming Composition (Coating Liquid)

Additives and solvents were mixed with the hydrolysis condensates (polymer) 1 to 11 obtained in the above synthesis example and the hydrolysis condensate (polymer) of Comparative Synthesis Example 1 and 2 at the ratios shown in Table 2-1 and Table 2-2, and the mixture was filtered through a 0.02 μm polyethylene filter to prepare composition solutions for forming a polysiloxane underlayer film, respectively. Each addition amount in Table 2 is shown in parts by mass.

In Table 2, the fact that the amount of each synthesis example described in the column of composition is 2 parts by mass means that the amount of the hydrolysis condensate is 2 parts by mass. In addition, in Table 2, MA means maleic acid, TPSNO3 means triphenylsulfonium nitrate, PGEE means propylene glycol monoethyl ether, and PGME means propylene glycol monomethyl ether.

In addition, in Table 2, Add-1 to Add-11 are additives represented by the following structural formulae, respectively.

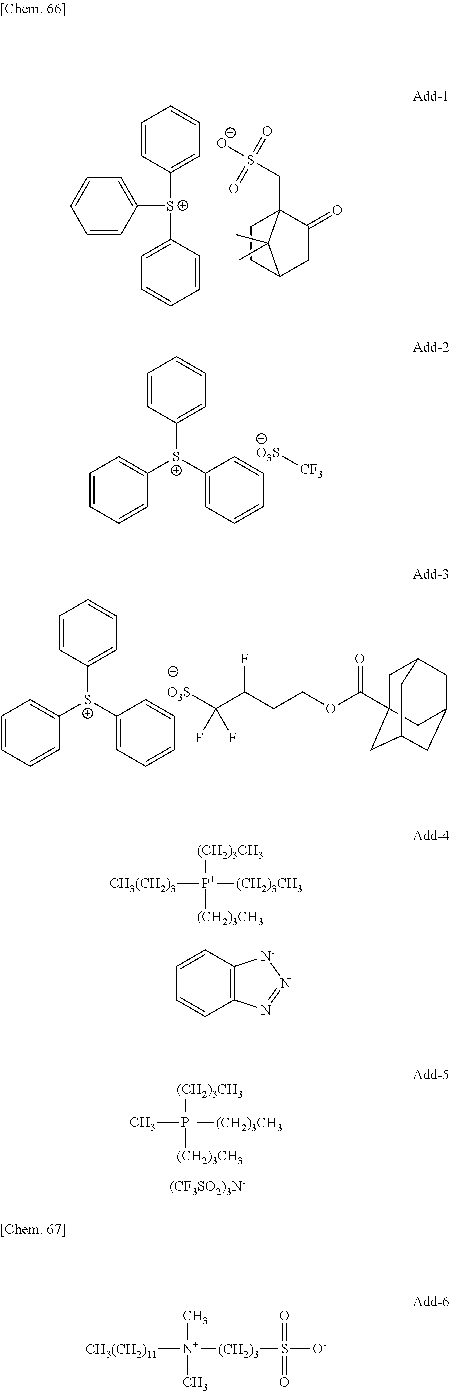

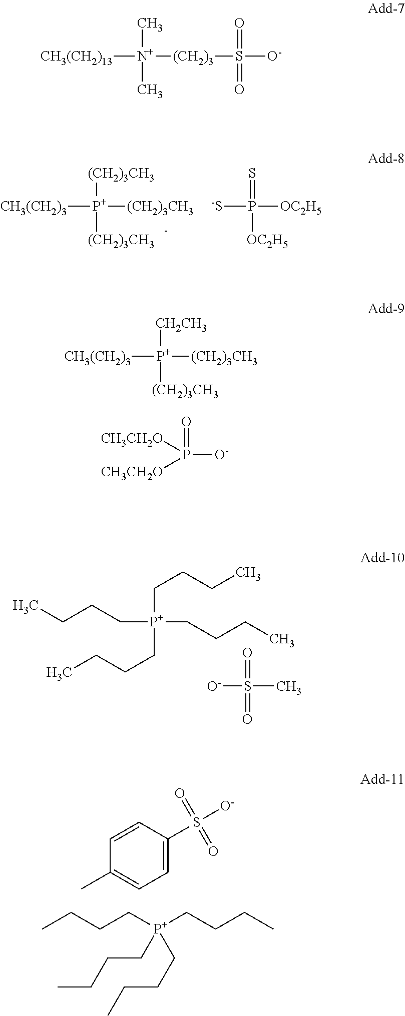

TABLE 2-1

| No. | Composition | Additive 1 | Additive 2 | Additive 3 | Solvent | | |
|---|---|---|---|---|---|---|---|
| Preparation | Synthesis | MA | TPSNO3 | | PGEE | PGME | Water |
| Example 1 | Example 1 | | | | | | |
| (part by mass) | 2 | 0.02 | 0.01 | | 80 | 8 | 12 |
| Preparation | Synthesis. | MA | TPSNO3 | | PGEE | PGME | Water |
| Example 2 | Example 2 | | | | | | |
| (part by mass) | 2 | 0.02 | 0.01 | | 80 | | 12 |
| Preparation | Synthesis | MA | TPSNO3 | | PGEE | PGME | Water |
| Example 3 | Example 3 | | | | | | |
| (part by mass) | 2 | 0.02 | 0.01 | | 80 | 8 | 12 |
| Preparation | Synthesis | MA | TPSNO3 | | PGEE | PGME | Water |
| Example 4 | Example 4 | | | | | | |
| (part by mass) | 2 | 0.02 | 0.01 | | 80 | | 12 |
| Preparation | Synthesis | MA | TPSNO3 | | PGEE | PGME | Water |
| Example 5 | Example 5 | | | | | | |
| (part by mass) | 2 | 0.02 | 0.01 | | 80 | 8 | 12 |
| Preparation | Synthesis | MA | TPSNO3 | | PGEE | PGME | Water |
| Example 6 | Example 6 | | | | | | |
| (part by mass) | 2 | 0.02 | 0.01 | | 80 | 8 | 12 |
| Preparation | Synthesis | MA | TPSNO3 | | PGEE | PGME | Water |
| Example 7 | Example 7 | | | | | | |
| (part by mass) | 2 | 0.02 | 0.01 | | 80 | 8 | 12 |
| Preparation | Synthesis | MA | TPSNO3 | | PGEE | PGME | Water |
| Example 8 | Example 8 | | | | | | |
| (part by mass) | 2 | 0.02 | 0.01 | | 80 | 8 | 12 |
| Preparation | Synthesis | MA | TPSNO3 | | PGEE | PGME | Water |
| Example 9 | Example 9 | | | | | | |
| (part by mass) | 2 | 0.02 | 0.01 | | 80 | | 12 |
| Preparation | Synthesis | MA | TPSNO3 | | PGEE | PGME | Water |
| Example 10 | Example 10 | | | | | | |
| (part by mass) | 2 | 0.02 | 0.01 | | 80 | 8 | 12 |
| Preparation | Synthesis | MA | TPSNO3 | | PGEE | PGME | Water |
| Example 11 | Example 11 | | | | | | |
| (part by mass) | 2 | 0.02 | 0.01 | | 80 | 8 | 12 |
| Preparation | Synthesis | MA | TPSNO3 | Add-1 | PGEE | PGME | Water |
| Example 12 | Example 1 | | | | | | |
| (part by mass) | 2 | 0.02 | 0.01 | 0.3 | 80 | 8 | 12 |
| Preparation | Synthesis | MA | TPSNO3 | Add-1 | PGEE | PGME | Water |
| Example 13 | Example 2 | | | | | | |
| (part by mass) | 2 | 0.02 | 0.01 | 0.3 | 80 | 8 | 12 |
| Preparation | Synthesis | MA | TPSNO3 | Add-1 | PGEE | PGME | Water |
| Example 14 | Example 3 | | | | | | |
| (part by mass) | 2 | 0.02 | 0.01 | 0.3 | 80 | R | 12 |
| Preparation | Synthesis | MA | TPSNO3 | Add-1 | PGEE | PGME | Water |
| Example 15 | Example 4 | | | | | | |
| (part by mass) | 2 | 0.02 | 0.01 | 0.3 | 80 | 8 | 12 |
| Preparation | Synthesis | MA | TPSNO3 | Add-1 | PGEE | PGME | Water |
| Example 16 | Example 5 | | | | | | |
| (part by mass) | 2 | 0,02 | 0.01 | 0.3 | 80 | 8 | 12 |
| Preparation | Synthesis | MA | TPSNO3 | Add-1 | PGEE | PGME | Water |
| Example 17 | Example 6 | | | | | | |
| (part by mass) | 2 | 0.02 | 0.01 | 0.3 | 80 | 8 | 12 |
| Preparation | Synthesis | MA | TPSNO3 | Add-1 | PGEE | PGME | Water |
| Example 18 | Example 7 | | | | | | |
| (part by mass) | 2 | 0.02 | 0.01 | 0.3 | 80 | 8 | 12 |
| Preparation | Synthesis | MA | TPSNO3 | Add-1 | PGEE | PGME | Water |
| Example 19 | Example 8 | | | | | | |
| (part by mass) | 2 | 0.02 | 0.01 | 0.3 | 80 | 8 | 12 |
| Preparation | Synthesis | MA | TPSNO3 | Add-1 | PGEE | PGME | Water |
| Example 20 | Example 9 | | | | | | |
| (part by mass) | 2 | 0.02 | 0.01 | 0.3 | 80 | 8 | 12 |
| Preparation | Synthesis | MA | TPSNO3 | Add-1 | PGEE | PGME | Water |
| Example 21 | Example 10 | | | | | | |
| (part by mass) | 2 | 0.02 | 0.01 | 0.3 | 80 | 8 | 12 |
| Preparation | Synthesis | MA | TPSNO3 | Add-1 | PGEE | PGME | Water |
| Example 22 | Example 1} | | | | | | |
| (part by mass) | 2 | 0.02 | 0.01 | 0.3 | 80 | 8 | 12 |
| Preparation | Synthesis | MA | TPSNO3 | Add-1 | PGEE | PGME | Water |
| Example 23 | Example 6 | | | | | | |
| (part by mass) | 2 | 0.02 | 0.01 | 0.1 | 80 | 8 | 12 |
| Preparation | Synthesis | MA | TPSNO3 | Add-1 | PGEE | PGME | Water |
| Example 24 | Example 6 | | | | | | |
| (part by mass) | 2 | 0.02 | 0.01 | 0.2 | 80 | 8 | 12 |
| Preparation | Synthesis | MA | TPSNO3 | Add-2 | PGEE | PGME | Water |
| Example 25 | Example 6 | | | | | | |
| (part by mass) | 2 | 0.02 | 0.01 | 0.1 | 80 | 8 | 12 |
| Preparation | Synthesis | MA | TPSNO3 | Add-3 | PGEE | PGME | Water |
| Example 26 | Example 8 | | | | | | |
| (part by mass) | 2 | 0.02 | 0.01 | 0.1 | 80 | 8 | 12 |
| Preparation | Synthesis | MA | TPSNO3 | Add-4 | PGEE | PGME | Water |
| Example 27 | Example 6 | | | | | | |
| (part by mass) | 2 | 0.02 | 0.01 | 0.3 | 80 | 8 | 12 |
| Preparation | Synthesis | MA | TPSNO3 | Add-5 | PGEE | PGME | Water |
| Example 28 | Example 6 | | | | | | |
| (part by mass) | 2 | 0.02 | 0.01 | 0.3 | 80 | 8 | 12 |
| Preparation | Synthesis | MA | TPSNO3 | Add-6 | PGEE | PGME | Water |
| Example 29 | Example 8 | | | | | | |
| (part by mass) | 2 | 0.02 | 0.01 | 0.3 | 80 | 8 | 12 |
| Preparation | Synthesis | MA | TPSNO3 | Add-7 | PGEE | PGME | Water |
| Example 30 | Example 6 | | | | | | |
| (part by mass) | 2 | 0.02 | 0.01 | 0.3 | 80 | 8 | 12 |
| Preparation | Synthesis | MA | TPSNO3 | Add-8 | PGEE | PGME | Water |
| Example 31 | Example 6 | | | | | | |
| (part by mass) | 2 | 0.02 | 0.01 | 0.3 | 80 | 8 | 12 |
| Preparation | Synthesis | MA | TP5NO3 | Add-9 | PGEE | PGME | Water |
| Example 32 | Example 6 | | | | | | |
| (part by mass) | 2 | 0.02 | 0.01 | 0.3 | 80 | 8 | 12 |
| Preparation | Synthesis | MA | TPSNO3 | Add-10 | PGEE | PGME | Water |
| Example 33 | Example 6 | | | | | | |
| (part by mass) | 2 | 0.02 | 0.01 | 0.3 | 80 | 8 | 12 |
| Preparation | Synthesis | MA | TPSNO3 | Add-11 | PGEE | PGME | Water |
| Example 34 | Example 6 | | | | | | |
| (part by mass) | 2 | 0.02 | 0.01 | 0.3 | 80 | 8 | 12 |
| Comparative Preparation | Comparative Synthesis | MA | TPSNO3 | | PGEE | PGME | Water |
| Example 1 | Example | | | | | | |
| (part by mass) | 2 | 0.02 | 0.01 | | 80 | 8 | 12 |
| Comparative Preparation | Comparative Synthesis | MA | TPSNO3 | | PGEE | PGME | Water |
| Example 2 | Example 2 | | | | | | |
| (part by mass) | 2 | 0.02 | 0.01 | | 80 | 8 | 12 |

### [3] Preparation of Organic Underlayer Film Forming Composition

Carbazole (6.69 g, 0.040 mol, manufactured by Tokyo Chemical Industry Co., Ltd.), 9-fluorenone (7.28 g, 0.040 mol, manufactured by Tokyo Chemical Industry Co., Ltd.), and p-toluenesulfonic acid monohydrate (0.76 g, 0.0040 mol, manufactured by Tokyo Chemical Industry Co., Ltd.) were charged into a 100 mL four-necked flask under nitrogen, 1,4-dioxane (6.69 g, manufactured by KANTO CHEMICAL CO., INC.) was added thereto and stirred, then the mixture was heated to 100° C. to dissolve the solid, and polymerization was initiated.

After 24 hours, the reaction mixture was allowed to cool to 60° C., and diluted by adding chloroform (34 g, manufactured by KANTO CHEMICAL CO., INC.), and the diluted reaction mixture was added dropwise to methanol (168 g, manufactured by KANTO CHEMICAL CO., INC.), and reprecipitation was performed. The obtained precipitate was collected by filtration, and the collected solid was dried at 80° C. for 24 hours to obtain 9.37 g of the desired polymer represented by the formula (X) (hereinafter, abbreviated as PCzFL).

The 1H-NMR measurement results of PCzFL were as follows.

1H-NMR (400 MHZ, DMSO-d₆): δ7.03-7.55 (br, 12H), δ7.61-8.10 (br, 4H), δ11.18 (br, 1H)

In addition, the weight average molecular weight (Mw) of PCzFL was 2,800 in terms of polystyrene by GPC, and the polydispersity Mw/Mn was 1.77.

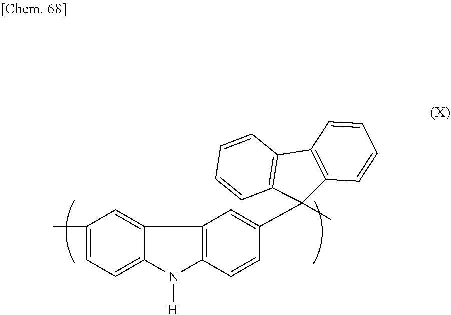

20 g of PCzFL, 3.0 g of tetramethoxymethyl glycoluril (Powderlink 1174 (trade name) manufactured by Nippon Cytec Industries, Ltd. (former Mitsui Cytec Co., Ltd.)) as a crosslinking agent, 0.30 g of pyridinium paratoluenesulfonate as a catalyst, and 0.06 g of Megafac R-30 (Manufactured by DIC Corporation, trade name) as a surfactant were mixed, and the mixture was dissolved in 88 g of propylene glycol monomethyl ether acetate to prepare a solution. Thereafter, the solution was filtered using a polyethylene microfilter having a pore size of 0.10 μm and further filtered using a polyethylene microfilter having a pore size of 0.05 μm to prepare the organic underlayer film forming composition.

### [4] Examples 1 to 34 and Comparative Examples 1 and 2: Evaluation of Resist Pattern by ArF Exposure (PTD)

The organic underlayer film forming composition was applied onto a silicon wafer using a spinner, and heated on a hot plate at 240° C. for 60 seconds to form an organic underlayer film (A layer) (film thickness: 200 nm).

The coating liquid obtained in Preparation Example 1 was applied thereon by spin coating, and heated on a hot plate at 215° C. for 1 minute to form a silicon-containing resist underlayer film (B layer) (20 nm).

Furthermore, a commercially available ArF resist (Manufactured by JSR Corporation, trade name: AR2772JN) was applied thereon by spin coating, and heated on a hot plate at 110° C. for 90 seconds to form a resist film (C layer) (120 nm). Thereafter, using NSR-S307E Scanner (Wavelength: 193 nm, NA: 0.85, σ: 0.85/0.93) manufactured by Nikon Corporation, exposure was performed through a mask set so that the line width of the photoresist and the width between lines became 0.065 μm after the following development, that is, a 0.065 μm line- and -space (L/S)=1/1 dense line was formed.

After the exposure, the post exposure bake (110° C. for 1 minute) is performed, and the result is cooled on a cooling plate to room temperature, developed for 60 seconds using a 2.38% aqueous alkali solution, and rinsed to form a resist pattern.

In the same procedure, resist patterns were formed using the coating liquids obtained in Preparation Examples 2 to 34 and Comparative Preparation Examples 1 and 2.

The experimental results using Preparation Examples 1 to 34 were designated as Examples 1 to 34, and the experimental results using Comparative Preparation Examples 1 and 2 were designated as Comparative Examples 1 and 2.

The obtained photoresist pattern was evaluated by confirming a pattern shape by pattern cross section observation, and a photoresist pattern in which pattern collapse (significant pattern peeling, undercut, and line bottom thickening (fusing)) did not occur was evaluated as “Good”, and a photoresist pattern in which pattern collapse occurred was evaluated as “Poor”. The obtained results are shown in Table 3.

In the following description, the example number of the resist underlayer film forming composition used is also treated as the example number of various evaluations performed using the composition.

### [5] Examples 1 to 34 and Comparative Examples 1 and 2: Evaluation of Siloxane Bond Strength Ratio by FT-IR

The coating liquid obtained in Preparation Example 1 was applied onto a silicon wafer by spin coating, and heated on a hot plate at 215° C. for 1 minute to form a silicon-containing resist underlayer film (B layer). On the formed layer B, the layer B was further laminated twice in the same step to obtain a layer B (80 nm thick) laminated three times.

In the same procedure, a silicon-containing resist underlayer film was formed using each of the coating liquids obtained in Preparation Examples 2 to 34 and Comparative Preparation Examples 1 and 2.

For each of the obtained silicon-containing resist underlayer films, the peak intensity of a siloxane bond observed at a wave number of 1000 to 1250 cm-1 was compared using Fourier transform infrared spectroscopy (FT/IR-6600 (manufactured by JASCO Corporation)). The peak intensity was compared using a value normalized with the intensity of the silicon-containing resist underlayer film of Comparative Example 2 as 100. In a case where the bond strength ratio to Comparative Example 2 is relatively high (for example, 90 or more), solubility tends to decrease. The obtained results are shown in Table 3.

### [6] Examples 1 and 34, Comparative Examples 1 and 2: Evaluation of Removability with SC-1 Chemical Solution (Ammonia/Hydrogen Peroxide Aqueous Solution)

The coating liquid obtained in Preparation Example 1 was applied onto a silicon wafer by spin coating, and heated on a hot plate at 215° C. for 1 minute to form a silicon-containing resist underlayer film (B layer) (20 nm).

In the same procedure, a silicon-containing resist underlayer film was formed using each of the coating liquids obtained in Preparation Examples 2 to 34 and Comparative Preparation Examples 1 and 2.

The obtained silicon wafer on which each silicon-containing resist underlayer film was formed was immersed in a SC-1 chemical solution (28% ammonia water/33% hydrogen peroxide water/water=Jan. 1, 2010 (v/v/v)) adjusted to a liquid temperature of 60° C. for 180 seconds or 300 seconds, then rinsed with water for 60 seconds, and then dried. Then, the thickness of the silicon-containing resist underlayer film after immersion in the SC-1 chemical solution for 300 seconds was measured, and the film thickness change rate (%) was calculated. A film having a change rate of the film thickness after immersion with respect to the film thickness of the silicon-containing resist underlayer film before immersion of 90% or more was evaluated as “Good”, and a film having a change rate of less than 90% was evaluated as “Poor”. In addition, among those evaluated as “Good” in the immersion for 300 seconds, those in which the change rate of the film thickness of the silicon-containing resist underlayer film after the immersion for 180 seconds was 90% or more were evaluated as “Very Good”. The obtained results are shown in Table 3.

### [7] Examples 1 to 34 and Comparative Examples 1 and 2: Evaluation of Residue after Dry Etching

Onto a silicon wafer, the organic underlayer film forming composition was applied onto a silicon wafer using a spinner, and heated on a hot plate at 240° C. for 60 seconds to form an organic underlayer film (A layer) (film thickness: 70 nm).

The coating liquid obtained in Preparation Example 1 was applied thereon by spin coating, and heated on a hot plate at 215° C. for 1 minute to form a silicon-containing resist underlayer film (B layer) (20 nm).

Dry etching was performed for 20 seconds under CF₄ gas conditions using a dry etcher (LAM-2300) manufactured by LAM RESEARCH CORPORATION and the silicon-containing resist underlayer film (B layer) was removed from the obtained silicon wafer with a film. Thereafter, the dry etching was performed for 5 seconds under 02/COS-based gas conditions to remove the organic underlayer film (layer A).

In the same procedure, the silicon-containing resist underlayer film was formed using each of the coating liquids obtained in Preparation Examples 2 to 34 and Comparative Preparation Examples 1 and 2, and the silicon-containing resist underlayer film (B layer) and the organic underlayer film (A layer) were removed.

The silicon wafer surface from which the organic underlayer film (A layer) and the silicon-containing resist underlayer film (B layer) had been removed was observed using a scanning probe microscope (AFM 5000 manufactured by Hitachi High-Tech Corporation). In a case where a convex etching residue having a width of 0.05 μm or more and a height of 2 nm or more was confirmed, it was evaluated as “Poor”, and in a case of not confirmed, it was evaluated as “Good”. The obtained results are shown in Table 3.

TABLE 3

| | | | Siloxane | SC-1 Chemical | Etching |
|---|---|---|---|---|---|
| | Preparation | Pattern | Binding | Solution | Residue |
| | Example | Shape | strength ratio | Removability | Removability |
| Example 1 | 1 | Good | 72 | Good | Good |
| Example 2 | 2 | Good | 74 | Good | Good |
| Example 3 | 3 | Good | 74 | Good | Good |
| Example 4 | 4 | Good | 72 | Good | Good |
| Example 5 | 5 | Good | 69 | Good | Good |
| Example 6 | 6 | Good | 72 | Good | Good |
| Example 7 | 7 | Good | 68 | Good | Good |
| Example 8 | 8 | Good | 68 | Good | Good |
| Example 9 | 9 | Good | 74 | Good | Good |
| Example 10 | 10 | Good | 76 | Good | Good |
| Example 11 | 11 | Good | 65 | Good | Good |
| Example 12 | 12 | Good | 61 | Very Good | Good |
| Example 13 | 13 | Good | 66 | Very Good | Good |
| Example 14 | 14 | Good | 67 | Very Good | Good |
| Example 15 | 15 | Good | 65 | Very Good | Good |
| Example 16 | 16 | Good | 62 | Very Good | Good |
| Example 17 | 17 | Good | 57 | Very Good | Good |
| Example 18 | 18 | Good | 56 | Very Good | Good |
| Example 19 | 19 | Good | 58 | Very Good | Good |
| Example 20 | 20 | Good | 53 | Very Good | Good |
| Example 21 | 21 | Good | 52 | Very Good | Good |
| Example 22 | 22 | Good | 54 | Very Good | Good |
| Example 23 | 23 | Good | 67 | Very Good | Good |
| Example 24 | 24 | Good | 64 | Very Good | Good |
| Example 25 | 25 | Good | 66 | Very Good | Good |
| Example 26 | 26 | Good | 64 | Very Good | Good |
| Example 27 | 27 | Good | 64 | Very Good | Good |
| Example 28 | 28 | Good | 66 | Very Good | Good |
| Example 29 | 29 | Good | 59 | Very Good | Good |
| Example 30 | 30 | Good | 58 | Very Good | Good |
| Example 31 | 31 | Good | 66 | Very Good | Good |
| Example 32 | 32 | Good | 63 | Very Good | Good |
| Example 33 | 33 | Good | 63 | Very Good | Good |
| Example 34 | 34 | Good | 64 | Very Good | Good |
| Comparative | Comparative | — | 100 | Poor | — |
| Example 1 | Preparation | | (Reference) | | |
| | Example 1 | | | | |
| Comparative | Comparative | Good | — | — | Poor |
| Example 2 | Preparation | | | | |
| | Example 2 | | | | |

1. A silicon-containing resist underlayer film forming composition for forming a silicon-containing resist underlayer film soluble in a basic chemical solution, the composition comprising: a hydrolysis condensate of a hydrolyzable silane mixture containing at least one of a hydrolyzable silane represented by Formula (1) below and a hydrolyzable silane represented by Formula (2) below:
R¹ₐR²_{b}Si(R³)₄—(a+b) (1)
(In Formula (1),
R¹ is a group bonded to a silicon atom, and represents an organic group containing a succinic anhydride skeleton,
R² is a group bonded to a silicon atom, and independently of one another represents an optionally substituted alkyl group, an optionally substituted halogenated alkyl group, an optionally substituted alkoxyalkyl group, or an organic group containing an epoxy group, an acryloyl group, a methacryloyl group, a mercapto group, an amino group, an amide group, an alkoxy group, a sulfonyl group, or a cyano group, or a combination of these,
R³ is a group or atom bonded to the silicon atom, and independently of one another represents an alkoxy group, an aralkyloxy group, an acyloxy group, or a halogen atom, and
a represents 1, b represents an integer of 0 to 2, and 4-(a+b) represents an integer of 1 to 3)
R⁴ₐR⁵_{b}Si(R⁶)₄—(a+b) (2)
(In Formula (2),
R⁴ is a group which is bonded to a silicon atom and represents a monovalent group represented by Formula (2-1) below, and 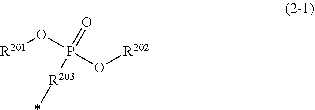
(In Formula (2-1),
R²⁰¹ to R²⁰² each independently represent a hydrogen atom or an organic group containing an optionally substituted alkyl group, R²⁰³ represents an optionally substituted alkylene group, and * represents a bond bonded to a silicon atom)
R⁵ is a group bonded to a silicon atom, and independently of one another represents an optionally substituted alkyl group, an optionally substituted halogenated alkyl group, an optionally substituted alkoxyalkyl group, or an organic group containing an epoxy group, an acryloyl group, a methacryloyl group, a mercapto group, an amino group, an amide group, an alkoxy group, a sulfonyl group, or a cyano group, or any combination of these,
R⁶ is a group or atom bonded to the silicon atom, and each independently represents an alkoxy group, an aralkyloxy group, an acyloxy group, or a halogen atom, and
a represents 1, b represents an integer of 0 to 2, and 4-(a+b) represents an integer of 1 to 3.)

2. The silicon-containing resist underlayer film forming composition according to claim 1, further comprising: a compound A having a chemical structure containing a cation AX⁺ and an anion AZ⁻, the anion having a molecular weight of 65 or more.

3. The silicon-containing resist underlayer film forming composition according to claim 2, wherein the anion AZ⁻ is at least one anion selected from the group consisting of anions represented by the following (A) to (E): 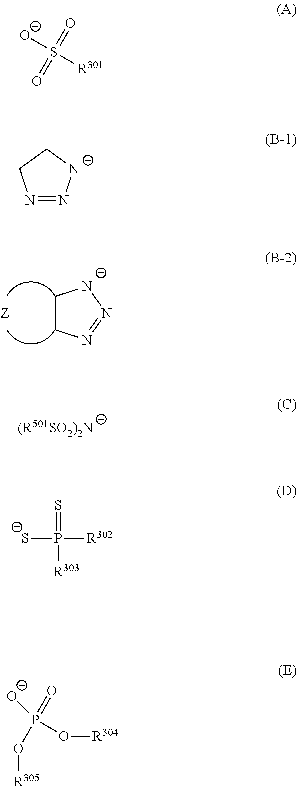
(In Formulae (A) to (E),
R³⁰¹ represents an optionally substituted alkyl group, an optionally substituted aryl group, an optionally substituted halogenated alkyl group, an optionally substituted aralkyl group, or an organic group containing an ester bond (—C(═O)—O— or —O—C(═O)—), or a combination of these,
Z represents an aromatic ring, a cyclic alkane, or a cyclic alkene with a non-aromatic ring,
R⁵⁰¹ represents an alkyl group in which some or all of the alkyl group may be substituted with a fluorine atom,
R³⁰² and R³⁰³ each independently represent an alkyl group, and
R³⁰⁴ and R³⁰⁵ each independently represent an alkyl group.)

4. The silicon-containing resist underlayer film forming composition according to claim 1, wherein the hydrolyzable silane mixture further contains a hydrolyzable silane represented by Formula (3) below:
R⁷ₐR⁸_{b}Si(R⁹)₄—(a+b) (3)
(In Formula (3),
R⁷ is a group bonded to a silicon atom, and represents an organic group containing an alkenyl group,
R⁸ is a group bonded to a silicon atom, and independently of one another represents an optionally substituted alkyl group, an optionally substituted halogenated alkyl group or an optionally substituted alkoxyalkyl group, or represents an organic group containing an epoxy group, an acryloyl group, a methacryloyl group, a mercapto group, an amino group, an amide group, an alkoxy group, a sulfonyl group, or a cyano group, or a combination of these,
R⁹ is a group or atom bonded to a silicon atom, and independently of one another represents an alkoxy group, an aralkyloxy group, an acyloxy group, or a halogen atom, and
a represents 1, b represents an integer of 0 to 2, and 4-(a+b) represents an integer of 1 to 3.)

5. The silicon-containing resist underlayer film forming composition according to claim 4, wherein the hydrolyzable silane mixture further contains a hydrolyzable silane represented by Formula (4) below:
Si(R¹⁰)₄ (4)
(In Formula (4),
R¹⁰ is a group or atom bonded to a silicon atom, and independently of one another represents an alkoxy group, an aralkyloxy group, an acyloxy group, or a halogen atom.)

6. A silicon-containing resist underlayer film forming composition for forming a silicon-containing resist underlayer film soluble in a basic chemical solution, the composition comprising:
a compound A having a chemical structure containing a cation AX⁺ and an anion AZ⁻, the anion having a molecular weight of 65 or more.

7. The silicon-containing resist underlayer film forming composition according to claim 6, wherein the anion AZ⁻ is at least one anion selected from the group consisting of anions represented by the following (A) to (E): 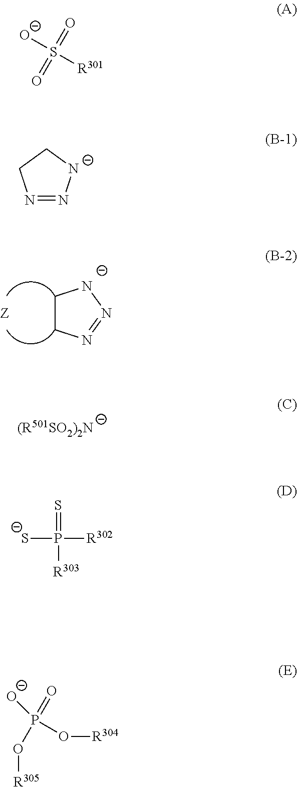
(In Formulae (A) to (E),
R³⁰¹ represents an optionally substituted alkyl group, an optionally substituted aryl group, an optionally substituted halogenated alkyl group, an optionally substituted aralkyl group, or an organic group containing an ester bond (—C(═O)—O— or —O—C(═O)—), or a combination of these,
Z represents an aromatic ring, a cyclic alkane, or a cyclic alkene with a non-aromatic ring,
R⁵⁰¹ represents an alkyl group in which some or all of the alkyl group may be substituted with a fluorine atom,
R³⁰² and R³⁰³ each independently represent an alkyl group, and
R³⁰⁴ and R³⁰⁵ each independently represent an alkyl group.)

8. A silicon-containing resist underlayer film formed using the resist underlayer film forming composition according to claim 1.

9. A pattern forming method comprising:
a process of forming an organic underlayer film on a semiconductor substrate;
a process of forming a silicon-containing resist underlayer film by applying the resist underlayer film forming composition according to claim 1 on the organic underlayer film and firing the composition;
a process of forming a resist film by applying a resist film forming composition on the silicon-containing resist underlayer film;
a process of obtaining a resist pattern by exposing and developing the resist film;
a process of etching the silicon-containing resist underlayer film using a resist pattern as a mask; and
a process of etching the organic underlayer film using the patterned silicon-containing resist underlayer film as a mask.

10. The pattern forming method according to claim 9, further comprising: a process of removing a silicon-containing resist underlayer film by a wet method using a chemical solution after the process of etching the organic underlayer film.

11. The pattern forming method according to claim 10, wherein the chemical solution is a basic chemical solution.

12. A silicon-containing resist underlayer film formed using the resist underlayer film forming composition according to claim 6.

13. A pattern forming method comprising:
a process of forming an organic underlayer film on a semiconductor substrate;
a process of forming a silicon-containing resist underlayer film by applying the resist underlayer film forming composition according to claim 6 on the organic underlayer film and firing the composition;
a process of forming a resist film by applying a resist film forming composition on the silicon-containing resist underlayer film;
a process of obtaining a resist pattern by exposing and developing the resist film;
a process of etching the silicon-containing resist underlayer film using a resist pattern as a mask; and
a process of etching the organic underlayer film using the patterned silicon-containing resist underlayer film as a mask.

14. The pattern forming method according to claim 13, further comprising: a process of removing a silicon-containing resist underlayer film by a wet method using a chemical solution after the process of etching the organic underlayer film.

15. The pattern forming method according to claim 14, wherein the chemical solution is a basic chemical solution.
